(19) United States
(12) Patent Application Publication
(10) Pub. No.: US 2026/0231606 A1
(43) Pub. Date: Aug. 6, 2026

(54) Light-Emitting Device and Display Panel

(71) Applicant: BOE TECHNOLOGY GROUP CO., LTD., Chaoyang District, Beijing (CN)

(72) Inventors: Rongrong Gao, Beijing (CN); Dongxu Zhang, Beijing (CN); Xianwen Meng, Beijing (CN); Lei Chen, Beijing (CN)

(21) Appl. No.: 19/147,737

(22) PCT Filed: Jul. 29, 2024
(86) PCT No.: PCT/CN2024/108212

§ 371 Date: Jul. 14, 2025

(30) Foreign Application Priority Data
Aug. 31, 2023 (CN) 202311121381.4

(51) Int. Cl. H10K 50/19; H10K 50/15; H10K 50/18; H10K 85/30; H10K 85/40; H10K 85/60; H10K 101/10; H10K 101/40; H10K 102/00

(52) U.S. Cl. CPC H10K 50/19; H10K 50/15; H10K 50/181; H10K 85/342; H10K 85/40; H10K 85/626; H10K 85/633; H10K 85/636; H10K 85/654; H10K 85/6572; H10K 85/6574; H10K 85/6576; H10K 85/658; H10K 2101/10; H10K 2101/40; H10K 2102/351

(57) ABSTRACT

A light-emitting device includes a cathode and an anode that are arranged opposite to each other, and at least one light-emitting unit located between the cathode and the anode. A light-emitting unit includes a light-emitting layer and a first type of functional layer arranged on a side of the light-emitting layer proximate to the anode. The first type of functional layer includes a first functional sub-layer and a second functional sub-layer, a material of the first functional sub-layer includes a second functional material. An overlap rate of density of states for HOMO of the first functional material and density of states for HOMO of the second functional material is greater than 0% and less than or equal to 90%.

### CROSS-REFERENCE TO RELATED APPLICATIONS

This application is the United States national phase of International Patent Application No. PCT/CN2024/108212, filed Jul. 29, 2024, and claims priority to Chinese Patent Application No. 202311121381.4, filed Aug. 31, 2023, the disclosures of which are hereby incorporated by reference in their entireties.

### BACKGROUND OF THE INVENTION

### Field of the Invention

The present disclosure relates to the field of display technologies, and in particular, to a light-emitting device and a display panel.

### Description of Related Art

Organic light-emitting diode (OLED) display panels have the advantages of self-illumination, high color gamut, high saturation, high response speed and the like, and are widely used in display screens such as mobile phones, tablets, and car displays.

### SUMMARY OF THE INVENTION

In an aspect, a light-emitting device is provided. The light-emitting device includes: a cathode and an anode that are arranged opposite to each other, and at least one light-emitting unit located between the cathode and the anode. A light-emitting unit of the at least one light-emitting unit includes a light-emitting layer and a first type of functional layer arranged on a side of the light-emitting layer proximate to the anode; the first type of functional layer includes a first functional sub-layer and a second functional sub-layer, a material of the first functional sub-layer includes a first functional material, and a material of the second functional sub-layer includes a second functional material. An overlap rate of density of states for HOMO of the first functional material and density of states for HOMO of the second functional material is greater than 0% and less than or equal to 90%.

In some embodiments, the first functional sub-layer is in contact with the light-emitting layer, and a material of the light-emitting layer includes a host material; an overlap rate of the density of states for HOMO of the first functional material and density of states for HOMO of the host material is greater than 0% and less than or equal to 90%.

In some embodiments, the material of the light-emitting layer further includes a guest material; at least one of the host material, the guest material and the first functional material is a deuterated material.

In some embodiments, an absolute value of a difference between an electron reorganization energy of the host material and a hole reorganization energy of the host material is less than or equal to 0.1 eV; and/or a hole mobility of the host material is greater than an electron mobility of the host material.

In some embodiments, a dipole moment of the first functional material is greater than 0 D.

In some embodiments, a lowest bond dissociation energy of bond dissociation energies of the first functional material in a ground state is greater than or equal to 2.40 eV; and/or a lowest bond dissociation energy of bond dissociation energies of the first functional material in an anionic state is greater than or equal to 1.0 eV.

In some embodiments, a lowest bond dissociation energy of bond dissociation energies of the host material in a ground state is greater than or equal to 1.50 eV; and/or a lowest bond dissociation energy of bond dissociation energies of the guest material in a ground state is greater than or equal to 1.50 eV.

In some embodiments, a triplet energy level of the host material is less than a triplet energy level of the guest material; and/or a singlet energy level of the host material is greater than a singlet energy level of the guest material.

In some embodiments, the light-emitting unit further includes: a second type of functional layer disposed on a side of the light-emitting layer proximate to the cathode. The second type of functional layer includes a third functional sub-layer, and the third functional sub-layer is in contact with the light-emitting layer; a material of the third functional sub-layer includes a third functional material. A triplet energy level of the host material is greater than a triplet energy level of the third functional material. The triplet energy level of the host material is less than a triplet energy level of the first functional material.

In some embodiments, the host material is selected from structures represented by a following general formula (I).

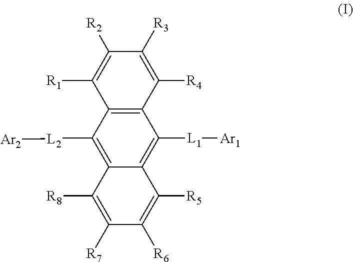

Here, R₁, R₂, R₃, R₄, R₅, R₆, R₇ and R₈ are same or different, and are independently selected from hydrogen, deuterium, substituted or unsubstituted alkyl, substituted or unsubstituted alkoxy, substituted or unsubstituted aryl, substituted or unsubstituted aryloxy, substituted or unsubstituted diarylamino, substituted or unsubstituted siloxane and substituted or unsubstituted silyl; L₁ and L₂ are same or different, and are independently selected from a single bond, substituted or unsubstituted arylene and substituted or unsubstituted heteroarylene; Ar₁ and Ar₂ are same or different, and are independently selected from substituted or unsubstituted aryl; and at least one of R₁, R₂, R₃, R₄, R₅, R₆, R₇, R₈, L₁, L₂, Ar₁ and Ar₂ contains deuterium.

In some embodiments, in a case where the host material is a deuterated material, a mass fraction of deuterium in the host material is greater than or equal to 1.0% and less than or equal to 4.9%.

In some embodiments, the guest material is selected from structures represented by a following general formula (II).

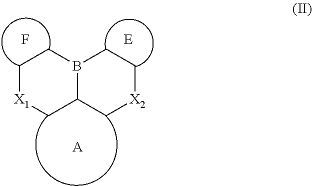

Here, A, E and F are same or different, and are independently selected from a substituted or unsubstituted aromatic ring, a substituted or unsubstituted heteroaromatic ring, and substituted or unsubstituted cycloalkane; in a case where A, E and F are each selected from a substituted aromatic ring, a substituted heteroaromatic ring and substituted cycloalkane, a substituent is connected to an adjacent substituent to form a substituted or unsubstituted ring; X₁ and X₂ are same or different, and are independently selected from O, N(Rₐ) and C(R_{b}R_{c}); Rₐ, R_{b} and R_{c} are same or different, and are independently selected from hydrogen, deuterium, halogen, cyano, substituted or unsubstituted alkyl, substituted or unsubstituted silyl, substituted or unsubstituted alkoxy, substituted or unsubstituted aryl and substituted or unsubstituted heterocyclic; and at least one of A, E and F contains deuterium.

In some embodiments, a substituent of at least one of A, E, and F includes tert-butyl.

In some embodiments, in a case where the guest material is a deuterated material, a mass fraction of deuterium in the guest material is greater than or equal to 0.1% and less than or equal to 8.5%.

In some embodiments, the first functional material is selected from structures represented by a following general formula (III).

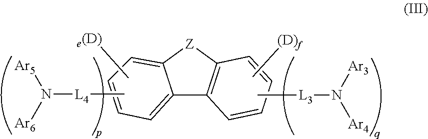

Here, Z is selected from O, S, N(Rₐ) and C(RₑR_{f}); R_{d}, Rₑ, and R_{f} are same or different, and are independently selected from substituted or unsubstituted alkyl, substituted or unsubstituted aryl, and substituted or unsubstituted heteroaryl; L₃ and L₄ are same or different, and are independently selected from a single bond, substituted or unsubstituted arylidene, and substituted or unsubstituted heteroarylene; e and f are same or different, and are independently selected from 1, 2, 3 and 4; Ar₃, Ar₄, Ar₅ and Ar₆ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S; p and q are same or different, and are independently selected from 0, 1 and 2, and a sum of p and q is greater than or equal to 1 and less than or equal to 2.

In some embodiments, the first functional material is selected from structures represented by a following general formula (III-A);

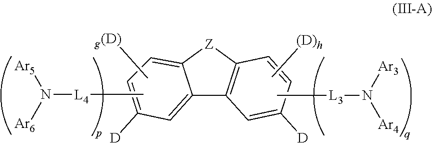

Here, g and h are same or different, and are independently selected from 0, 1, 2 and 3.

In some embodiments, the first functional material is selected from structures represented by a following general formula (IV);

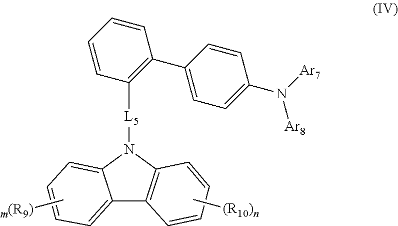

Here, L₅ is selected from a single bond, and substituted or unsubstituted C6-C60 arylene; Ar₇ and Ar₈ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S; R₉ and R₁₀ are same or different, and are independently selected from hydrogen, deuterium, halogen, cyano, nitro, amino, substituted or unsubstituted C1-C60 alkyl, substituted or unsubstituted C3-C60 cycloalkyl, substituted or unsubstituted C2-C60 alkenyl, substituted or unsubstituted C6-C60 aryl, and substituted or unsubstituted C2-C60 heteroaryl; or R₉ and R₁₀ are each connected to an adjacent substituent to form a substituted or unsubstituted ring; the C2-C60 heteroaryl includes at least one heteroatom, and the heteroatom includes N, O and S; m and n are same or different, and are independently selected from 1, 2, 3 and 4; at least one R₉ is deuterium; and at least one R₁₀ is deuterium.

In some embodiments, in a case where the first functional material is a deuterated material, a mass fraction of deuterium in the first functional material is greater than or equal to 0.15% and less than or equal to 5.50%.

In some embodiments, the light-emitting device comprises at least two light-emitting units, and the at least two light-emitting units are arranged in sequence. The light-emitting device further includes a charge generation layer located between two adjacent light-emitting units. The charge generation layer includes a hole generation layer and an electron generation layer that are stacked, and the electron generation layer is closer to the anode than the hole generation layer.

In some embodiments, a structural formula of the second functional material is as follows.

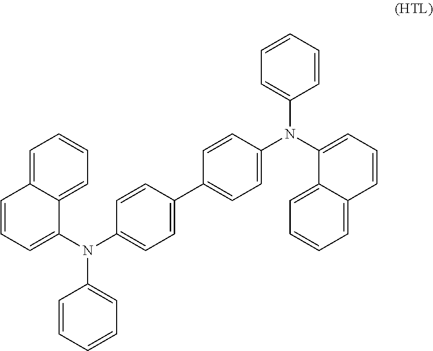 [SMILES: c1ccc(N(c2ccc(-c3ccc(N(c4ccccc4)c4cccc5ccccc45)cc3)cc2)c2cccc3ccccc23)cc1]

In some embodiments, the light-emitting device is configured to emit light of a first wavelength, and the light of the first wavelength is blue light.

In another aspect, a display panel is provided. The display panel includes a plurality of light-emitting devices each as described in any of the above embodiments and a plurality of pixel driving circuits. A pixel driving circuits is electrically connected to a light-emitting device, and is used to drive the light-emitting device to emit light.

In yet another aspect, a display panel is provided. The display panel includes a substrate and a plurality of light-emitting devices. The plurality of light-emitting devices are arranged on the substrate and arranged in a first direction, and the first direction is parallel to a plane where the substrate is located. The plurality of light-emitting devices include at least one first light-emitting device, at least one second light-emitting device and at least one third light-emitting device, the first light-emitting device is configured to emit blue light, the second light-emitting device is configured to emit green light, and the third light-emitting device is configured to emit red light. Each light-emitting device of the plurality of light-emitting devices includes: a cathode and an anode that are arranged opposite to each other, and at least one light-emitting unit arranged between the cathode and the anode; a light-emitting unit of the at least one light-emitting unit includes a light-emitting layer; a number of light-emitting units included in each light-emitting device of the plurality of light-emitting devices is n, where n is a positive integer greater than or equal to 1. A thickness of a light-emitting layer of an N-th light-emitting unit of the third light-emitting device is greater than a thickness of a light-emitting layer of an N-th light-emitting unit of the second light-emitting device, and the thickness of the light-emitting layer of the N-th light-emitting unit of the second light-emitting device is greater than a thickness of a light-emitting layer of an N-th light-emitting unit of the first light-emitting device, wherein N is a positive integer less than or equal to n.

In some embodiments, a difference between the thickness of the light-emitting layer of the N-th light-emitting unit of the third light-emitting device and the thickness of the light-emitting layer of the N-th light-emitting unit of the first light-emitting device is a first thickness difference, a difference between the thickness of the light-emitting layer of the N-th light-emitting unit of the second light-emitting device and the thickness of the light-emitting layer of the N-th light-emitting unit of the first light-emitting device is a second thickness difference, and a difference between the thickness of the light-emitting layer of the N-th light-emitting unit of the third light-emitting device and the thickness of the light-emitting layer of the N-th light-emitting unit of the second light-emitting device is a third thickness difference. A ratio of the first thickness difference to the second thickness difference is greater than or equal to 1.5 and less than or equal to 2, and a ratio of the third thickness difference to the second thickness difference is greater than or equal to 1 and less than or equal to 1.5.

In some embodiments, the light-emitting unit further includes a first type of functional layer disposed on a side of the light-emitting layer proximate to the anode; the first type of functional layer includes a first functional sub-layer in contact with the light-emitting layer. A difference between a thickness of a first functional sub-layer of the N-th light-emitting unit of the third light-emitting device and a thickness of a first functional sub-layer of the N-th light-emitting unit of the first light-emitting device is a fourth thickness difference, and a difference between a thickness of a first functional sub-layer of the N-th light-emitting unit of the second light-emitting device and a thickness of a first functional sub-layer of the N-th light-emitting unit of the first light-emitting device is a fifth thickness difference; a ratio of the fourth thickness difference to the fifth thickness difference is greater than or equal to 1.1 and less than or equal to 1.5.

In some embodiments, the light-emitting unit further includes a second type of functional layer disposed on a side of the light-emitting layer proximate to the cathode; a ratio of a thickness of the first type of functional layer to a thickness of the second type of functional layer is greater than or equal to 1 and less than or equal to 5.

In some embodiments, a material of the light-emitting layer includes a guest material, and the guest material is configured to emit light of a set wavelength. A relative molecular weight of the guest material of the light-emitting layer of the first light-emitting device is greater than or equal to 650 and less than or equal to 1300; and/or a relative molecular weight of the guest material of the light-emitting layer of the second light-emitting device is greater than or equal to 700 and less than or equal to 1400; and/or a relative molecular weight of the guest material of the light-emitting layer of the third light-emitting device is greater than or equal to 700 and less than or equal to 1500.

In some embodiments, an absolute value of a difference between the relative molecular weight of the guest material of the light-emitting layer of the third light-emitting device and the relative molecular weight of the guest material of the light-emitting layer of the first light-emitting device is less than or equal to 600; and/or an absolute value of a difference between the relative molecular weight of the guest material of the light-emitting layer of the second light-emitting device and the relative molecular weight of the guest material of the light-emitting layer of the first light-emitting device is less than or equal to 500.

In some embodiments, a difference between the relative molecular weight of the guest material of the light-emitting layer of the third light-emitting device and the relative molecular weight of the guest material of the light-emitting layer of the first light-emitting device is a first relative molecular weight difference, and a difference between the relative molecular weight of the guest material of the light-emitting layer of the second light-emitting device and the relative molecular weight of the guest material of the light-emitting layer of the first light-emitting device is a second relative molecular weight difference. A ratio of an absolute value of the first relative molecular weight difference to an absolute value of the second relative molecular weight difference is greater than or equal to 0.5 and less than or equal to 6.

In some embodiments, an optical path length of light in the light-emitting layer of the light-emitting unit proximate to the anode of the first light-emitting device and the first type of functional layer is a first optical path length; an optical path length of light in the light-emitting layer of the light-emitting unit proximate to the anode of the second light-emitting device and the first type of functional layer is a second optical path length; an optical path length of light in the light-emitting layer of the light-emitting unit proximate to the anode of the third light-emitting device and the first type of functional layer is a third optical path length. A ratio of the third optical path length to the second optical path length is greater than or equal to 1.1 and less than or equal to 1.25; a ratio of the third optical path length to the first optical path length is greater than or equal to 1.25 and less than or equal to 1.45; a ratio of the second optical path length to the first optical path length is greater than or equal to 1.05 and less than or equal to 1.25.

In some embodiments, the light-emitting device includes a first light-emitting unit and a second light-emitting unit; the first light-emitting unit is closer to the anode than the second light-emitting unit. A ratio of a thickness of a light-emitting layer of the first light-emitting unit to a thickness of a light-emitting layer of the second light-emitting unit is greater than or equal to 0.8 and less than or equal to 1.5.

In some embodiments, in a case where the light-emitting unit includes a first type of functional layer and a second type of functional layer, the first type of functional layer further includes a second functional sub-layer and a fourth functional sub-layer, and the fourth functional sub-layer, the second functional sub-layer and the first functional sub-layer are sequentially arranged in a direction away from the anode; the second type of functional layer includes a third functional sub-layer, a fifth functional sub-layer and a sixth functional sub-layer, and the sixth functional sub-layer, the fifth functional sub-layer and the third functional sub-layer are sequentially arranged in a direction away from the cathode. A sum of a thickness of a second functional sub-layer of the second light-emitting unit and a thickness of a fifth functional sub-layer is a first thickness sum, and a sum of a thickness of a second functional sub-layer of the first light-emitting unit and a thickness of a fifth functional sub-layer is a second thickness sum; a ratio of the first thickness sum to the second thickness sum is greater than or equal to 2 and less than or equal to 4.

In some embodiments, a sum of a thickness of a second functional sub-layer of the second light-emitting unit and a thickness of a fifth functional sub-layer is a first thickness sum, and a sum of a thickness of a second functional sub-layer of the first light-emitting unit and a thickness of a fifth functional sub-layer is a second thickness sum; a ratio of the first thickness sum to the second thickness sum is greater than or equal to 2 and less than or equal to 5.

In some embodiments, a sum of a thickness of a third functional sub-layer of the second light-emitting unit and the thickness of the fifth functional sub-layer of the second light-emitting unit is a fifth thickness sum, and a sum of a thickness of a third functional sub-layer of the first light-emitting unit and the thickness of the fifth functional sub-layer of the first light-emitting unit is a sixth thickness sum; a ratio of the fifth thickness sum to the sixth thickness sum is greater than or equal to 1.5 and less than or equal to 3.

In some embodiments, in a case where the first type of functional layer further includes a second functional sub-layer, a material of the light-emitting layer includes a host material and a guest material, a material of the first functional sub-layer includes a first functional material, and a material of the second functional sub-layer includes a second functional material. An overlap rate of density of states for HOMO of the first functional material and density of states for HOMO of the second functional material is greater than 0% and less than or equal to 90%; and/or an overlap rate of the density of states for HOMO of the first functional material and density of states for HOMO of the host material is greater than 0% and less than or equal to 90%.

In some embodiments, at least one of the host material, the guest material and the first functional material is a deuterated material.

In some embodiments, an absolute value of a difference between an electron reorganization energy of the host material and a hole reorganization energy of the host material is less than or equal to 0.1 eV; and/or a hole mobility of the host material is greater than an electron mobility of the host material.

In some embodiments, a dipole moment of the first functional material is greater than 0 D.

In some embodiments, a lowest bond dissociation energy of bond dissociation energies of the first functional material in a ground state is greater than or equal to 2.40 eV; and/or a lowest bond dissociation energy of bond dissociation energies of the first functional material in an anionic state is greater than or equal to 1.0 eV.

In some embodiments, a lowest bond dissociation energy of bond dissociation energies of the host material in a ground state is greater than or equal to 1.50 eV; and/or a lowest bond dissociation energy of bond dissociation energies of the guest material in a ground state is greater than or equal to 1.50 eV.

In some embodiments, a triplet energy level of the host material is less than a triplet energy level of the guest material; and/or a singlet energy level of the host material is greater than a singlet energy level of the guest material.

In some embodiments, in a case where the light-emitting unit further includes a third functional sub-layer, the third functional sub-layer is in contact with the light-emitting layer, and a material of the third functional sub-layer includes a third functional material. A triplet energy level of the host material is greater than a triplet energy level of the third functional material; and/or the triplet energy level of the host material is less than a triplet energy level of the first functional material.

In some embodiments, the host material is selected from structures represented by a following general formula (I);

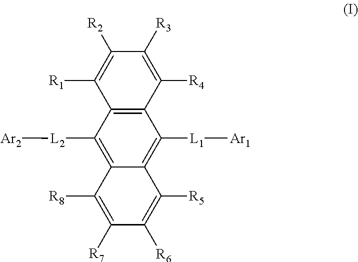

R₁, R₂, R₃, R₄, R₅, R₆, R₇ and R₈ are same or different, and are independently selected from hydrogen, deuterium, substituted or unsubstituted alkyl, substituted or unsubstituted alkoxy, substituted or unsubstituted aryl, substituted or unsubstituted aryloxy, substituted or unsubstituted diarylamino, substituted or unsubstituted siloxane and substituted or unsubstituted silyl; L₁ and L₂ are same or different, and are independently selected from a single bond, substituted or unsubstituted arylene and substituted or unsubstituted heteroarylene; Ar₁ and Ar₂ are same or different, and are independently selected from substituted or unsubstituted aryl; and at least one of R₁, R₂, R₃, R₄, R₅, R₆, R₇, R₈, L₁, L₂, Ar₁ and Ar₂ contains deuterium.

In some embodiments, in a case where the host material is a deuterated material, a mass fraction of deuterium in the host material is greater than or equal to 1.0% and less than or equal to 4.9%.

In some embodiments, the guest material is selected from structures represented by a following general formula (II);

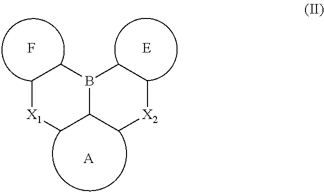

A, E and F are same or different, and are independently selected from a substituted or unsubstituted aromatic ring, a substituted or unsubstituted heteroaromatic ring, and substituted or unsubstituted cycloalkane; in a case where A, E and F are each selected from a substituted aromatic ring, a substituted heteroaromatic ring and substituted cycloalkane, a substituent is connected to an adjacent substituent to form a substituted or unsubstituted ring; X₁ and X₂ are same or different, and are independently selected from O, N(Rₐ) and C(R_{b}R_{c}); Rₐ, R_{b} and R_{c} are same or different, and are independently selected from hydrogen, deuterium, halogen, cyano, substituted or unsubstituted alkyl, substituted or unsubstituted silyl, substituted or unsubstituted alkoxy, substituted or unsubstituted aryl and substituted or unsubstituted heterocyclic; and at least one of A, E and F contains deuterium.

In some embodiments, a substituent of at least one of A, E, and F includes tert-butyl.

In some embodiments, in a case where the guest material is a deuterated material, a mass fraction of deuterium in the guest material is greater than or equal to 0.1% and less than or equal to 8.5%.

In some embodiments, the first functional material is selected from structures represented by a following general formula (III).

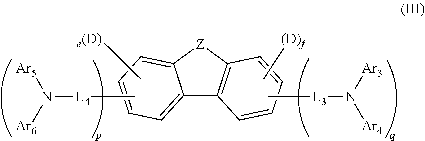

Here, Z is selected from O, S, N(Rₐ) and C(RₑR_{f}); R_{d}, Rₑ, and R_{f} are same or different, and are independently selected from substituted or unsubstituted alkyl, substituted or unsubstituted aryl, and substituted or unsubstituted heteroaryl; L₃ and L₄ are same or different, and are independently selected from a single bond, substituted or unsubstituted arylidene, and substituted or unsubstituted heteroarylene; e and f are same or different, and are independently selected from 1, 2, 3 and 4; Ar₃, Ar₄, Ar₅ and Ar₆ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S; p and q are same or different, and are independently selected from 0, 1 and 2, and a sum of p and q is greater than or equal to 1 and less than or equal to 2.

In some embodiments, the first functional material is selected from structures represented by a following general formula (III-A);

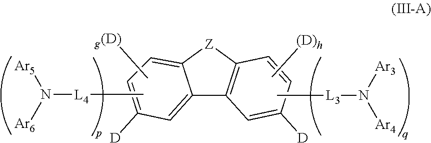

Here, g and h are same or different, and are independently selected from 0, 1, 2 and 3.

In some embodiments, the first functional material is selected from structures represented by a following general formula (IV).

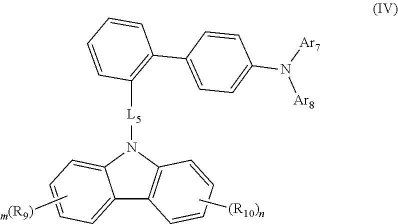

Here, L₅ is selected from a single bond, and substituted or unsubstituted C6-C60 arylene; Ar₇ and Ar₈ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S; R₉ and R₁₀ are same or different, and are independently selected from hydrogen, deuterium, halogen, cyano, nitro, amino, substituted or unsubstituted C1-C60 alkyl, substituted or unsubstituted C3-C60 cycloalkyl, substituted or unsubstituted C2-C60 alkenyl, substituted or unsubstituted C6-C60 aryl, and substituted or unsubstituted C2-C60 heteroaryl; or R₉ and R₁₀ are each connected to an adjacent substituent to form a substituted or unsubstituted ring; the C2-C60 heteroaryl includes at least one heteroatom, and the heteroatom includes N, O and S; m and n are same or different, and are independently selected from 1, 2, 3 and 4; at least one R₉ is deuterium; and at least one R₁₀ is deuterium.

In some embodiments, in a case where the first functional material is a deuterated material, a mass fraction of deuterium in the first functional material is greater than or equal to 0.15% and less than or equal to 5.50%.

In some embodiments, the light-emitting device comprises at least two light-emitting units, and the at least two light-emitting units are arranged in sequence. The light-emitting device further includes a charge generation layer located between two adjacent light-emitting units; the charge generation layer includes a hole generation layer and an electron generation layer that are stacked, and the electron generation layer is closer to the anode than the hole generation layer.

In some embodiments, a structural formula of the second functional material is as follows.

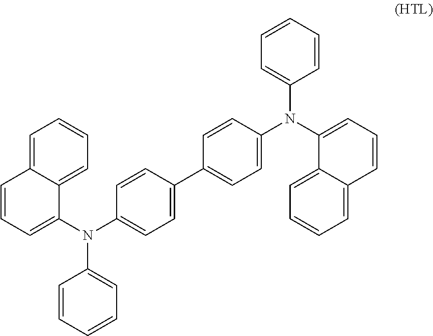 [SMILES: c1ccc(N(c2ccc(-c3ccc(N(c4ccccc4)c4cccc5ccccc45)cc3)cc2)c2cccc3ccccc23)cc1]

In some embodiments, the host material is a host material of a light-emitting layer of the first light-emitting device; the guest material is a guest material of a light-emitting layer of the first light-emitting device; the first functional material is a material of a first functional sub-layer of the first light-emitting device; and the second functional material is a material of a second functional sub-layer of the first light-emitting device. In a case where the light-emitting unit further includes a third functional sub-layer, a third functional material is a material of a third functional sub-layer of the first light-emitting device.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a structural diagram of another display panel, in accordance with some embodiments;

FIG. 4 is a structural diagram of yet another display panel, in accordance with some embodiments;

FIG. 5 is a structural diagram of yet another display panel, in accordance with some embodiments;

FIG. 6 is a structural diagram of a light-emitting device, in accordance with some embodiments;

FIG. 7 is a structural diagram of another light-emitting device, in accordance with some embodiments;

FIG. 8 is a structural diagram of yet another display panel, in accordance with some embodiments;

FIG. 9 is a structural diagram of yet another light-emitting device, in accordance with some embodiments;

FIG. 10 is a structural diagram of yet another display panel, in accordance with some embodiments;

FIG. 11 is a diagram showing variation of exciton intensity at different positions in a light-emitting layer, in accordance with some embodiments;

FIG. 12 is a molecular filling diagram during simulation calculation of density of states, in accordance with some embodiments;

FIG. 13 is a distribution diagram of density of states of a material of an electron blocking layer and a material of a hole transport layer, in accordance with some embodiments;

FIG. 14 is a diagram illustrating a process of generating singlet excitons during triplet-triplet fusion, in accordance with some embodiments;

FIG. 15 is a diagram showing changes in bond dissociation energy before and after deuteration of a material, in accordance with some embodiments;

FIG. 16 is a structural diagram of yet another light-emitting device, in accordance with some other embodiments; and

FIG. 17 is a structural diagram of yet another display panel, in accordance with some other embodiments.

### DESCRIPTION OF THE INVENTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, a feature defined with “first” and “second” may explicitly or implicitly include one or more of the features. In the description of the embodiments of the present disclosure, the terms “a plurality of”, “the plurality of” and “multiple” each mean two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially”, or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

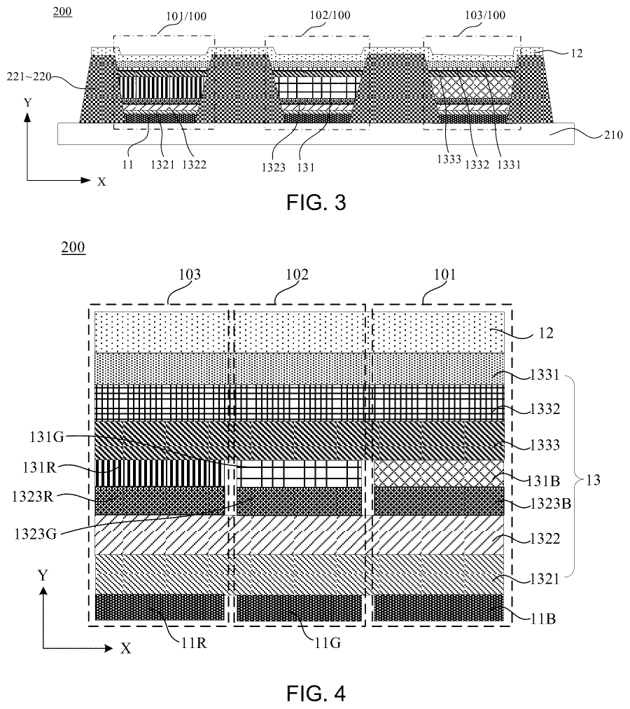

It will be noted that, for example, “11~1” shown in the accompanying drawings of the present disclosure indicates that Component 11 belongs to Component 1; for example, “221~220” shown in FIG. 2 indicates that the pixel definition layer 221 belongs to the light-emitting functional layer 220, and other similar signs shown in the accompanying drawings also follow the above description. The sign such as “1/2” shown in the accompanying drawings of the present disclosure indicates that both Structure 1 and Structure 2 refer to this structure; for example, “101/100” shown in FIG. 3 indicates that both First light-emitting device 101 and Light-emitting device 100 refer to this structure, and other similar signs appearing in the drawings also follow the above description.

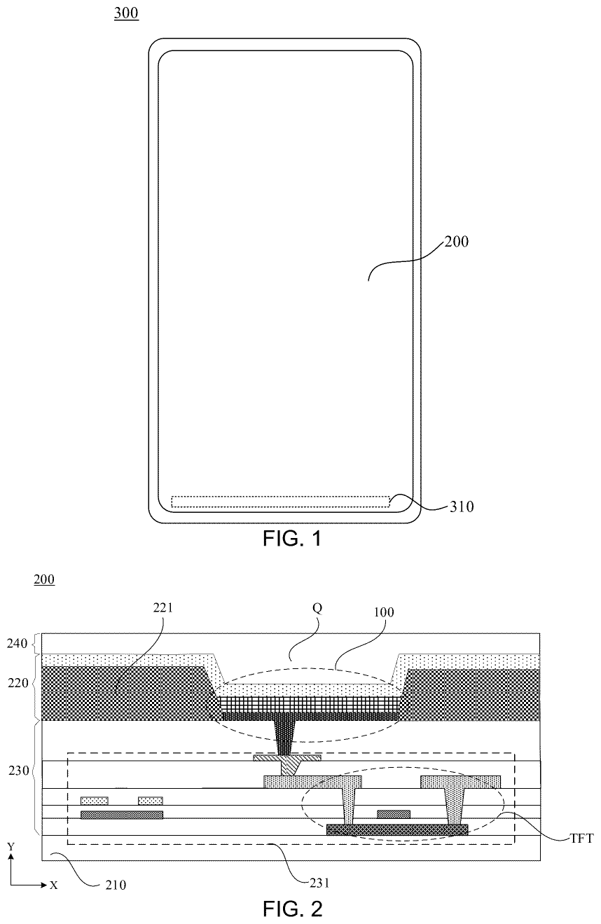

As shown in FIG. 1, some embodiments of the present disclosure provide a display apparatus 300, and the display apparatus 300 includes a display panel 200.

The display apparatus 300 may be an organic light-emitting diode (OLED) display apparatus 300.

For example, as shown in FIG. 1, the display apparatus 300 further includes a driver chip 310. The driver chip 310 is used to drive the display panel 200 to perform display.

In addition, the display apparatus 300 may further include an under-screen camera, an under-screen fingerprint recognition sensor and the like, so that the display apparatus 300 is able to implement various functions such as taking pictures, video recording, fingerprint recognition, or face recognition.

The display apparatus 300 may be any apparatus that displays images whether in motion (e.g., videos) or stationary (e.g., static images), and whether textual or graphical. More specifically, it is expected that the display apparatus 300 in the embodiments may be implemented in or associated with various electronic devices, which include (but is not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, a building structure, a packaging and aesthetic structure (e.g., a display for an image of a piece of jewelry).

In some embodiments, as shown in FIG. 2, the display panel 200 includes a substrate 210 and a light-emitting functional layer 220 disposed on the substrate 210; the light-emitting functional layer 220 includes a plurality of light-emitting devices 100, and the plurality of light-emitting devices 100 are arranged in a first direction X, and the first direction X is parallel to a plane where the substrate 210 is located.

For example, the substrate 210 may be a transparent substrate. A material of the substrate 210 may be a rigid material, such as glass; alternatively, the material of the substrate 210 may be a flexible material, such as polyimide.

In some examples, as shown in FIG. 2, the display panel 200 further includes an array layer 230 disposed between the substrate 210 and the light-emitting functional layer 220, and the array layer 230 includes a plurality of pixel driving circuits 231; the pixel driving circuit 231 includes a plurality of transistors TFT. Each pixel driving circuit 231 is electrically connected to a light-emitting device 100, and is used to drive the light-emitting device 100 to emit light.

For example, in the display panel 200, the pixel driving circuit 231 generates a driving current. Each light-emitting device 100 emits light due to the driving action of the driving current generated by the corresponding pixel driving circuits 231, and the light emitted by the plurality of the light-emitting devices 100 cooperates with each other, so that the display panel 200 realizes the display function.

In some examples, as shown in FIG. 2, the display panel 200 further includes an encapsulation layer 240; the array layer 230, the light-emitting functional layer 220, and the encapsulation layer 240 are stacked on the substrate 210, and the array layer 230, the light-emitting functional layer 220, and the encapsulation layer 240 are arranged in sequence in a direction away from the substrate 210.

For example, the display panel 200 may be an OLED display panel; in this case, the encapsulation layer 240 covers the light-emitting devices 100, and the light-emitting devices 100 are wrapped, so as to prevent a service life of the OLED display panel 200 from being shortened due to damage of an organic material of the light-emitting device 100 caused by a case that moisture and oxygen in an external environment enter the display panel 200.

In some embodiments, as shown in FIGS. 2 and 3, in the display panel 200, the light-emitting functional layer 220 further includes a pixel definition layer 221 disposed on a side of the substrate 210; the pixel definition layer 221 has a plurality of openings Q, and the plurality of light-emitting devices 100 may be disposed in one-to-one correspondence with the plurality of openings Q.

In some embodiments, as shown in FIGS. 3 to 5, the plurality of light-emitting devices 100 of the display panel 200 include a first light-emitting device 101, a second light-emitting device 102 and a third light-emitting device 103. Due to the action of the driving voltage, the first light-emitting device 101 is configured to emit light of a first wavelength, which is blue light. The second light-emitting device 102 is configured to emit light of a second wavelength, which is green light. The third light-emitting device 103 is configured to emit light of a third wavelength, which is red light.

The plurality of light-emitting device 100 include a first light-emitting device 101, a second light-emitting device 102 and a third light-emitting device 103. Thus, it is possible to respectively adjust the luminance (gray scale) of the first light-emitting device 101, the second light-emitting device 102, and the third light-emitting device 103 to achieve the display of multiple colors through color combination and superposition, so that full-color display of the display panel 200 is achieved.

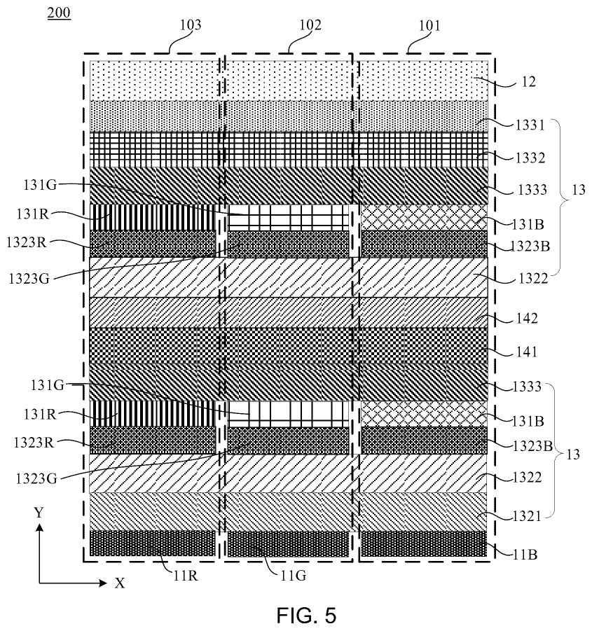

It will be noted that FIGS. 4 and 5 are simplified schematic diagrams obtained after removing other film layers in the display panel 200 except the film layers related to the light-emitting device 100. In FIGS. 4 and 5, multiple light-emitting devices 100 are, for example, a first light-emitting device 101, a second light-emitting device 102 and a third light-emitting device 103.

In some embodiments, as shown in FIGS. 3 to 7, the light-emitting device 100 includes: an anode 11 and a cathode 12 that are arranged in sequence, and at least one light-emitting unit 13 disposed between the anode 11 and the cathode 12. The light-emitting unit 13 includes a light-emitting layer 131.

During operation, voltages are applied to the anode 11 and the cathode 12 respectively to generate an electric field therebetween, which may drive holes in the anode 11 and electrons in the cathode 12 to recombine in the light-emitting layer 131 to emit light.

In some examples, as shown in FIG. 3, the anode 11 may be located on a side of the light-emitting unit 13 proximate to the substrate 210, and the cathode 12 may be located on a side of the light-emitting unit 13 away from the substrate 210. In some other examples, the anode 11 may be located on a side of the light-emitting unit 13 away from the substrate 210, and the cathode 12 may be located on a side of the light-emitting unit 13 proximate to the substrate 210.

For example, in order to ensure that the light-emitting device 100 is capable of emitting light effectively, the anode 11 may be made of a material with a high work function, so that the holes in the anode 11 is able to effectively move to the light-emitting layer 131 of the light-emitting unit 13 due to the driving of the electric field to recombine with the electrons in the cathode 12 to emit light. The material of the anode 11 may be a transparent conductive metal oxide material. For example, the material of the anode 11 may be indium tin oxide (ITO) or indium zinc oxide (IZO). Alternatively, the anode 11 may be a composite electrode including multiple materials; for example, the material of the anode 110 may be ITO/Ag/ITO, Ag/IZO, CNT/ITO, CNT/IZO, GO/ITO or GO/IZO, where Ag is silver, CNT is carbon nanotube, and GO is graphene oxide.

In some examples, the cathode 12 may be made of a material with a low work function, so that the electrons of the cathode 12 may be more easily injected into the target film layer (e.g., an electron injection layer 1331, the description of the electron injection layer 1331 will be made in the following content, which will not be repeated here). In this way, the electrons in the cathode 12 may effectively move to the light-emitting layer 131 of the light-emitting unit 13 due to the driving of the electric field to recombine with the holes in the anode 11 to emit light. In addition, the cathode 12 also needs to have good light transmittance and conductivity. The material of the cathode 12 may be a metal material, metal oxide or metal alloy, such as aluminum (Al), silver (Ag), gold (Au), magnesium (Mg), calcium (Ca), ytterbium (Yb), indium (In), lithium (Li), potassium (K), sodium (Na), tin (Sn), titanium (Ti), lead (Pb), samarium (Sm), yttrium (Y), indium tin oxide (ITO), magnesium silver alloy (Mg:Ag), ytterbium gold alloy (Yb:Au), ytterbium silver alloy (Yb:Ag), lithium aluminum alloy (Li:Al) or lithium calcium magnesium alloy (Li:Ca:Al). Alternatively, the material of cathode 12 may be a laminated material, such as magnesium/aluminum (Mg/AI), magnesium/silver (Mg/Ag), aluminum/silver (Al/Ag), aluminum/gold (Al/Au), ytterbium/gold (Yb/Au), ytterbium/silver (Yb/Ag), calcium/magnesium (Ca/Mg), calcium/silver (Ca/Ag), or barium/silver (Ba/Ag).

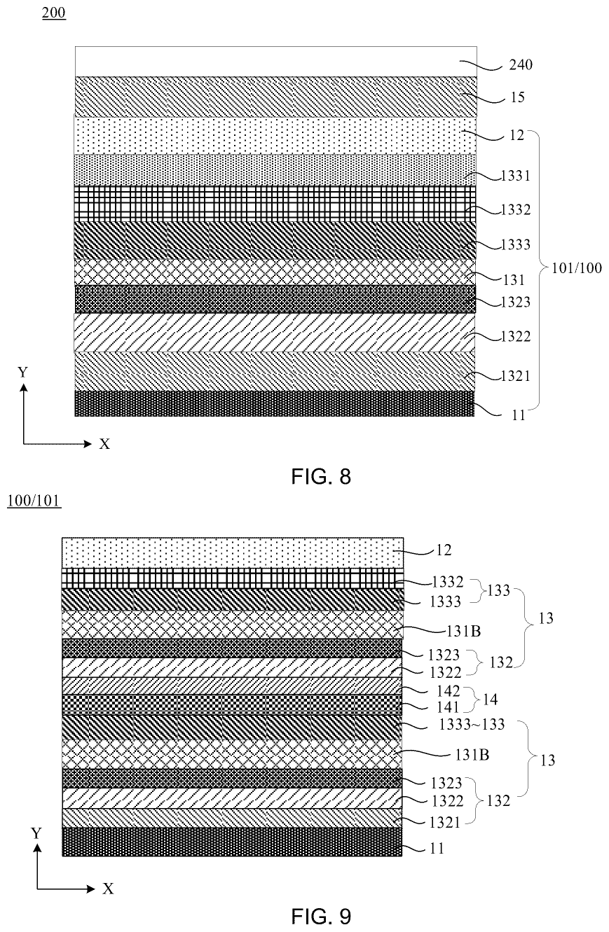

In some embodiments, as shown in FIG. 8, in the display panel 200, a covering layer 15 is provided between the encapsulation layer 240 and the cathode 12. A material forming the covering layer 15 is, for example, a material having a high refractive index. By providing the covering layer 15, it is possible to improve the light extraction efficiency of the light-emitting device 100 due to the property of high refractive index of the material, thereby improving the efficiency and luminance of the light-emitting device 100 when lit.

It will be noted that FIG. 8 is a simplified schematic diagram obtained after removing the other film layers in the display panel 200 except the film layers related to the light-emitting device 100. In FIG. 8, the light-emitting device 100 is, for example, the first light-emitting device 101.

In some examples, the structural formula of the material of the covering layer 15 may be shown in the following formula.

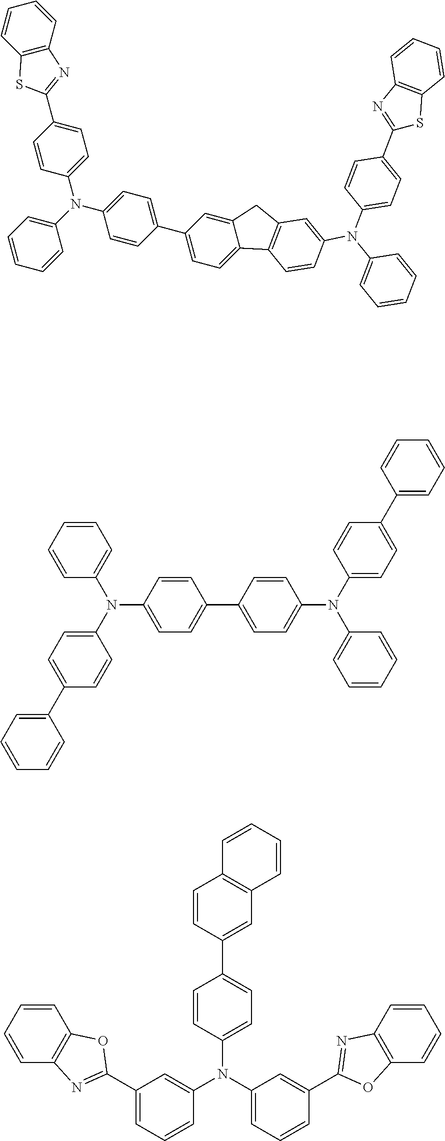 [SMILES: c1ccc(N(c2ccc(-c3ccc4c(c3)Cc3cc(N(c5ccccc5)c5ccc(-c6nc7ccccc7s6)cc5)ccc3-4)cc2)c2ccc(-c3nc4ccccc4s3)cc2)cc1 ; c1ccc(-c2ccc(N(c3ccccc3)c3ccc(-c4ccc(N(c5ccccc5)c5ccc(-c6ccccc6)cc5)cc4)cc3)cc2)cc1 ; c1cc(-c2nc3ccccc3o2)cc(N(c2ccc(-c3ccc4ccccc4c3)cc2)c2cccc(-c3nc4ccccc4o3)c2)c1]

In some examples, as shown in FIGS. 3, 4, 6, and 8, the light-emitting device 100 includes one light-emitting unit 13. In this case, the light-emitting device 100 is of a single-layer light-emitting device, and the anode 11, the light-emitting unit 13, and the cathode 12 are stacked in a second direction Y, the second direction Y and the first direction X intersect. In some other examples, as shown in FIGS. 5, 7, 9, and 10, the light-emitting device 100 includes a plurality of (e.g. two) light-emitting units 13 that are stacked; in this case, the light-emitting device 100 is of a tandem light-emitting device, and the anode 11, the plurality of light-emitting units 13, and the cathode 12 are stacked in the second direction Y.

For example, as shown in FIGS. 3 to 10, the second direction Y is perpendicular to the first direction X.

In some embodiments, as shown in FIGS. 5, 7, 9 and 10, in a case where the light-emitting device 100 includes a plurality of light-emitting units 13, i.e., the light-emitting device 100 includes at least two light-emitting units 13, the light-emitting device 100 further includes a charge generation layer 14, and the charge generation layer 14 is located between two adjacent light-emitting units 13 of the plurality of light-emitting units 13.

Due to the provision of the charge generation layer 14, the plurality of light-emitting units 13 may be connected in sequence in a direction (e.g., the second direction Y) perpendicular to the light exit surface. Moreover, the charge generation layer 14 in the tandem OLED light-emitting device 100 not only plays the role of connecting the light-emitting units 13, but also helps to improve the generation efficiency of charges (holes or electrons), which may have a significant impact on the performance of the light-emitting device 100.

In some examples, as shown in FIGS. 5, 7, 9 and 10, the charge generation layer 14 includes an electron generation layer 141 and a hole generation layer 142 that are stacked; the electron generation layer 141 is closer to the anode 11 than the hole generation layer 142.

For example, the electron generation layer 141 may be referred to as an N-type charge generation layer. A thickness of the electron generation layer 141 may be in a range of 15 nm to 25 nm, inclusive. The material of the electron generation layer 141 may be an electronic material, such as an electronic material containing phenolamine or phosphonoxy group. In some examples, the electron generation layer 141 contains a dopant, and the dopant may be an alkali metal, an alkaline earth metal, and an oxide thereof. The alkali metal is, for example, lithium (Li), sodium (Na), potassium (K), or cesium (Cs); the alkaline earth metal is, for example, magnesium (Mg), strontium (Sr), barium (Ba), or radium (Ra).

For example, the hole generation layer 142 may also be referred to as a P-type charge generation layer. The thickness of the hole generation layer 142 may be in a range of 5 nm to 15 nm, inclusive. The material of the hole generation layer 142 may be a hole-type material, such as N,N′-Bis-(1-naphthalenyl)-N,N′-bis-phenyl-(1,1′-biphenyl)-4,4′-diamine (NPB) or N,N′-Bis(3-methylphenyl)-N,N′-bis(phenyl)benzidine (TPD). In some examples, the hole generation layer 142 contains a dopant, such as 2,3,6,7,10,11-hexacyano-1,4,5,8,9,12-hexaazatriphenylene (HATCN) or 2,3,5,6-tetrafluoro-7,7,8,8-tetracyanoquinodimethane (F4TCNQ).

In some embodiments, as shown in FIGS. 3 to 10, in order to improve the luminous efficiency of the light-emitting device 100, the light-emitting unit 13 further includes a hole transport functional layer 132, which is located on a side of the light-emitting layer 131 proximate to the anode 11 and in contact with the light-emitting layer 131. The hole transport functional layer 132 includes, for example, at least one of a hole injection layer (HIL) 1321, a hole transport layer (HTL) 1322, and an electron blocking layer (EBL) 1323 that are stacked. In the case where the hole transport functional layer 132 includes the hole injection layer 1321, the hole transport layer 1322 and the electron blocking layer 1323, the hole injection layer 1321, the hole transport layer 1322 and the electron blocking layer 1323 are sequentially stacked in a direction away from the anode 11, and the electron blocking layer 1323 is in contact with the light-emitting layer 131.

In some embodiments, as shown in FIGS. 3 to 10, in order to improve the luminous efficiency of the light-emitting device 100, the light-emitting unit 13 further includes an electron transport functional layer 133, which is located on a side of the light-emitting layer 131 proximate to the cathode 12 and in contact with the light-emitting layer 131. The electron transport functional layer 133 includes, for example, at least one of an electron injection layer (EIL) 1331, an electron transport layer (ETL) 1332, and a hole blocking layer (EBL) 1333 that are stacked. In the case where the electron transport functional layer 133 includes the electron injection layer 1331, the electron transport layer 1332 and the hole blocking layer 1333, the electron injection layer 1331, the electron transport layer 1332 and the hole blocking layer 1333 are sequentially stacked in a direction away from the cathode 12, and the hole blocking layer 1333 is in contact with the light-emitting layer 131.

The provision of the hole injection layer 1321, the hole transport layer 1322, the electron blocking layer 1323, the electron injection layer 1331, the electron transport layer 1332, and the hole blocking layer 1333 is equivalent to provide a transitional step between the anode 11 and the light-emitting layer 131 and provide a transitional step between the cathode 12 and the light-emitting layer 131, which reduces the barrier height that carrier transition needs to overcome, so that the luminous efficiency is improved.

For example, the hole transport functional layer 132 is configured to transport holes, and/or block electrons and excitons generated in the light-emitting unit 131. For example, the hole injection layer 1321 is configured to reduce the hole injection barrier to improve the hole injection efficiency; the hole transport layer 1322 may be configured to transport holes; the electron blocking layer 1323 is configured to transport holes and block electrons and excitons generated in the light-emitting layer 131.

For example, the electron transport functional layer 133 is configured to transport electrons, and/or block holes and excitons generated in the light-emitting layer 131.

A thickness of the hole injection layer 1321 may be in a range of 5 nm to 30 nm, inclusive. A material of the hole injection layer 1321 may be an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide or manganese oxide. Alternatively, the material of the hole injection layer 1321 may be a dopant containing a strong electron-withdrawing material, such as 2,3,5,6-tetrafluoro-7,7′,8,8′-tetracyanoquinodimethane (F4TCNQ), 2,3,6,7,10,11-Hexacyano-1,4,5,8,9,12-hexaazatriphenylene (HATCN) or pyrazino[2,3-f][1,10]phenanthroline-2,3-dicarbonitrile (PPDN). Alternatively, the material of the hole injection layer 1321 may be a material obtained by performing P-type doping on the material of the hole transport layer 1322, in which case the thickness of the hole injection layer 1321 may be in a range of 5 nm to 20 nm; the process for forming the hole injection layer 1321 is, for example, co-evaporating the material of the hole transport layer 1322 and a P-type dopant. The structural formulas of F4TCNQ, HATCN and PPDN are as follows.

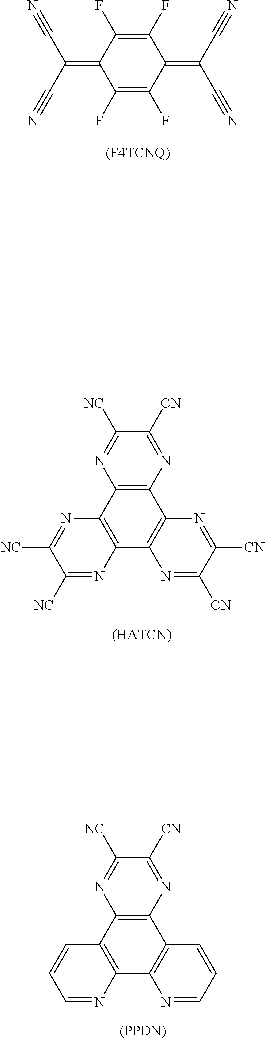

For example, the thickness of the hole transport layer 1322 of the single-layer light-emitting device may be in a range of 100 nm to 2000 nm, inclusive; the thickness of the hole transport layer 1322 of the tandem light-emitting device may be in a range of 15 nm to 25 nm, inclusive. The material of the hole transport layer 1322 has good hole transport property and may be aromatic amine materials or carbazole materials, such as N,N′-Bis-(1-naphthalenyl)-N,N′-bis-phenyl-(1,1′-biphenyl)-4,4′-diamine (NPB), 4,4′,4″-tris(carbazol-9-yl)-triphenylamine (TCTA), 4,4′-Cyclohexylidenebis[N, N-bis(4-methylphenyl)aniline] (TAPC), N,N′-Bis(3-methylphenyl)-N,N′-bis(phenyl)benzidine (TPD), 4-phenyl-4′-(9-phenylfluoren-9-yl)triphenylamine (BAFLP) or N,N′-diphenyl-N,N′-bis(9,9-dimethylfluoren-2-yl)benzidine (DFLDPBi). The structural formulas of NPB, TCTA and TAPC are as follows.

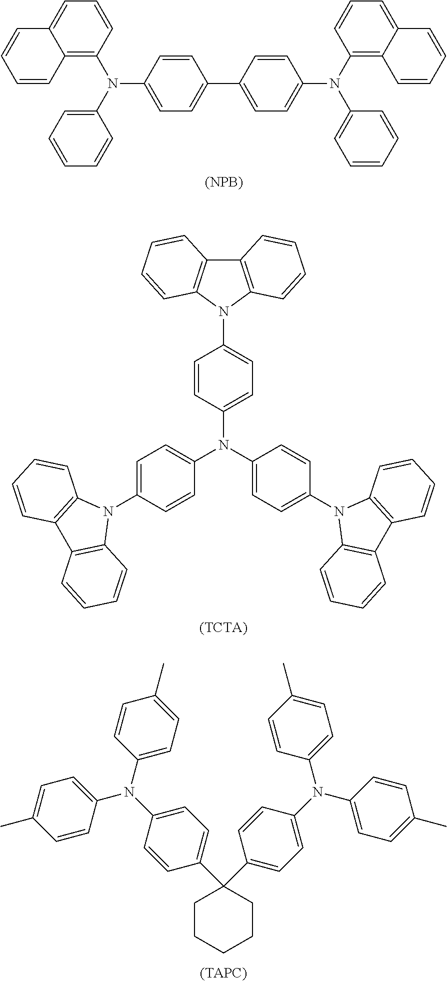

For example, the thickness of the electron blocking layer 1323 of the single-layer light-emitting device may be in a range of 5 nm to 100 nm, inclusive; the thickness of the electron blocking layer 1323 of the tandem light-emitting device may be in a range of 5 nm to 15 nm, inclusive. The material of the electron blocking layer 1323 has good hole transport property and may be aromatic amine materials or carbazole materials, such as 4,4′-bis(carbazol-9-yl)biphenyl (CBP) or 9-phenyl-3-[4-(10-phenyl-9-anthryl)phenyl]-9H-carbazole (PCzPA).

For example, the thickness of the electron injection layer 1331 is in a range of 1 nm to 10 nm, inclusive. The material of the electron injection layer 1331 has the property of electron transport capability, and has the effect of injecting electrons from the cathode 12, as well as good film forming capability. The material of the electron injection layer 1331 may be an alkali metal or a metal, such as lithium fluoride (LiF), ytterbium (Yb), magnesium (Mg), calcium (Ca), or a compound of the above metals.

For example, the thickness of the electron transport layer 1332 of the single-layer light-emitting device may be in a range of 20 nm to 100 nm, inclusive; the thickness of the electron transport layer 1332 of the tandem light-emitting device may be in a range of 20 nm to 100 nm, inclusive. The thickness of the hole blocking layer 1333 of the single-layer light-emitting device may be in a range of 5 nm to 100 nm, inclusive; the thickness of the hole blocking layer 1333 of the tandem light-emitting device may be in a range of 5 nm to 15 nm, inclusive. The materials of the electron transport layer 1332 and the hole blocking layer 1333 may be aromatic heterocyclic compounds, such as imidazole derivatives, pyrimidine derivatives, oxazine derivatives, compounds containing a nitrogen-containing six-membered ring structure, or compounds having a phosphine oxide-based substituent on a heterocyclic ring. Among them, imidazole derivatives are, for example, benzimidazole derivatives, imidazopyridine derivatives or benzimidazolephenaN-thridine derivatives; oxazine derivatives are, for example, triazine derivatives; compounds containing a nitrogen-containing six-membered ring structure are, for example, quinoline derivatives, isoquinoline derivatives, or phenanthroline derivatives. In some examples, the materials of the electron transport layer 1332 and the hole blocking layer 1333 are 2,2′-(1,3-Phenylene)bis[5-(4-tert-butylphenyl)-1,3,4-oxadiazole] (OXD-7), 3-(biphenyl-4-yl)-5-(4-tert-butylphenyl)-4-phenyl-4H-1,2,4-triazole (TAZ), 3-(4-tert-butylphenyl)-4-(4-ethylphenyl)-5-(4-biphenyl)-1,2,4-triazole (p-EtTAZ), 4,7-diphenyl-1,10-phenanthroline (BPhen), 2,9-dimethyl-4,7-diphenyl-1,10-phenanthroline (BCP) or 1,3,5-tris(1-phenyl-1H-benzimidazol-2-yl)benzene (TPBi). The structural formulas of BPhen and TPBi are as follows.

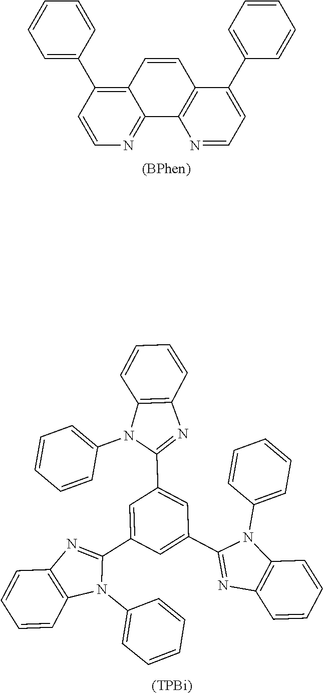

For example, the thickness of the light-emitting layer 131 of the single-layer light-emitting device may be in a range of 20 nm to 100 nm, inclusive; the thickness of the light-emitting layer 131 of the tandem light-emitting device may be in a range of 10 nm to 20 nm, inclusive.

In some embodiments, as shown in FIGS. 4, 5 and 10, in the case where the plurality of light-emitting devices 100 include the first light-emitting device 101, the second light-emitting device 102 and the third light-emitting device 103, the cathodes 12 of the plurality of light-emitting devices 100 are of a whole-layer structure in which the cathodes 12 are connected, that is, the cathodes 12 may be a common electrode shared by the plurality of light-emitting devices 100. The hole injection layers 1321 of the plurality of light-emitting devices 100 may also be of a whole-layer structure in which the hole injection layers 1321 are connected; that is, the hole injection layers 1321 may be a common film layer shared by the plurality of light-emitting devices 100. The hole transport layer 1322, the electron injection layer 1331, and the electron transport layer 1332, the hole blocking layer 1333, the electron generation layer 141, and the hole generation layer 142 may each also be a common film layer shared by the plurality of light-emitting devices 100.

For example, as shown in FIG. 3, in the case where the cathodes 12 are a common electrode shared by the plurality of light-emitting devices 100, the cathodes 12 are simultaneously formed on a side of the pixel definition layer 221 away from the substrate 210.

In some embodiments, as shown in FIGS. 4, 5 and 10, in the case where the plurality of light-emitting devices 100 include the first light-emitting device 101, the second light-emitting device 102 and the third light-emitting device 103, the electron blocking layers 1323 of the first light-emitting device 101, the second light-emitting device 102 and the third light-emitting device 103 are independently arranged, so that the materials of the electron blocking layers 1323 with matching performance may be selected as needed according to the different materials of the light-emitting layers 131.

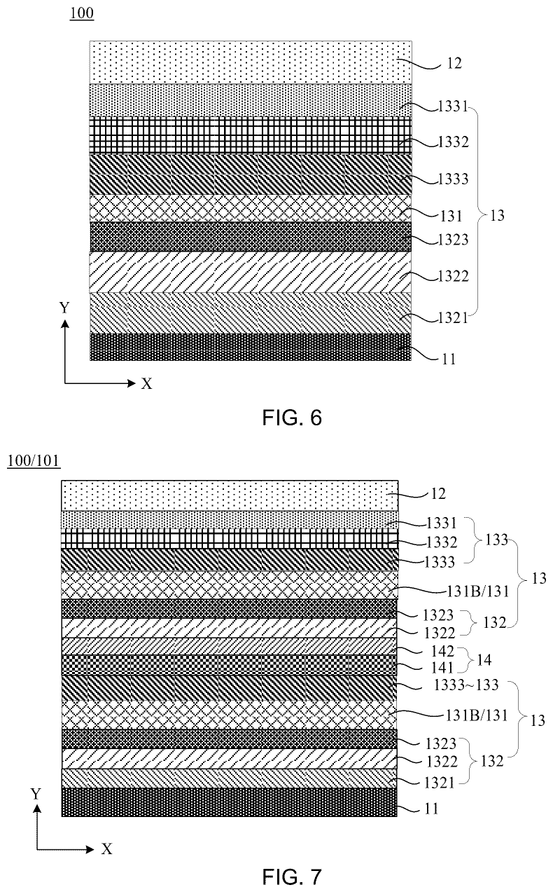

For example, in the case where the light-emitting device 100 is a single-layer light-emitting device, the structure of the light-emitting device 100 (e.g., the first light-emitting device 101) is as shown in FIG. 6, the light-emitting device 100 includes an anode 11, a hole injection layer 1321, a hole transport layer 1322, an electron blocking layer 1323, a light-emitting layer 1323, a hole blocking layer 1333, an electron transport layer 1332, the electron injection layer 1331, and a cathode 12 that are stacked.

For example, in the case where the light-emitting device 100 is a single-layer light-emitting device, and the plurality of light-emitting devices 100 includes the first light-emitting device 101, the second light-emitting device 102 and the third light-emitting device 103, the structure of the display panel 200 is as shown in FIG. 4, the first light-emitting device 101, the second light-emitting device 102 and the third light-emitting device 103 are arranged in the first direction X. The cathode 12 is a common electrode of the first light-emitting device 101, the second light-emitting device 102 and the third light-emitting device 103; the hole injection layers 1321, the hole transport layer 1322, the hole blocking layer 1333, the electron transport layer 1332, and the electron injection layer 1331 are each a common layer of the first light-emitting device 101, the second light-emitting device 102 and the third light-emitting device 103; the anodes 11 are arranged independently, and are respectively the anode 11B of the first light-emitting device 101, the anode 11G of the second light-emitting device 102 and the anode 11R of the third light-emitting device 103; the electron blocking layers 1323 are arranged independently, and are respectively the electron blocking layer 1323B of the first light-emitting device 101, the electron blocking layer 1323G of the second light-emitting device 102 and the electron blocking layer 1323R of the third light-emitting device 103; the light-emitting layers 131 are arranged independently, and are respectively the light-emitting layer 131B of the first light-emitting device 101, the light-emitting layer 131G of the second light-emitting device 102 and the light-emitting layer 131R of the third light-emitting device 103.

For example, in the case where the light-emitting device 100 is a tandem light-emitting device (for example, including two light-emitting units 13), the structure of the light-emitting device 100 (e.g., the first light-emitting device 101) is as shown in FIGS. 7 and 9, the light-emitting device 100 includes an anode 11, a hole transport functional layer 132, a light-emitting layer 131, an electron transport functional layer 133, an electron generation layer 141, a hole generation layer 142, a hole transport functional layer 132, a light-emitting layer 131, an electron transport functional layer 133 and a cathode 12 that are stacked. The hole transport functional layer 132, the light-emitting layer 131, and the electron transport functional layer 133 that are located on a side proximate to the anode 11 constitute a first light-emitting unit 13, and the hole transport functional layer 132, the light-emitting layer 131, and the electron transport functional layer 133 that are located on a side proximate to the cathode 12 constitute a second light-emitting unit 13.

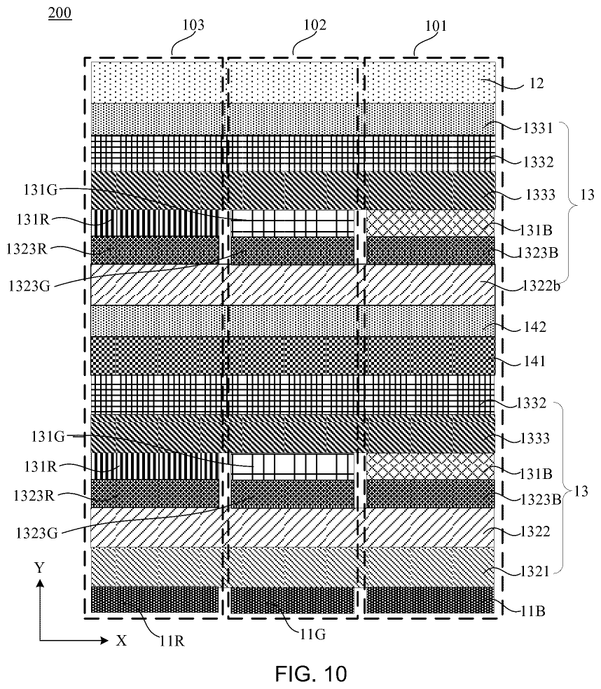

For example, in the case where the light-emitting device 100 is a tandem light-emitting device (for example, including two light-emitting units 13), and the plurality of light-emitting devices 100 include a first light-emitting device 101, a second light-emitting device 102, and a third light-emitting device 103, the structure of the display panel 200 is, for example, as shown in FIGS. 5 and 10, and the first light-emitting device 101, the second light-emitting device 102, and the third light-emitting device 103 are arranged in the first direction X. Moreover, the cathode 12 is the common electrode of the first light-emitting device 101, the second light-emitting device 102 and the third light-emitting device 103; the hole transport functional layers 132 of the first light-emitting unit 13 and the second light-emitting unit 13 except the electron blocking layer 1323 and the electron transport functional layers 133 of the first light-emitting unit 13 and the second light-emitting unit 13 are each a common film layer shared by the first light-emitting device 101, the second light-emitting device 102 and the third light-emitting device 103. The anodes 11 of the first light-emitting device 101, the second light-emitting device 102 and the third light-emitting device 103, the electron blocking layers 1323 and the light-emitting layers 131 of the first light-emitting unit 13, and the electron blocking layer 1323 and the light-emitting layer 131 of the second light-emitting unit 13 are independently arranged. Regarding the independent arrangement, reference may be made to the above content and details are not repeated here.

For example, in the above-mentioned tandem light-emitting device, as shown in FIGS. 5, 7, 9 and 10, the hole transport functional layer 132 of the first light-emitting unit 13 may include a hole injection layer 1321, a hole transport layer 1322 and an electron blocking layer 1323. The hole transport functional layer 132 of the second light-emitting unit 13 may include a hole transport layer 1322 and an electron blocking layer 1323.

For example, in the above-mentioned tandem light-emitting device, as shown in FIGS. 5, 7 and 9, the electron transport functional layer 133 of the first light-emitting unit 13 may include a hole blocking layer 1333. Alternatively, as shown in FIG. 10, the electron transport functional layer 133 of the first light-emitting unit 13 may include a hole blocking layer 1333 and an electron transport layer 1332.

For example, in the above-mentioned tandem light-emitting device, as shown in FIGS. 5, 7 and 10, the electron transport functional layer 133 of the second light-emitting unit 13 may include a hole blocking layer 1333, an electron transport layer 1332, and an electron injection layer 1331. Alternatively, as shown in FIG. 9, the electron transport functional layer 133 of the second light-emitting unit 13 may include a hole blocking layer 1333 and an electron transport layer 1332.

In the tandem light-emitting device including two light-emitting units 13, the electron generation layer 141 may inject electrons into the first light-emitting unit 13, and the hole generation layer 142 may inject holes into the second light-emitting unit 13.

In some embodiments, a material of the light-emitting layer 13 includes a host material H and a guest material D.

For example, the host material H may be configured to transport holes or electrons, and/or the host material H may be configured such that electrons and holes recombine to form excitons and the exciton energy is transferred to the guest material D.

For example, the guest material D may be configured to emit photons by using the exciton energy transferred from the host material H, and/or the guest material D may be configured such that electrons and holes recombine to form excitons to emit photons.

In some examples, the guest material D is a fluorescent material that capable of emitting light using singlet excitons; in some other examples, the guest material D is a phosphorescent material or a delayed fluorescent material that capable of emitting light using triplet excitons.

In some examples, the host material H includes more than two materials. For example, the host material H may include a first host material and a second host material; the first host material is a hole-type material and the second host material is an electron-type material.

For example, in the case where the plurality of light-emitting devices 100 include a first light-emitting device 101, the host material H of the first light-emitting device 101 may be anthracene derivatives, such as 9,10-di(2-naphthyl) anthracene (ADN) or 2-methyl-9,10-bis(naphthalen-2-yl) anthracene (MADN); the guest material D of the first light-emitting device 101 may be pyrene derivatives, fluorene derivatives, perylene derivatives, styrylamine derivatives or a metal complex, such as 2,5,8,11-tetra-tert-butylperylene (TBPe), 4,4′-bis[4-(diphenylamino)styryl]biphenyl (BDAVBi), 4,4′-bis[4-(di-p-tolylamino)styryl]biphenyl (DPAVBi) or bis(4,6-difluorophenylpyridine-N, C2)picolinyliridium (FIrpic). The structure formulas of ADN and DPAVBi are shown in the following formula.

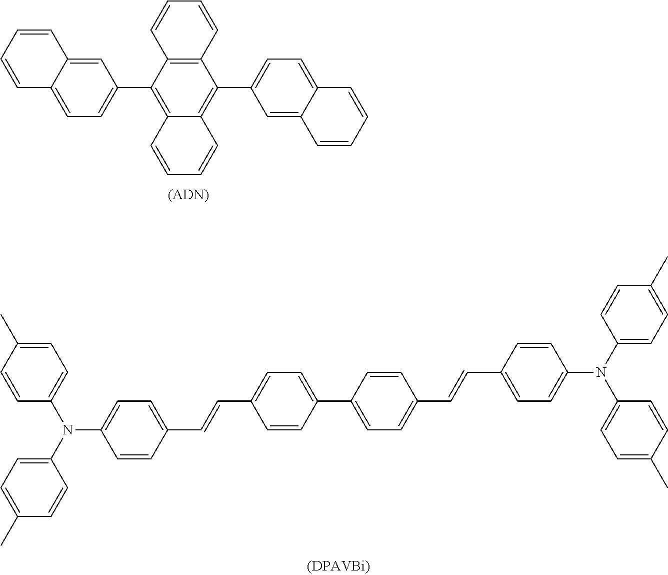

For example, in the case where the plurality of light-emitting devices 100 include the second light-emitting device 102, the main material H of the second light-emitting device 102 may be coumarin dyes, quinacridone derivatives, polycyclic aromatic hydrocarbons, diaminoanthracene derivatives or carbazole derivatives, such as N,N′-dimethylquinacridone (DMQA), N,N′-di-1-naphthalenyl-N, N′-diphenyl-[9,9′-bianthracene]-10,10′-diamine; N10,N10′-diphenyl-N10,N10′-dinaphthalenyl-9,9′-bianthracene-10,10′-diamine (BA-NPB), 8-hydroxyquinoline aluminum salt (Alq3) or 4,4′-bis(carbazol-9-yl)biphenyl (CBP); the guest material D of the second light-emitting device 102 may be a metal complex, such as tri(2-phenylpyridine)iridium (Ir(ppy)3) or acetylacetonate di(2-phenylpyridine)iridium (Ir(ppy)2(acac)). The structural formulas of CBP and Ir(ppy)3 are as follows.

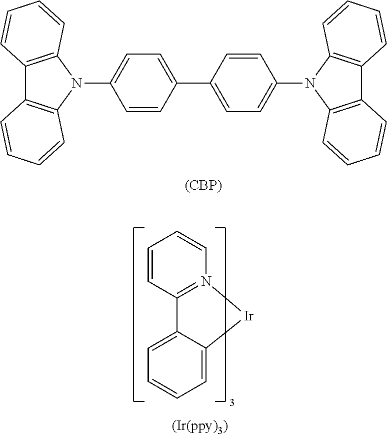

For example, in the case where the plurality of light-emitting devices 100 include a third light-emitting device 103, the main material H of the third light-emitting device 103 may be DCM materials, such as 4-(dicyanomethylene)-2-methyl-6-(4-dimethylaminophenylvinyl)-4H-pyran (DCM), 4-(dicyanomethylene)-2-tert-butyl-6-(1,1,7,7-tetramethyljulolidine-9-enyl)-4H-pyran (DCJTB), 2-[2-(1-Methylethyl)-6-[2-(2,3,6,7-tetrahydro-1,1,7,7-tetramethyl-1H,5H-benzo[ij]quinolizin-9-yl) ethenyl]-4H-pyran-4-ylidene]propanedinitrile (DCJTI), or 2,8-Bis(9H-carbazol-9-yl)dibenzothiophene (DCzDBT); the guest material D of the third light-emitting device 103 may be a metal complex, such as bis(1-phenyl-isoquinoline)(acetylacetonato)iridium (III) (Ir(piq)2(acac)), platinum (II) octaethylporphyrin (PtOEP), or bis[2-(2′-benzothienyl)pyridinato-N,C3′](acetylacetonato)iridium (Ir(btp)₂(acac)). The structural formulas of DCzDBT and Ir(piq)2(acac) is as follows.

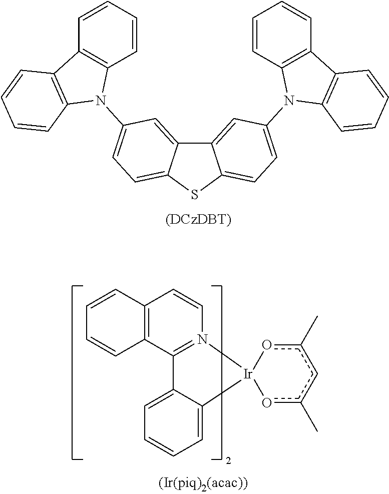

As mentioned in the background, in the field of organic semiconductors, OLED light-emitting devices have the advantages of self-luminescence, low power consumption, bright colors, wide viewing angle, and capable of being prepared into flexible products, and are gradually replacing liquid crystal displays (LCD) in the field of small and medium-sized displays to become a mainstream product, and have been successfully used in lighting systems, communication systems, vehicle display systems, portable electronic devices, and high-definition display devices.

With the development of OLED light-emitting devices, the requirements for the efficiency, service life and other performance of OLED light-emitting devices are becoming increasingly higher. The efficiency and service life of the light-emitting device are related to the device structure and the optimal combination of organic materials in each film layer. In terms of device structure, the structure of OLED light-emitting devices has developed from the original sandwich structure to a multi-layer device structure. As for the description of the structure of the tandem device, reference will be made to the above description, which will not be repeated here.

Based on the above-mentioned structure of the tandem device, due to the action of the driving voltage, electrons are emitted from the cathode 12, injected through the electron injection layer 1331, and transmitted to the light-emitting layer 131 via the electron transport layer 1332 and the hole blocking layer 1333; holes are emitted from the anode 11, injected through the hole injection layer 1321, and transmitted to the light-emitting layer 131 via the hole transport layer 1322 and the electron blocking layer 1323. The electrons and holes recombine in the light-emitting layer 131 to form excitons, and the excitons excite radiative transition to emit light. According to the different types of electron orbits in the excitons, the excitons may be classified into singlet excitons and triplet excitons, in which the singlet excitons account for 25% and the triplet excitons account for 75%.

Since the matching of mobility and energy levels between the functional film layers in the light-emitting device 100, as well as the properties of the material itself will affect the injection and transmission of carriers inside the light-emitting device 100 and/or the formation and quenching of excitons, the interface structure of the OLED light-emitting device will affect the properties (e.g., current density, luminance, luminous efficiency and stability) of the light-emitting device.

In some implementations, the consistency of the regions where holes and electrons recombine to form excitons in the first light-emitting device 101, the second light-emitting device 102, and the third light-emitting device 103 is relatively poor, which affects the color matching of the display panel 200 and is prone to color cast problems.

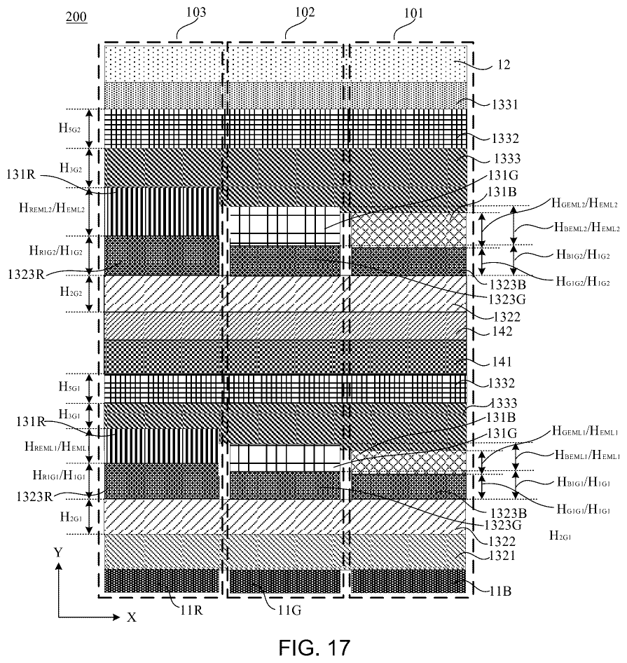

Based on this, some embodiments of the present disclosure provide a display panel 200, as shown in FIG. 17, the display panel 200 includes a plurality of light-emitting devices 100, and the plurality of light-emitting devices 100 include at least one first light-emitting device 101, at least one second light-emitting device 102, and at least one third light-emitting device 103. The number of light-emitting units 13 included in each light-emitting device 100 is n, where n is a positive integer greater than or equal to 1. A thickness of a light-emitting layer 131 of an N-th light-emitting unit of the third light-emitting device 103 is greater than a thickness of a light-emitting layer 131 of an N-th light-emitting unit of the second light-emitting device 102; the thickness of the light-emitting layer 131 of the N-th light-emitting unit of the second light-emitting device 102 is greater than a thickness of a light-emitting layer 131 of an N-th light-emitting unit of the first light-emitting device 101, where N is a positive integer less than or equal to n.

For example, in a case of n=1, i.e., the light-emitting device 100 being a single-layer light-emitting device, the thickness H_{REML1} of the light-emitting layer 131 of the third light-emitting device 103, the thickness H_{GEML1} of the light-emitting layer 131 of the second light-emitting device 102 and the thickness H_{BEML1} of the light-emitting layer of the first light-emitting device 101 satisfy: H_{REML1}>H_{GEML1}>H_{BEML1}.

For example, in a case of n=2, i.e., the light-emitting device 100 being a tandem light-emitting device including two light-emitting units 13, the light-emitting unit 13 proximate to the anode 11 may be set as the first light-emitting unit, and the light-emitting unit 13 proximate to the cathode 12 may be set as the second light-emitting unit. In this case, the thickness H_{BEML1} of the light-emitting layer 131 of the first light-emitting unit 13 of the first light-emitting device 101, the thickness H_{GEML1} of the light-emitting layer 131 of the first light-emitting unit 13 of the second light-emitting device 102, and the thickness H_{REML1} of the light-emitting layer 131 of the first light-emitting unit 13 of the third light-emitting device 103 satisfy: H_{REML1}>H_{GEML1}>H_{BEML1}; the thickness H_{BEML2} of the light-emitting layer 131 of the second light-emitting unit 13 of the first light-emitting device 101, the thickness H_{GEML2} of the light-emitting layer 131 of the second light-emitting device 102 and the thickness H_{REML2} of the light-emitting layer 131 of the second light-emitting unit 13 of the third light-emitting device 103 satisfy: H_{REML2}>H_{GEML2}>H_{BEML2}.

Regarding the tandem light-emitting device in a case of n>2, reference may be made to the above description and details will not be repeated here.

It will be noted that the thickness mentioned here refers to a dimension of the light-emitting layer 131 in the second direction Y.

It can be understood that mobility of carriers in the light-emitting layer 131 of the third light-emitting device 103 is greater than mobility of carriers in the light-emitting layer 131 of the second light-emitting device 102, and the mobility of carriers in the light-emitting layer 131 of the second light-emitting device 102 is greater than mobility of carriers in the light-emitting layer 131 of the first light-emitting device 101. With the above-mentioned configuration, the thickness of the light-emitting layer 131 of the first light-emitting device 101, the second light-emitting device 102, and the third light-emitting device 103 may be matched with the mobility of carriers. In this way, the regions where holes and electrons recombine to form excitons in the first light-emitting device 101, the second light-emitting device 102, and the third light-emitting device 103 may be made relatively consistent, which may alleviate the problem of color deviation.

In some embodiments, as shown in FIG. 17, a difference between the thickness H_{REMLN} of the light-emitting layer 131 of the N-th light-emitting unit of the third light-emitting device 103 and the thickness H_{BEMLN} of the light-emitting layer 131 of the N-th light-emitting unit of the first light-emitting device 101 is a first thickness difference (H_{REMLN}−H_{BEMLN}); a difference between the thickness H_{GEMLN} of the light-emitting layer 131 of the N-th light-emitting unit of the second light-emitting device 102 and the thickness H_{BEMLN} of the light-emitting layer 131 of the N-th light-emitting unit of the first light-emitting device 101 is a second thickness difference (H_{GEMLN}−H_{BEMLN}); a difference between the thickness H_{REMLN} of the light-emitting layer of the N-th light-emitting unit of the third light-emitting device and the thickness H_{GEMLN} of the light-emitting layer 131 of the N-th light-emitting unit of the second light-emitting device 102 is a third thickness difference (H_{REMLN}−H_{GEMLN}). A ratio of the first thickness difference (H_{REMLN}−H_{BEMLN}) to the second thickness difference (H_{GEMLN}−H_{BEMLN}) is greater than or equal to 1.5 and less than or equal to 2; a ratio of the third thickness difference (H_{REMLN}−H_{GEMLN}) to the second thickness difference (H_{GEMLN}−H_{BEMLN}) is greater than or equal to 1 and less than or equal to 1.5. That is, 1.5≤(H_{REMLN}−H_{BEMLN})/(H_{GEMLN}−H_{BEMLN})≤2, and 1≤(H_{REMLN}−H_{GEMLN})/(H_{GEMLN}−H_{BEMLN})≤1.5.

With such a configuration, the thickness of the light-emitting layer 131 of the second light-emitting device 102 and the thickness of the light-emitting layer 131 of the third light-emitting device 103 may be made relatively small. Thus, the driving voltages of the second light-emitting device 102 and the third light-emitting device 103 may be made relatively low, thereby reducing the driving voltage of the display panel 200.

For example, the ratio of the first thickness difference (H_{REMLN}−H_{BEMLN}) to the second thickness difference (H_{GEMLN}−H_{BEMLN}) may be 1.5, 1.6, 1.7, 1.8, 1.9 or 2.0, etc.

For example, the ratio of the third thickness difference (H_{REMLN}−H_{GEMLN}) to the second thickness difference (H_{GEMLN}−H_{BEMLN}) may be 1.0, 1.1, 1.2, 1.3, 1.4 or 1.5, etc.

In some embodiments, as shown in FIG. 17, the light-emitting unit 13 further includes a first type of functional layer 132 (see FIG. 9) disposed on a side of the light-emitting layer 131 (see FIG. 9) proximate to the anode 11; the first type of functional layer 132 includes a first functional sub-layer 1323 in contact with the light-emitting layer 131; a difference between a thickness H_{R1GN} of a first functional sub-layer 1323 of the N-th light-emitting unit of the third light-emitting device 103 and a thickness H_{B1GN} of a first functional sub-layer 1323 of the N-th light-emitting unit of the first light-emitting device 101 is a fourth thickness difference (H_{R1GN}−H_{B1GN}); a difference between a thickness H_{G1GN} of a first functional sub-layer 1323 of the N-th light-emitting unit of the second light-emitting device 102 and a thickness H_{B1GN} of a first functional sub-layer 1323 of the N-th light-emitting unit of the first light-emitting device 101 is a fifth thickness difference (H_{G1GN}−H_{B1GN}). A ratio of the fourth thickness difference (H_{R1GN}−H_{B1GN}) to the fifth thickness difference (H_{G1GN}−H_{B1GN}) is greater than or equal to 1.1 and less than or equal to 1.5. That is, 1.1≤(H_{R1GN}−H_{B1GN})/(H_{G1GN}−H_{B1GN})≤1.5.

For example, the first type of functional layer 132 is a hole transport functional layer; and the first functional sub-layer 1323 is an electron blocking layer 1323.

It will be understood that in the case where the thickness of the light-emitting layer 131 of the second light-emitting device 102 and the thickness of the light-emitting layer 131 of the third light-emitting device 103 are relatively small, with the above-mentioned configuration, the color coordinates of the first light-emitting device 101, the second light-emitting device 102 and the third light-emitting device 103 may be adjusted by adjusting the thickness of the first functional sub-layer 1323, so that the display panel 200 has a high color gamut display effect.

For example, the ratio of the fourth thickness difference (H_{R1GN}−H_{B1GN}) to the fifth thickness difference (H_{G1GN}−H_{B1GN}) may be 1.1, 1.2, 1.3, 1.4, 1.5, or the like.

In some embodiments, as shown in FIG. 17, the light-emitting unit 13 further includes a second type of functional layer 133 (see FIG. 9) disposed on the side of the light-emitting layer 131 proximate to the cathode 12; a ratio of the thickness of the first type of functional layer 132 to a thickness of the second type of functional layer 133 is greater than or equal to 1 and less than or equal to 5.

For example, the first type of functional layer 132 is a hole transport functional layer, and the second type of functional layer 133 is an electron transport functional layer. It will be noted that the thickness of the first type of functional layer 132 may be a sum of a thickness of a hole transport layer 1322 and a thickness of a hole injection layer 1321, or a sum of the thickness of the hole transport layer 1322, the thickness of the hole injection layer 1321 and a thickness of the electron blocking layer 1323, which is not limited here. Correspondingly, the thickness of the second type of functional layer 133 may be a sum of a thickness of an electron transport layer 1332 and a thickness of an electron injection layer 1331, or a sum of the thickness of the electron transport layer 1332, the thickness of the electron injection layer 1331 and a thickness of a hole blocking layer 1333, which is not limited here.

It can be understood that since the hole mobility of the material of the hole transport functional layer 132 is relatively high, by setting the ratio of the thickness of the first type of functional layer 132 to the thickness of the second type of functional layer 133 to be greater than or equal to 1 and less than or equal to 5, the thickness of the hole transport functional layer may be made relatively great. In this way, the transmission of carriers may be relatively more balanced, and the region where holes and electrons recombine to form excitons may be relatively far away from the first functional sub-layer 1323 (e.g., the electron blocking layer 1323), so that the electrons and excitons have relatively less influence on the first functional sub-layer 1323, thereby improving the service life of the light-emitting device 100. Moreover, with such a configuration, the light emitted by the light-emitting device 100 may meet the set requirements.

For example, the ratio of the thickness of the first type of functional layer 132 to the thickness of the second type of functional layer 133 may be, 1, 2, 3, 4, or 5, etc.

In some embodiments, a relative molecular weight M_{BD} of the guest material BD of the light-emitting layer 131 of the first light-emitting device 101 is greater than or equal to 650 and less than or equal to 1300. That is, 650≤M_{BD}≤1300.

With such a configuration, the relative molecular weight M_{BD} of the guest material BD of the light-emitting layer 131 of the first light-emitting device 101 may be made relatively high, the glass transition temperature (Tg) of the guest material BD may be made relatively high, the thermal stability of the guest material BD may be improved, the film-forming property of the guest material BD may be improved, so that the film stability of the light-emitting layer 131 of the first light-emitting device 101 may be made relatively high, and the service life of the light-emitting device 100 may be improved.

For example, the relative molecular weight M_{BD} of the guest material BD of the light-emitting layer 131 of the first light-emitting device 101 may be 650, 658, 757, 822, 896, 940, 980, 1019 or 1300, etc.

In some embodiments, the relative molecular weight M_{GD} of the guest material GD of the light-emitting layer 131 of the second light-emitting device 102 is greater than or equal to 700 and less than or equal to 1400. That is, 700≤M_{GD}≤1400.

With such a configuration, the relative molecular weight M_{GD} of the guest material GD of the light-emitting layer 131 of the second light-emitting device 102 may be made relatively high, the glass transition temperature (Tg) of the guest material GD may be made relatively high, the thermal stability of the guest material GD may be improved, the film-forming property of the guest material GD may be improved, so that the film stability of the light-emitting layer 131 of the second light-emitting device 102 may be made relatively high, and the service life of the light-emitting device 100 may be improved.

For example, the relative molecular weight M_{GD} of the guest material GD of the light-emitting layer 131 of the second light-emitting device 102 may be 700, 715, 716, 797, 880, 1089, 1160, 1300 or 1400, etc.

In some embodiments, the relative molecular weight M_{RD} of the guest material RD of the light-emitting layer 131 of the third light-emitting device 103 is greater than or equal to 700 and less than or equal to 1500. That is, 700≤M_{BD}≤1500.

With such a configuration, the relative molecular weight M_{RD} of the guest material RD of the light-emitting layer 131 of the third light-emitting device 103 may be made relatively high, the glass transition temperature (Tg) of the guest material RD may be made relatively high, the thermal stability of the guest material RD may be improved, the film-forming property of the guest material RD may be improved, so that the film stability of the light-emitting layer 131 of the third light-emitting device 103 may be made relatively high, and the service life of the light-emitting device 100 may be improved.

For example, the relative molecular weight M_{RD} of the guest material RD of the light-emitting layer 131 of the third light-emitting device 103 may be 700, 741, 793, 1078, 1276, 1400 or 1500, etc.

In some embodiments, an absolute value |M_{RD}−M_{BD}| of a difference between the relative molecular weight M_{RD} of the guest material RD of the light-emitting layer 131 of the third light-emitting device 103 and the relative molecular weight M_{BD} of the guest material BD of the light-emitting layer 131 of the first light-emitting device 101 is less than or equal to 600. That is, |M_{RD}−M_{BD}|≤600.

For example, the absolute value |M_{RD}−M_{BD}| of the difference between the relative molecular weight M_{RD} of the guest material RD of the light-emitting layer 131 of the third light-emitting device 103 and the relative molecular weight M_{BD} of the guest material BD of the light-emitting layer 131 of the first light-emitting device 101 may be 0, 100, 200, 300, 400, 500 or 600, etc.

In some embodiments, an absolute value |M_{GD}−M_{BD}| of a difference between the relative molecular weight M_{GD} of the guest material GD of the light-emitting layer 131 of the second light-emitting device 102 and the relative molecular weight M_{BD} of the guest material BD of the light-emitting layer 131 of the first light-emitting device 101 is less than or equal to 500. That is, |M_{GD}−M_{BD}|≤500.

For example, the absolute value |M_{GD}−M_{BD}| of the difference between the relative molecular weight M_{GD} of the guest material GD of the light-emitting layer 131 of the second light-emitting device 102 and the relative molecular weight M_{BD} of the guest material BD of the light-emitting layer 131 of the first light-emitting device 101 may be 0, 100, 200, 300, 400 or 500, etc.

In some embodiments, a difference (M_{RD}−M_{BD}) between the relative molecular weight M_{RD} of the guest material RD of the light-emitting layer 131 of the third light-emitting device 103 and the relative molecular weight M_{BD} of the guest material BD of the light-emitting layer 131 of the first light-emitting device 101 is a first relative molecular weight difference; a difference (M_{GD}−M_{BD}) between the relative molecular weight M_{GD} of the guest material GD of the light-emitting layer 131 of the second light-emitting device 102 and the relative molecular weight M_{BD} of the guest material BD of the light-emitting layer 131 of the first light-emitting device 101 is a second relative molecular weight difference. A ratio of an absolute value of the first relative molecular weight difference to an absolute value of the second relative molecular weight difference is greater than or equal to 0.5 and less than or equal to 6. That is:

$$0.5 \leq \frac{\vert {M}_{RD} - {M}_{BD} \vert}{\vert {M}_{GD} - {M}_{BD} \vert} \leq 6$$

For example, the ratio of the absolute value of the first relative molecular weight difference to the absolute value of the second relative molecular weight difference may be 0.5, 1.0, 2.0, 3.0, 4.0, 5.0 or 6.0.

In some embodiments, an optical path length of light in the light-emitting layer 131 of the light-emitting unit 13 proximate to the anode 11 of the first light-emitting device 101 and the first type of functional layer 132 is a first optical path length D1; an optical path length of light in the light-emitting layer 131 of the light-emitting unit 13 proximate to the anode 11 of the second light-emitting device 102 and the first type of functional layer 132 is a second optical path length D2; an optical path length of light in the light-emitting layer 131 of the light-emitting unit 13 proximate to the anode 11 of the third light-emitting device 103 and the first type of functional layer 132 is a third optical path length D3. A ratio of the third optical path length D3 to the second optical path length D2 is greater than or equal to 1.1 and less than or equal to 1.25; that is: 1.1≤D3/D2≤1.25. A ratio of the third optical path length D3 to the first optical length D1 is greater than or equal to 1.25 and less than or equal to 1.45; that is: 1.25≤D3/D1≤1.45. A ratio of the second optical path length D2 to the first optical path length D1 is greater than or equal to 1.05 and less than or equal to 1.25; that is: 1.05≤D2/D1≤1.25.

In the related art, the optical path length may be understood as a distance that light travels in a vacuum in the same time. Under the condition of the same propagation time or the same phase change, the distance the light travels in the medium is converted into the corresponding distance the light travels in a vacuum. Numerically, the optical path length is equal to the refractive index of the medium multiplied by the distance the light travels in the medium.

For example, in the case where the first type of functional layer 132 of the light-emitting unit 13 proximate to the anode 11 of the light-emitting device 100 (e.g., the first light-emitting device 101, the second light-emitting device 102, or the third light-emitting device 103) includes a hole injection layer 1321, a hole transport layer 1322, and an electron blocking layer 1323, the optical path length D in the light-emitting layer 131 of the light-emitting unit 13 proximate to the anode 11 of the light-emitting device 101 and the first functional layer 132 may be calculated by the following formula:

D1=d1×n1+d2×n2+d3×n3+d4×n4

In the formula, d1, d2, d3, and d4 are respectively the thickness of the hole injection layer 1321, the thickness of the hole transport layer 1322, the thickness of the electron blocking layer 1323, and the thickness of the light-emitting layer 131; n1, n2, n3, and n4 are respectively the refractive index of the material of the hole injection layer 1321, the refractive index of the material of the hole transport layer 1322, the refractive index of the material of the electron blocking layer 1323, and the refractive index of the material of the light-emitting layer 131.

As for the case where the first type of functional layer 132 of the light-emitting unit 13 proximate to the anode 11 of the light-emitting device 100 includes a hole injection layer 1321 and a hole transport layer 1322, or includes a hole transport layer 1322 and an electron blocking layer 1323, reference may be made to the above description, which will not be repeated here.

It will be understood that in a case of 1.1≤D3/D2≤1.25, 1.25≤D3/D1≤1.45, and 1.05≤D2/D1≤1.25, the light extraction efficiency of the third light-emitting device 103, the second light-emitting device 102 and the first light-emitting device 101 may be made relatively high. In this way, the external quantum efficiency of the third light-emitting device 103, the second light-emitting device 102 and the first light-emitting device 101 may be improved, thereby improving the efficiency of the display panel 200.

For example, the ratio of the third optical path length D3 to the second optical path length D2 may be 1.10, 1.15, 1.20 or 1.25, etc.

For example, the ratio of the third optical path length D3 and the first optical path length D1 may be 1.25, 1.30, 1.35, 1.40 or 1.45, etc.

For example, the ratio of the second optical path length D2 to the first optical path length D1 may be 1.05, 1.10, 1.15, 1.20 or 1.25, etc.

In some embodiments, as shown in FIG. 17, the light-emitting device 100 includes a first light-emitting unit and a second light-emitting unit; the first light-emitting unit is closer to the anode 11 than the second light-emitting unit; a ratio of a thickness H_{EML1} of the light-emitting layer 131 of the first light-emitting unit to a thickness H_{EML2} of a light-emitting layer 131 of the second light-emitting unit is greater than or equal to 0.8 and less than or equal to 1.5; that is: 0.8≤H_{EML1}/H_{EML2}≤1.5.

It will be understood that in a case of 0.8≤H_{EML1}/H_{EML2}≤1.5, the thickness H_{EML1} of the light-emitting layer 131 of the first light-emitting unit is relatively consistent with the thickness H_{EML2} of the light-emitting layer 131 of the second light-emitting unit. In this way, the probability of color deviation may be reduced, thereby improving the color purity of the light-emitting device 100; furthermore, the efficiency of the light-emitting device 100 may be improved, so that the expected efficiency of the tandem light-emitting device may be achieved.

For example, the ratio of the thickness H_{EML1} of the light-emitting layer 131 of the first light-emitting unit to the thickness H_{EML2} of the light-emitting layer 131 of the second light-emitting unit may be 0.8, 1.0, 1.2, 1.4 or 1.5.

The light-emitting device 101 may be any one of the first light-emitting device 101, the second light-emitting device 102 and the third light-emitting device 103, which is not limited here.

In some embodiments, as shown in FIG. 17, in a case where the light-emitting unit 13 includes the first type of functional layer 132 and the second type of functional layer 133, the first type of functional layer 132 further includes a second functional sub-layer 1322 and a fourth functional sub-layer 1321, and the fourth functional sub-layer 1321, the second functional sub-layer 1322 and the first functional sub-layer 1323 are arranged in sequence in a direction away from the anode 11; the second type of functional layer 133 includes a third functional sub-layer 1333, a fifth functional sub-layer 1332 and a sixth functional sub-layer 1331; the sixth functional sub-layer 1331, the fifth functional sub-layer 1332 and the third functional sub-layer 1333 are arranged in sequence in a direction away from the cathode 12. A sum of a thickness H_{2G2} of the second functional sub-layer 1322 of the second light-emitting unit 13 and a thickness H_{5G2} of the fifth functional sub-layer 1332 of the second light-emitting unit 13 is a first thickness sum (H_{2G2}+H_{5G2}), and a sum of a thickness H_{2G1} of the second functional sub-layer 1322 of the first light-emitting unit 13 and a thickness H_{5G1} of the fifth functional sub-layer 1332 of the first light-emitting unit 13 is a second thickness sum (H_{2G1}+H_{5G1}); a ratio of the first thickness sum (H_{2G2}+H_{5G2}) to the second thickness sum (H_{2G1}+H_{5G1}) is greater than or equal to 2 and less than or equal to 4. That is, 2≤(H_{2G2}+H_{5G2})/(H_{2G1}+H_{5G1})≤4.

For example, the first functional sub-layer is the electron blocking layer 1323, the second functional sub-layer is the hole transport layer 1322, the fourth functional sub-layer is the hole injection layer 1321, the third functional sub-layer is the hole blocking layer 1333, the fifth functional sub-layer is the electron transport layer 1332, and the sixth functional sub-layer is the electron injection layer 1333.

It can be understood that in the case where the ratio of the first thickness sum to the second thickness sum is greater than or equal to 2 and less than or equal to 4, the thickness of the second light-emitting unit is relatively greater than the thickness of the first light-emitting unit, thereby improving the light extraction efficiency of the tandem light-emitting device 100.

For example, the ratio of the first thickness sum to the second thickness sum may be, 2.0, 2.5, 3.0, 3.5, 4.0, etc.

The light-emitting device 100 may be any one of the first light-emitting device 101, the second light-emitting device 102 and the third light-emitting device 103, which is not limited here.

In some embodiments, as shown in FIG. 17, a sum of a thickness H_{1G2} of the first functional sub-layer 1323 of the second light-emitting unit and a thickness H_{2G2} of the second functional sub-layer 1322 of the second light-emitting unit is a third thickness sum (H_{1G2}+H_{2G2}), and a sum of a thickness H_{1G1} of the first functional sub-layer 1323 of the first light-emitting unit and a thickness H_{2G1} of the second functional sub-layer 1322 of the first light-emitting unit is a fourth thickness sum (H_{1G1}+H_{2G1}); a ratio of the third thickness sum (H_{1G2}+H_{2G2}) to the fourth thickness sum (H_{1G1}+H_{2G1}) is greater than or equal to 2 and less than or equal to 5. That is, 2≤(H_{1G2}+H_{2G2})/(H_{1G1}+H_{2G1})≤5.

It can be understood that in the case where the ratio of the third thickness sum to the fourth thickness sum is greater than or equal to 2 and less than or equal to 5, the thickness of the second light-emitting unit is relatively greater than the thickness of the first light-emitting unit, thereby improving the light extraction efficiency of the tandem light-emitting device 100.

For example, the ratio of the third thickness sum to the fourth thickness sum may be 2.0, 2.5, 3.0, 3.5, 4.0 or 5.0, etc.

The light-emitting device 100 may be any one of the first light-emitting device 101, the second light-emitting device 102 and the third light-emitting device 103, which is not limited here.

In some embodiments, as shown in FIG. 17, a sum of a thickness H_{3G2} of the third functional sub-layer 1333 of the second light-emitting unit and a thickness H_{5G2} of the fifth functional sub-layer 1332 of the second light-emitting unit is a fifth thickness sum (H_{3G2}+H_{5G2}), and a sum of a thickness H_{3G1} of the third functional sub-layer 1333 of the first light-emitting unit and a thickness H_{5G1} of the fifth functional sub-layer 1332 of the first light-emitting unit is a sixth thickness sum (H_{3G1}+H_{5G1}). A ratio of the fifth thickness sum (H_{3G2}+H_{5G2}) to the sixth thickness sum (H_{3G1}+H_{5G1}) is greater than or equal to 1.5 and less than or equal to 3. That is, 1.5≤(H_{3G2}+H_{5G2})/(H_{3G1}+H_{5G1})≤3.

It can be understood that in the case where the ratio of the fifth thickness sum to the sixth thickness sum is greater than or equal to 1.5 and less than or equal to 3, the thickness of the second light-emitting unit is relatively greater than the thickness of the first light-emitting unit, thereby improving the light extraction efficiency of the tandem light-emitting device 100.

For example, the ratio of the fifth thickness sum to the sixth thickness sum may be 1.5, 2.0, 2.2, 2.5 or 3.0, etc.

The light-emitting device 100 may be any one of the first light-emitting device 101, the second light-emitting device 102 and the third light-emitting device 103, which is not limited here.

In some implementations, in the case where the display panel 200 includes the first light-emitting device 101, the second light-emitting device 102, and the third light-emitting device 103, the service life of the first light-emitting device 101 is relatively small.

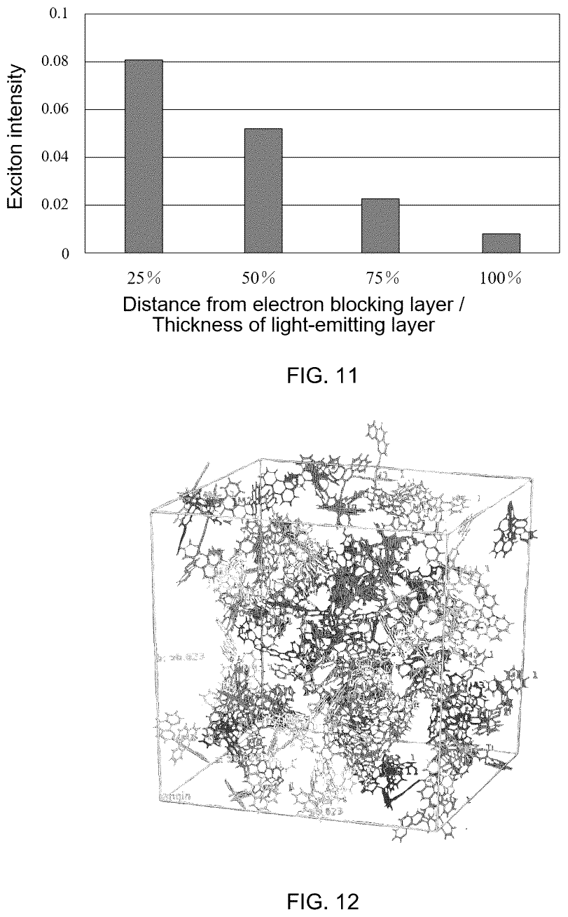

In some other implementations, during the light emission process of the light-emitting device 100, a region (hereinafter referred to as an exciton recombination region for ease of description) where holes and electrons recombine to form excitons is located at the interface between the electron blocking layer 1323 and the light-emitting layer 131. In some cases, during the light emission process of the first light-emitting device 101, the exciton intensity at various positions in the second direction Y in the light-emitting layer 131 is, for example, as shown in FIG. 11. As can be seen from FIG. 11, compared with the middle position of the light-emitting layer 131 and the position of the light-emitting layer 131 proximate to the electron transport functional layer 133, the exciton intensity is relatively great at the position of the light-emitting layer 131 proximate to the electron blocking layer 1323 due to a case, caused by a fact that the transmission rate of electrons is greater than the transmission rate of holes, that the exciton recombination region is located on the side of the light-emitting layer 131 proximate to the electron blocking layer 1323. In this case, electrons and high-energy excitons will accumulate on the material of the electron blocking layer 1323, causing degradation of the material of the electron blocking layer 1323, affecting the performance (e.g., the service life) of the light-emitting device, and further affecting the service life of the entire display panel 200. Therefore, improving the service life of the light-emitting device 100 (especially the first light-emitting device 101) is of great significance to improving the service life of the entire display panel 200.

Based on this, some embodiments of the present disclosure provide a light-emitting device 100, and the light-emitting unit 13 includes a first type of functional layer arranged on a side of the light-emitting layer 131 proximate to the anode 11. The first type of functional layer includes a first functional sub-layer and a second functional sub-layer; a material of the first functional sub-layer includes a first functional material, and a material of the second functional sub-layer includes a second functional material. An overlap rate of density of states for highest occupied molecular orbital (HOMO) of the first functional material and density of states for HOMO of the second functional material is greater than 0% and less than or equal to 90%.

It will be understood that the first type of functional layer mentioned above is the hole transport functional layer 132. The first functional sub-layer is one of the hole injection layer 1321, the hole transport layer 1322 and the electron blocking layer 1323, and the second functional sub-layer is another one of the hole injection layer 1321, the hole transport layer 1322 and the electron blocking layer 1323.

For example, the first functional sub-layer is the electron blocking layer 1323, and the first functional material is the material of the electron blocking layer 1323; the second functional sub-layer is the hole transport layer 1322, and the second functional material is the material of the hole transport layer 1322.

In the related art, the density of states (DOS) may be defined by the number of electron states allowed to be occupied in specific energy levels such as the highest occupied molecular orbital (HOMO) energy level and the lowest unoccupied molecular orbital (LUMO) energy level.

The density of states may be obtained by simulation and calculation by using molecular dynamics and quantum mechanics. The specific process is, for example, as follows: since a molecule has different conformations, when performing calculation, the simulation software may first performs simulation on hundreds to thousands of molecules (e.g., 500 molecules) through molecular dynamics, and optimizes the conformation of the molecule to make the optimized conformation of the molecule conform to the Boltzman distribution; and then, the simulation software establishes a Cell, and fills the geometric configurations of different conformations into the Cell according to different weights, as shown in FIG. 12, for example; and then, the simulation software calculates the highest occupied molecular orbital (HOMO) energy level and/or the lowest unoccupied molecular orbital (LUMO) energy level by quantum mechanics, and the calculated highest occupied molecular orbital energy level and/or the lowest unoccupied molecular orbital energy level conform to the Gaussian distribution; thus, the density of states is obtained.

It can be understood that the greater the overlap rate of the density of states for HOMO of the two materials, the more conducive it is to the transmission of holes between the two materials. In the case where the overlap rate of the density of states for HOMO of the first functional material and the density of states for HOMO of the second functional material is greater than 0% and less than or equal to 90%, the density of states for HOMO of the first functional material (e.g., the material of the electron blocking layer 1323) and the density of states for HOMO of the second functional material (e.g., the material of the hole transport layer 1322) overlap with each other. In this way, the transmission rate of holes between the first functional sub-layer (e.g., the electron blocking layer 1323) and the second functional sub-layer (e.g., the hole transport layer 1322) may be increased, thereby enhancing the hole transmission effect of the first type of functional layer (i.e., the hole transport functional layer 132). As a result, the holes and electrons may be relatively more balanced. Thus, the exciton recombination region may be relatively far away from the electron blocking layer 1323, which may reduce the accumulation of electrons and excitons on the material of the electron blocking layer 1323 to slow down the degradation of the material of the electron blocking layer 1323 and improve the stability of the material of the electron blocking layer 1323, so that the service life of the light-emitting device 100 may be improved; furthermore, the yield of excitons may be increased, which may improve the energy utilization rate, so that the efficiency of the light-emitting device 100 may be improved.

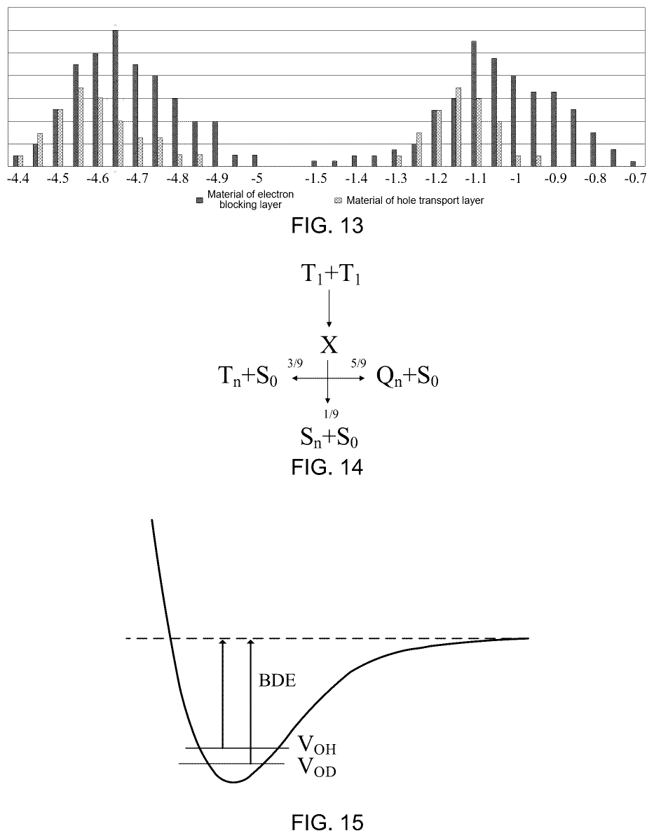

In some examples, in the case where the first functional sub-layer is the electron blocking layer 1323 and the second functional sub-layer is the hole transport layer 1322, the distribution diagram of the density of states of the material (i.e., the first functional material) of the electron blocking layer 1323 and the material (i.e., the second functional material) of the hole transport layer 1322 is shown in FIG. 13, in this figure, the density of states, in a range of −4.4 eV to −5.0 eV, at the left side is the density of states for HOMO, and the density of states, in a range of −1.5 eV to −0.7 eV, at the right side is the density of states for LUMO. As can be seen from FIG. 13, the density of states for HOMO of the material of the electron blocking layer 1323 and the density of states for HOMO of the material of the hole transport layer 1322 overlap in the energy level range of −4.4 eV to −4.85 eV, and has a high overlap rate.

For example, the overlap rate of the density of states for HOMO of the first functional material (e.g., the material of the electron blocking layer 1323) and the density of states for HOMO of the second functional material (e.g., the material of the hole transport layer 1322) may be 1%, 5%, 10%, 30%, 50%, 70% or 90%, etc.

In some embodiments, the structural formula of the above-described second functional material is shown as follows:

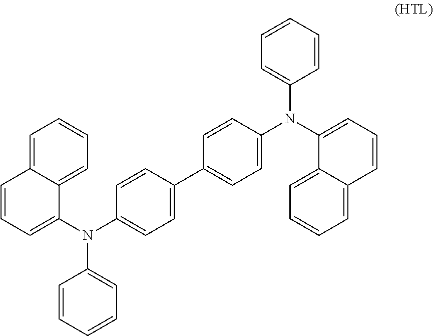 [SMILES: c1ccc(N(c2ccc(-c3ccc(N(c4ccccc4)c4cccc5ccccc45)cc3)cc2)c2cccc3ccccc23)cc1]

It will be noted that, “(HTL)” shown in the above structural formula is a name of the structural formula and is not part of the structure of the structural formula.

The second functional material is a material having a hole transport function. Based on the above structure, the second functional sub-layer may be a hole transport layer or a hole injection layer.

In some embodiments, the first functional sub-layer is in contact with the light-emitting layer 131, and an overlap ratio of the density of states for HOMO of the first functional material and the density of states for HOMO of the host material is greater than 0% and less than or equal to 90%.

The first functional sub-layer is in contact with the light-emitting layer 131, that is, the first functional sub-layer is a layer in the first type of functional layer that is closest to the light-emitting layer 131 and in contact with the light-emitting layer 131. For example, the first functional sub-layer may be one of the hole injection layer 1321, the hole transport layer 1322 and the electron blocking layer 1323.

For example, the first functional sub-layer is the electron blocking layer 1323, and the first functional material is the material of the electron blocking layer 1323.

As mentioned above, the greater the overlap rate of the density of states for HOMO of the two materials, the more conducive it is to the transmission of holes between the two materials. Moreover, the host material is the main material that performs the hole transport function in the light-emitting layer 131. In the case where the overlap rate of the density of states for HOMO of the first functional material and the density of states for HOMO of the host material is greater than 0% and less than or equal to 90%, the density of states for HOMO of the first functional material (e.g., the material of the electron blocking layer 1323) and the density of states for HOMO of the host material overlap with each other. In this way, the transmission rate of holes between the first functional material (e.g., the material of the electron blocking layer 1323) and the host material may be increased, thereby enhancing the hole transmission effect from the first type of functional layer (i.e., the hole transport functional layer 132) to the light-emitting layer 131. As a result, the holes and electrons may be relatively more balanced. Thus, the exciton recombination region may be relatively far away from the electron blocking layer 1323, which may reduce the accumulation of electrons and excitons on the material of the electron blocking layer 1323 to slow down the degradation of the material of the electron blocking layer 1323 and improve the stability of the material of the electron blocking layer 1323, so that the service life of the light-emitting device 100 may be improved; furthermore, the yield of excitons may be increased, which may improve the energy utilization rate, so that the efficiency of the light-emitting device 100 may be improved.

For example, the overlap rate of the density of states for HOMO of the first functional material (e.g., the material of the electron blocking layer 1323) and the density of states for HOMO of the host material may be 2%, 8%, 10%, 30%, 50%, 75% or 90%, etc.

In some examples, the density of states for HOMO of the material of the electron blocking layer 1323 satisfies at least one of the following conditions (i) and (ii):
(i) the overlap ratio of the density of states for HOMO of the material of the electron blocking layer 1323 and the density of states for HOMO of the material of the hole transport layer 1322 is greater than 0% and less than or equal to 90%;
(ii) the overlap ratio of the density of states for HOMO of the material of the electron blocking layer 1323 and the density of states for HOMO of the host material is greater than 0% and less than or equal to 90%.

In some embodiments, an absolute value of a difference between an electron reorganization energy λe(H) of the host material H and a hole reorganization energy λh(H) of the host material H is less than or equal to 0.1 eV. That is, the electron reorganization energy λe(H) of the host material H and the hole reorganization energy λh(H) of the host material H satisfy: |λe(H)−λh(H)|≤0.1 eV.

In the related art, the hole reorganization energy may be used to characterize the hole mobility of a material, and the electron reorganization energy may be used to characterize the electron mobility of a material.

It will be understood that, in the case of |λe(H)−λh(H)|≤0.1 eV, the difference between the hole mobility of the host material and the electron mobility of the host material is relatively small, which may make the transmission rate of holes in the host material and the transmission rate of electrons in the host material relatively consistent. In this way, the electrons and holes may be relatively more balanced. Thus, as mentioned above, it may be possible to slow down the degradation of the material of the electron blocking layer 1323, so that the service life of the light-emitting device 100 may be improved; furthermore, the yield of excitons may be increased, so that the efficiency of the light-emitting device 100 is improved.

In some examples, the electron reorganization energy λe(H) of the host material H is greater than the hole reorganization energy λh(H) of the host material H, and both satisfy: λe(H)−λh(H)≤0.1 eV. For example, the difference between the electron reorganization energy λe(H) of the host material H and the hole reorganization energy λh(H) of the host material H may be 0 eV, 0.2 eV, 0.4 eV, 0.6 eV, 0.8 eV or 1.0 eV, etc.

In some other examples, the hole reorganization energy λh(H) of the host material H is greater than the electron reorganization energy λe(H) of the host material H, and both satisfy: λh(H)−λe(H)≤0.1 eV. For example, the difference between the hole reorganization energy λh(H) of the host material H and the electron reorganization energy λe(H) of the host material H may be 0 eV, 0.15 eV, 0.4 eV, 0.6 eV, 0.85 eV or 1.0 eV, etc.

In some embodiments, the hole mobility of the host material is greater than the electron mobility of the host material.

It can be understood that in the case where the hole mobility of the host material is greater than the electron mobility of the host material, the exciton recombination region may be relatively far away from the electron blocking layer 1323, which may reduce the accumulation of carriers (electrons or holes) and excitons on the material of the electron blocking layer 1323 to slow down the degradation of the material of the electron blocking layer 1323 and improve the stability of the material of the electron blocking layer 1323, so that the service life of the light-emitting device 100 is improved.

In some implementations, the guest material of the light-emitting device 100 (e.g., the first light-emitting device 101) is a fluorescent material. Compared with phosphorescent materials that emit light by using triplet excitons due to the action of spin-orbit coupling, the fluorescent material does not have the action of spin-orbit coupling, so that the fluorescent material may only use the radiative deactivation of singlet excitons into the ground state to emit fluorescence, but cannot use the energy of triplet excitons with a high probability of generation for emitting light. Therefore, the internal quantum efficiency (IQE) of the light-emitting device 100 using the fluorescent material as the guest material reaches up to its theoretical limit of 25%, which is less than the internal quantum efficiency (which can reach 100%) of the light-emitting device 100 using the phosphorescent material as the guest material, resulting in the light-emitting device 100 (for example, the first light-emitting device 101) using the fluorescent material as the guest material having a relatively low efficiency.

In order to increase the efficiency of the light-emitting device 100 (e.g., the first light-emitting device 101) using the fluorescent material as the guest material, the triplet excitons may be utilized to emit light through the triplet-triplet annihilation (TTA) effect to increase the luminous efficiency of the fluorescent material. One form of the triplet-triplet annihilation (TTA) effect is triplet-triplet fusion (TTF) effect, the principle of which is that singlet excitons are generated by the collision and fusion of two triplet excitons to increase the emission of fluorescence, and the process is shown in FIG. 14. As shown in FIG. 14, after two triplet excitons collide and fuse, Sₙ and S₀ are generated with a probability of 1/9. Sₙ can generate singlet exciton S₁ through vibrational relaxation, and the process of S₁ radiative transition to S₀ can realize fluorescence luminescence. The generation probability of the singlet exciton S₁ is, for example, five triplet excitons generating one singlet exciton S₁. It can be seen that the efficiency of the light-emitting device 100 (e.g., the first light-emitting device 101) using fluorescent material as the guest material may be increased due to the TTF effect.

However, during the TTF process, when triplet excitons collide with each other, high-energy intermediates are generated. The energy of the intermediate is higher than the bond dissociation energy of the host material and/or the guest material, which may result in degradation of the host material and/or the guest material. Here, bond dissociation energy (BDE) may be understood as the energy required to break a specific chemical bond. Generally speaking, the higher the bond dissociation energy, the more stable the molecule, and correspondingly, the stability of the material is relatively high.

In some embodiments, at least one of the host material, the guest material, and the first functional material is a deuterated material.

It will be noted that the deuterated material refers to a material in which at least one hydrogen atom in the structure is replaced by a deuterium atom. That is, the structure of the deuterated material contains at least one deuterium atom.

It is understandable that hydrogen atom is a common element in OLED organic materials, deuterium is an isotope of hydrogen, and the atomic weight of deuterium is twice that of hydrogen. In a case where hydrogen in a compound molecule is replaced by deuterium, the chemical properties of the compound remain almost unchanged. Moreover, compared with the carbon-hydrogen bond, the carbon-deuterium bond has a shorter bond length, higher bond dissociation energy and lower vibration energy, which may shorten the bond length, increase the bond dissociation energy and improve the molecular stability. In a case where a hydrogen atom in the molecule of the material is replaced by deuterium atom, the physical and chemical properties of the material will change. In order to more clearly illustrate the effect of material deuteration on bond dissociation energy, FIG. 15 illustrates the change in bond dissociation energy before and after deuteration of the material. As shown in FIG. 15, when the hydrogen atom in the molecule is replaced by deuterium atom, the zero-point vibration energy of the compound may be reduced (from V_{0H} to V_{0D}), the bond dissociation energy of the compound may be increased, and the stability may be improved.

In addition, in a case where the material contains more deuterium atoms, the energy required for the material to undergo side reactions is also relatively high. Therefore, deuteration may make the probability of the material undergoing side reactions relatively low, thereby improving the stability of the material.

In some examples, the host material is a deuterated material.

With such a configuration, compared with the case where the host material does not contain a deuterium atom, the bond dissociation energy of the host material may be increased, resulting in the bond dissociation energy of the host material being higher than the energy of the intermediate of the TTF effect, so that the probability of degradation of the host material due to the energy of the intermediate is relatively low, and the probability of side reactions in the host material may be reduced; thus, the stability of the host material may be improved, so that the service life of the light-emitting device 100 (e.g., the first light-emitting device 101) may be increased. Furthermore, it may be possible to reduce the energy of the intermediate of the TTF effect, increase the difference between the bond dissociation energy of the host material and the energy of the intermediate of the TTF effect, which may reduce the probability of degradation of the host material, so that the stability of the host material and the service life of the light-emitting device 100 (e.g., the first light-emitting device 101) are both improved. In addition, it may be possible to reduce the molecular vibration of the host material, which may reduce the energy loss caused by the molecular vibration of the host material, and reduce the quantum efficiency loss caused by the molecular vibration of the host material, so that the efficiency of the light-emitting device 100 (e.g., the first light-emitting device 101) is improved.

In some examples, the guest material is a deuterated material.

With such a configuration, compared with the case where the guest material does not contain deuterium atoms, the bond dissociation energy of the guest material may be increased, resulting in that the bond dissociation energy of the guest material being higher than the energy of the intermediate of the TTF effect, so that the probability of degradation of the guest material due to the energy of the intermediate is relatively low, and the probability of side reactions in the guest material may be reduced; thus, the stability of the guest material may be improved, so that the service life of the light-emitting device 100 (e.g., the first light-emitting device 101) may be increased. Furthermore, it may be possible to reduce the molecular vibration of the guest material, which may reduce the energy loss caused by the molecular vibration of the guest material, and reduce the quantum efficiency loss caused by the molecular vibration of the guest material, so that the efficiency of the light-emitting device 100 (e.g., the first light-emitting device 101) is improved. In addition, the molecular vibration of the guest material is reduced, which may narrow the emission spectrum of the guest material, so that the color purity of the light-emitting device 100 (e.g., the first light-emitting device 101) is relatively high.

In some embodiments, the first functional material is a deuterated material. The first functional material is, for example, the material of the electron blocking layer 1323.

With such a configuration, compared with the case where the first functional material does not contain deuterium atoms, the bond dissociation energy of the first functional material may be increased, and the probability of side reactions in the first functional material may be reduced, which may improve the electrical stability of the first functional material and improve the electronic resistance of the first functional material to slow down the degradation of the first functional material caused by electrons and excitons, thereby improving the stability of the first functional material and improving the life of the light-emitting device 100 (e.g., the first light-emitting device 101).

In some examples, the host material, the guest material, and the first functional material are all deuterated materials.

As for the beneficial effects that can be achieved when the host material, the guest material and the first functional material are all deuterated materials, reference will be made to the above description, which will not be repeated here.

In some embodiments, a dipole moment of the first functional material is greater than 0 D.

It is understandable that when a molecule is asymmetric, the molecule is relatively more stable, and the higher the asymmetry of the molecule, the higher the stability of the molecule. In the case where the dipole moment of the first functional material is greater than 0 D, the molecule of the first functional material is of an asymmetric structure, which may improve the stability of the first functional material, thereby improving the service life of the light-emitting device 100 (e.g., the first light-emitting device 101).

For example, the dipole moment of the first functional material may be 0.05 D, 0.10 D, 0.20 D, 0.30 D or 0.40 D, etc.

In some examples, a dipole moment of the host material is greater than 0 D; for example, the dipole moment of the host material may be 0.06 D, 0.10 D, 0.20 D, 0.25 D, or 0.30 D, etc. In this way, the stability of the host material may be improved, so that the service life of the light-emitting device 100 (e.g., the first light-emitting device 101) may be improved.

In some examples, the dipole moment of the guest material is greater than 0 D. For example, the dipole moment of the guest material may be 0.04 D, 0.08 D, 0.10 D, 0.20 D, or 0.25 D. In this way, the stability of the guest material may be improved, so that the service life of the light-emitting device 100 (e.g., the first light-emitting device 101) may be improved.

In the related art, since a molecule of the material contains multiple chemical bonds, each chemical bond has a respective bond dissociation energy (BDE). The lowest bond dissociation energy refers to the energy required for bond breaking at the most easily breakable part of the molecule. Considering the methane molecule as an example, the molecule contains four carbon-hydrogen bonds, and each carbon-hydrogen bond has a different bond dissociation energy. The first hydrogen atom in the methane molecule is most easily lost, so that the energy required to lose the first hydrogen atom is the lowest of the bond dissociation energies of methane.

In some embodiments, the lowest bond dissociation energy of the bond dissociation energies of the first functional material in the ground state is greater than or equal to 2.40 eV.

It will be understood that the lowest bond dissociation energy of the bond dissociation energies of the first functional material in the ground state may be used to characterize the molecular stability of the first functional material. In the case where the lowest bond dissociation energy of the first functional material in the ground state is greater than or equal to 2.40 eV, the molecular stability of the first functional material is relatively high, thereby improving the service life of the light-emitting device 100 (e.g., the first light-emitting device 101).

For example, the lowest bond dissociation energy of the first functional material in the ground state may be 2.40 eV, 2.80 eV, 3.50 eV, 4.00 eV, 4.50 eV, or 5.0 eV, etc.

In some embodiments, the lowest bond dissociation energy of the bond dissociation energies of the first functional material in an anionic state is greater than or equal to 1.0 eV.

It will be understood that the lowest bond dissociation energy of the first functional material in an anionic state may be used to characterize the electron resistance of the first functional material. In the case where the lowest bond dissociation energy of the first functional material in the anionic state is greater than or equal to 1.0 eV, the electron resistance of the first functional material is relatively high. In this way, the degradation of the first functional material caused by electrons and excitons may be slowed down, thereby improving the service life of the light-emitting device 100 (e.g., the first light-emitting device 101).

For example, the lowest bond dissociation energy of the first functional material in the anionic state may be 1.0 eV, 1.5 eV, 2.0 eV, 2.5 eV, or 3.0 eV, etc.

In some embodiments, the lowest bond dissociation energy of the bond dissociation energies of the host material in the ground state is greater than or equal to 1.50 eV.

It can be understood that the lowest bond dissociation energy of the bond dissociation energies of the host material in the ground state may be used to characterize the molecular stability of the host material. In the case where the lowest bond dissociation energy of the host material in the ground state is greater than or equal to 1.50 eV, the molecular stability of the host material is relatively high, so that the service life of the light-emitting device 100 (e.g., the first light-emitting device 101) may be improved.

For example, the lowest bond dissociation energy of the bond dissociation energies of the host material in the ground state may be 1.50 eV, 2.00 eV, 2.50 eV, 3.00 eV, 3.50 eV, or 4.00 eV, etc.

In some embodiments, the lowest bond dissociation energy of the bond dissociation energies of the guest material in the ground state is greater than or equal to 1.50 eV.

It can be understood that the lowest bond dissociation energy of the bond dissociation energies of the guest material in the ground state may be used to characterize the molecular stability of the guest material. In the case where the lowest bond dissociation energy of the bond dissociation energies of the guest material in the ground state is greater than or equal to 1.50 eV, the molecular stability of the guest material is relatively high, thereby improving the service life of the light-emitting device 100 (e.g., the first light-emitting device 101).

For example, the lowest bond dissociation energy of the bond dissociation energies of the guest material in the ground state may be 1.50 eV, 2.10 eV, 2.50 eV, 3.00 eV, 3.60 eV, or 4.10 eV, etc.

In some embodiments, a triplet energy level T1(H) of the host material H is less than a triplet energy level T1(G1) of the first functional material G1. That is, the triplet energy level T1(H) of the host material H and the triplet energy level T1(G1) of the first functional material G1 satisfy: T1(H)<T1(G1).

The first functional material G1 is the material of the functional sub-layer, in direct contact with the light-emitting layer 131, of the first type of functional layer (i.e., the hole transport functional layer 132). For example, the material of the first functional material G1 is the material of the electron blocking layer 1323.

It will be understood that in the case where the triplet energy level T1(H) of the host material H is less than the triplet energy level T1(G1) of the first functional material G1, after the holes and electrons recombine to form triplet excitons in the host material, there are relatively few the triplet excitons transferred from the host material to the first functional material. In this way, the triplet excitons may be confined in the light-emitting layer 131 (for example, confined in the host material), which may increase the concentration of triplet excitons in the light-emitting layer 131. Thus, compared with the case where the concentration of triplet excitons is low, the probability of effective collision of triplet excitons may be increased, which may enhance the TTA effect, so that the TTA effect may be fully utilized to improve the efficiency of the light-emitting device 100 (e.g., the first light-emitting device 101).

In some embodiments, the triplet energy level T1(H) of the host material H is less than the triplet energy level T1(D) of the guest material D. That is, the triplet energy level T1(H) of the host material H and the triplet energy level T1(D) of the guest material D satisfy: T1(H)<T1(D).

It will be understood that in the case where the triplet energy level T1(H) of the host material H is less than the triplet energy level T1(D) of the guest material D, after the holes and electrons recombine to form triplet excitons in the host material, the triplet excitons transferred from the host material to the guest material are relatively few. In this way, the triplet excitons may be confined in the host material, which may increase the concentration of triplet excitons distributed in the host material. Thus, compared with the case where the concentration of triplet excitons in the host material is low, the probability of effective collision of triplet excitons may be increased, so that the TTA effect may be enhanced to fully utilize the TTA effect to improve the efficiency of the light-emitting device 100 (e.g., the first light-emitting device 101).

In some embodiments, a singlet energy level S1(H) of the host material H is greater than the singlet energy level S1(D) of the guest material D. That is, the singlet energy level S1(H) of the host material H and the singlet energy level S1(D) of the guest material D satisfy: S1(H)>S1(D).

It will be understood that in the case where the singlet energy level S1(H) of the host material H is greater than the singlet energy level S1(D) of the guest material D, the singlet excitons transferred from the guest material to the host material are relatively few. In this way, relatively more singlet excitons may be confined in the guest material, which increase the concentration of singlet excitons distributed in the guest material. Thus, compared with the case where the concentration of singlet excitons in the guest material is low, relatively more singlet excitons may be used for luminescence, thereby improving the efficiency of the light-emitting device 100 (e.g., the first light-emitting device 101).

In some embodiments, the light-emitting unit 13 further includes a second type of functional layer disposed on a side of the light-emitting layer 131 proximate to the cathode 12; the second type of functional layer includes a third functional sub-layer, and the third functional sub-layer is in contact with the light-emitting layer 131; the material of the third functional sub-layer includes a third functional material G3. A triplet energy level T1(H) of the host material H is less than a triplet energy level T1(G3) of the third functional material G3; That is, the triplet energy level T1(H) of the host material H and the triplet energy level T1(G3) of the third functional material G3 satisfy: T1(H)<T1(G3).

The second type of functional layer is the electron transport functional layer 133. The third functional sub-layer may be one of an electron injection layer 1331, an electron transport layer 1332 and a hole blocking layer 1333. The third functional material is the material of the functional sub-layer, in direct contact with the light-emitting layer 131, of the second type of functional layer (i.e., the electron transport functional layer 133). For example, the third functional material G3 is the material of the hole blocking layer 1333.

It will be understood that in the case where the triplet energy level T1(H) of the host material H is less than the triplet energy level T1(G3) of the third functional material G3, after the holes and electrons recombine to form triplet excitons in the host material, the triplet excitons transferred from the main material to the third functional material are relatively few. In this way, the triplet excitons may be confined in the light-emitting layer 131 (for example, confined in the host material), which may increase the concentration of triplet excitons in the light-emitting layer 131. Thus, compared with the case where the concentration of triplet excitons is low, the probability of effective collision of triplet excitons may be increased, so that the TTA effect may be enhanced to fully utilize the TTA effect to improve the efficiency of the light-emitting device 100 (e.g., the first light-emitting device 101).

The structures of the host material, the guest material, and the first functional material are exemplarily introduced below.

In some embodiments, the host material H is selected from the structures shown in the following general formula (I).

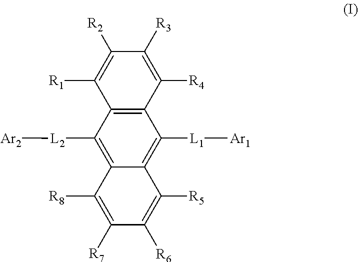

In the general formula, R₁, R₂, R₃, R₄, R₅, R₆, R₇ and R₈ are the same or different and are independently selected from hydrogen, deuterium, substituted or unsubstituted alkyl, substituted or unsubstituted alkoxy, substituted or unsubstituted aryl, substituted or unsubstituted aryloxy, substituted or unsubstituted diarylamino, substituted or unsubstituted siloxane and substituted or unsubstituted silyl.
L₁ and L₂ are the same or different, and are independently selected from a single bond, substituted or unsubstituted arylene and substituted or unsubstituted heteroarylene.
Ar₁ and Ar₂ are the same or different, and are independently selected from substituted or unsubstituted aryl.
At least one of R₁, R₂, R₃, R₄, R₅, R₆, R₇, R₈, L₁, L₂, Ar₁ and Ar₂ contains deuterium.

It will be noted that in a case where R₁, R₂, R₃, R₄, R₅, R₆, R₇, or R₈ is selected from substituted alkyl, substituted alkoxy, substituted aryl, substituted aryloxy, substituted diarylamino, substituted siloxane and substituted silyl, and/or L₁ or L₂ is any one of substituted arylene and substituted heteroarylene, and/or Ar₁ and Ar₂ are selected from substituted aryl; the type and number of the substituents are not limited here.

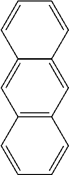 [SMILES: c1ccc2cc3ccccc3cc2c1]

It will be noted that in the general formula (I), is anthryl. Furthermore, in the above general formula (I), L₁ and L₂ may each be a single bond. In a case where L₁ is a single bond, anthryl and Ar₁ are directly connected through the single bond. In a case where L₂ is a single bond, anthryl and Ar₂ are directly connected through the single bond. In the general formula (I), L₁ and L₂ may each be any of substituted or unsubstituted arylene and substituted or unsubstituted heteroarylene. The structure of arylene will be described below by considering phenylene as an example. Phenyl is a general term for the remaining groups after the hydrogen atom of a carbon atom on the benzene ring is removed. Phenylene is a general name for the remaining groups after the hydrogen atoms of two carbon atoms on the benzene ring are removed. For understanding of heteroarylene, reference may be made to the above contents, and details are not repeated here.

It will be understood that in the case where at least one of R₁, R₂, R₃, R₄, R₅, R₆, R₇, R₈, L₁, L₂, Ar₁ and Ar₂ contains deuterium, the host material H is a deuterated material. Since the exciton recombination mainly occurs on the host material H, the TTF effect is also mainly realized on the host material. Therefore, compared with the case where the host material H does not contain a deuterium atom, by setting the host material H is a deuterated material, the bond dissociation energy of the host material H may be increased, and the energy of the intermediate of the TTF effect may be reduced, so that the bond dissociation energy of the host material H is higher than the energy of the intermediate of the TTF effect. Thus, the probability of degradation of the host material H may be reduced due to the energy of the intermediate, so that the stability of the host material H and the service life of the light-emitting device 100 (e.g., the first light-emitting device 101) are both improved.

Moreover, in a case where the deuterated position is the position of a carbon-hydrogen bond is located, a carbon-deuterium bond is formed. The carbon-hydrogen bond is usually a relatively weak energy part in the organic material. Through deuteration, the carbon-hydrogen bond may be replaced by a carbon-deuterium bond, which may shorten the bond length, increase the bond dissociation energy, and reduce the probability of side reactions in the host material, so that the molecular stability of the host material is improved. In this way, it is possible to improve the tolerance of the host material for the high-energy intermediate of the TTF effect, so that the service life of the light-emitting device 100 (e.g., the first light-emitting device 101) is improved.

In addition, the structure shown in the general formula (I) contains anthryl; that is, the host material H is an anthryl derivative. During the light-emitting process of the light-emitting device 100, electrons and holes recombine at the position where anthryl is located to form triplet excitons, so that the triplet excitons have a relatively high distribution density at the position where anthryl is located. In this way, the collision and fusion between triplet excitons may be increased, the TTA effect (e.g., the TTF effect) may be enhanced, so that the efficiency of the light-emitting device 100 (e.g., the first light-emitting device 101) may be improved.

Exemplary structures of the host material H with the structure represented by the general formula (I) are introduced below.

In some examples, in a case where R₁, R₂, R₃, R₄, R₅, R₆, R₇ and R₈ are all deuterium, and Ar₁ and Ar₂ do not contain deuterium, the structural formula of the host material H may be as shown below.

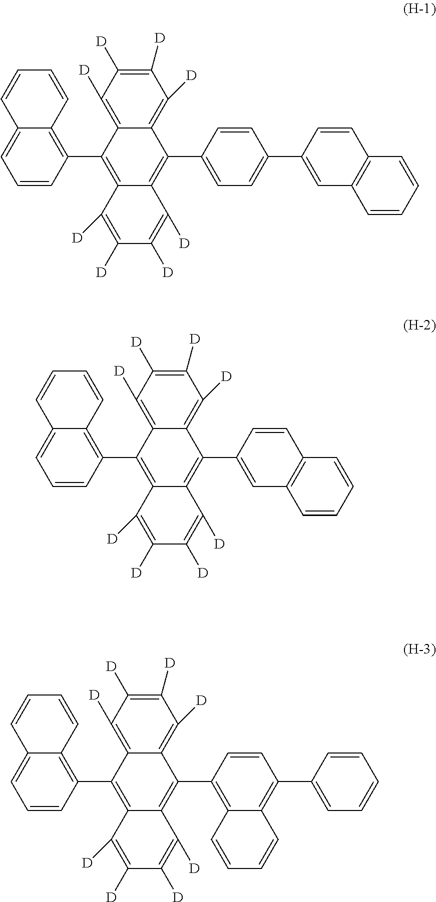 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3ccc(-c4ccccc4)c4ccccc34)c3c([2H])c([2H])c([2H])c([2H])c3c(-c3cccc4ccccc34)c2c1[2H]]

In some examples, in a case where R₁, R₂, R₃, R₄, R₅, R₆, R₇ and R₈ are all hydrogen, and Ar₁ and/or Ar₂ contain deuterium, the structural formula of the host material H may be as shown below.

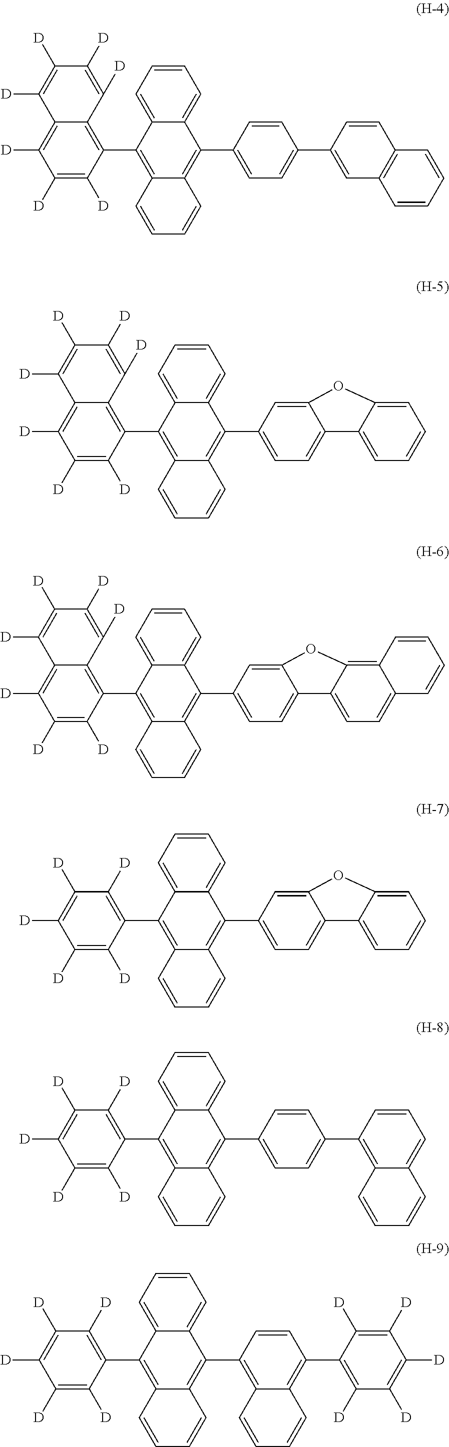

In some examples, when R₁, R₂, R₃, R₄, R₅, R₆, R₇ and R₈ are all deuterium, and Ar₁ and/or Ar₂ contain deuterium, the structural formula of the host material H may be as shown below.

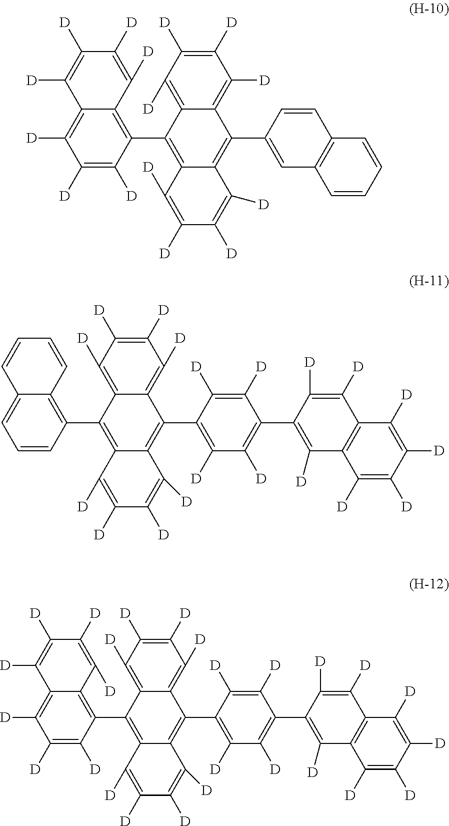

It will be noted that the structural formulas listed above are examples of the structure of the host material H, but not limitations on the structure of the host material H. in addition, “(H-x)” in the above structural formulas is a name of each structural formula but is not part of the structure in the structural formula, where x is a positive integer.

In some embodiments, in the case where the host material is a deuterated material, a mass fraction of deuterium in the host material is greater than or equal to 1.0% and less than or equal to 4.9%.

The mass fraction of deuterium in the host material refers to, in the structure of the host material, a ratio of the relative molecular mass of deuterium atoms to the relative molecular mass of the host material molecules.

It will be understood that in the case where the mass fraction of deuterium in the host material is greater than or equal to 1.0% and less than or equal to 4.9%, the mass fraction of deuterium in the host material is relatively high, that is, the host material contains relatively more deuterium atoms. As mentioned above, in the case where the number of deuterium atoms in the host material is relatively great, the bond dissociation energy and stability of the host material may be improved, so that the service life of the light-emitting device 100 (e.g., the first light-emitting device 101) is improved. Moreover, the molecular vibration of the host material may be reduced, and the quantum efficiency loss caused by the molecular vibration of the host material may be reduced, so that the efficiency of the light-emitting device 100 (e.g., the first light-emitting device 101) is improved. In addition, in a case where the host material contains relatively more deuterium atoms, the energy required for the host material to undergo side reactions is also relatively high. In this way, the probability of the host material undergoing side reactions may be relatively low, thereby improving the stability of the host material.

For example, the host material H is selected from the structures represented by general formula (I), and the mass fraction of deuterium in the host material is greater than or equal to 1.0% and less than or equal to 4.9%.

For example, the mass fraction of deuterium in the host material is 1.0%, 1.5%, 2.0%, 2.5%, 3.0%, 4.0%, 4.9%, etc.

In some embodiments, the guest material D is selected from structures represented by the following general formula (II).

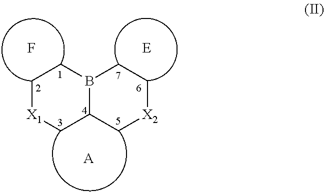

In the general formula, A, E and F are the same or different, and are independently selected from substituted or unsubstituted aromatic ring, substituted or unsubstituted heteroaromatic ring, and substituted or unsubstituted cycloalkane; in the case where A, E and F are each selected from substituted aromatic ring, substituted heteroaromatic ring and substituted cycloalkane, the substituent may be connected to an adjacent substituent to form a substituted or unsubstituted ring.

X₁ and X₂ are the same or different, and are independently selected from O, N(Rₐ) and C(R_{b}R_{c}). Here, O is oxygen, N(Rₐ) is a group in which a hydrogen atom on the nitrogen is substituted by Rₐ, and C(R_{b}R_{c}) is a group in which hydrogen atoms on the carbon are respectively substituted by R_{b} and R_{c}.

Rₐ, R_{b} and R_{c} are the same or different and are independently selected from hydrogen, deuterium, halogen, cyano, substituted or unsubstituted alkyl, substituted or unsubstituted silyl, substituted or unsubstituted alkoxy, substituted or unsubstituted aryl and substituted or unsubstituted heterocyclic.

At least one of A, E and F contains deuterium.

It will be noted that, in the structure represented by the general formula (II), B is boron; a relationship between A and the ring where X₁ and B are located and ring where X₂ and B are located means that the ring where X₁ and B are located, and the ring where X₂ and B are located and A are fused by sharing carbons at positions 3, 4, and 5; a relationship between the ring where X₁ and B are located and F means that the ring where X₁ and B are located and F are fused by sharing carbons at positions 1 and 2; a relationship between the ring where X₂ and B are located and E means that the ring where X₂ and B are located and E are fused by sharing carbons at positions 6 and 7. Although the structure shown in the general formula (II) shows that the sizes of E and F are inconsistent with the size of A, it is only to indicate that A, E, F, the ring where X₁ and B are located, and the ring where X₂ and B are located are fused in relationship, and the relative sizes of the rings are not limited.

It will be noted that, in the case where A, E and F are each selected from substituted aromatic ring, substituted heteroaromatic ring and a substituted cycloalkane, a substituent may be connected to an adjacent substituent to form a substituted or unsubstituted ring, and the term “substituent” and “adjacent substituent” mentioned here may be two substituents located on the same ring, or may be two substituents located on two adjacent rings of A, E and F, which is not limited here.

In some examples, in the case where A, E and F are each selected from substituted aromatic ring, substituted heteroaromatic ring and a substituted cycloalkane, a substituent is connected to an adjacent substituent to form a substituted or unsubstituted ring containing heteroatoms such as O, N, or S.

It will be noted that, in the case where A, E and F are each selected from substituted aromatic ring, substituted heteroaromatic ring and a substituted cycloalkane, and/or Rₐ, R_{b} or R_{c} is selected from substituted alkyl, substituted silyl, substituted alkoxy, substituted aryl and substituted heterocyclic, the type and number of the substituents are not limited here.

It is understood that in the case where at least one of A, E and F contains deuterium, the guest material D is a deuterated material. Compared with the case where the guest material D does not contain deuterium atoms, as described above, the bond dissociation energy of the guest material D may be increased, so that the probability of degradation of the guest material D due to the energy of the intermediate is relatively lower, and the probability of side reactions in the guest material D may be reduced, which may improve the stability of the guest material D and the service life of the light-emitting device 100 (e.g., the first light-emitting device 101). Furthermore, the energy loss caused by the vibration of the guest material molecules may be reduced, so that the efficiency of the light-emitting device 100 (e.g., the first light-emitting device 101) is improved. In addition, it is possible to suppress molecular vibration and narrow the emission spectrum of the guest material D, so that the color purity of the light-emitting device 100 (e.g., the first light-emitting device 101) is relatively high.

Exemplary structures of the guest material D with the structure represented by the general formula (II) are introduced below.

In some examples, in a case where X₁ and X₂ are both N(Rₐ), and two Rₐ do not contain deuterium, the structural formula of the guest material D may be as shown below.

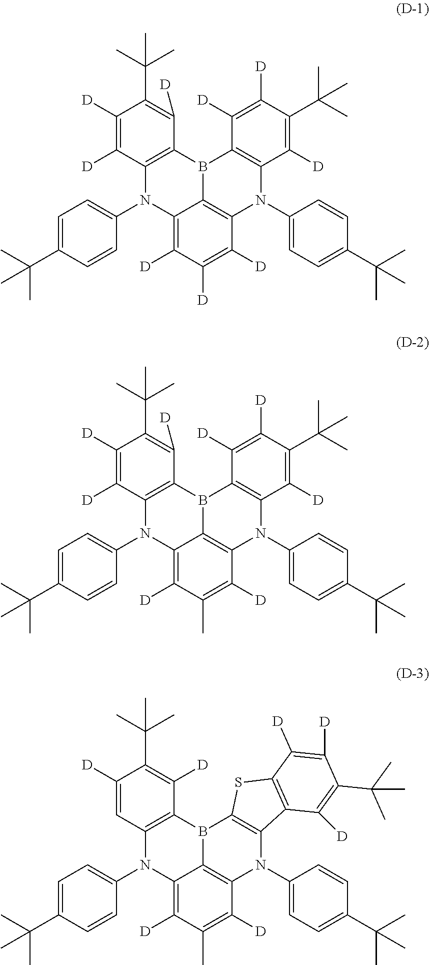

In some examples, in the case where X₁ and X₂ are both N(Rₐ), and two Rₐ contain deuterium, the structural formula of the guest material D may be as shown below.

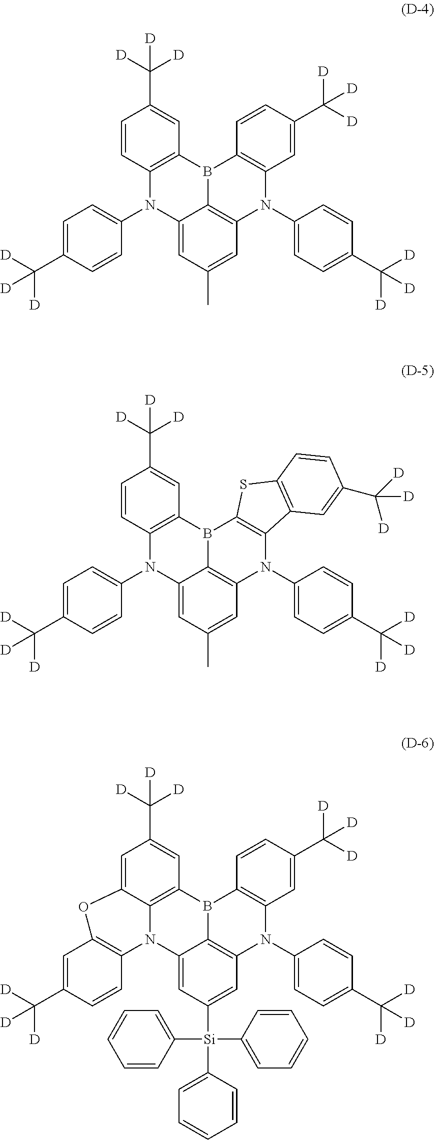 [SMILES: [2H]C([2H])([2H])c1ccc(N2c3ccc(C([2H])([2H])[2H])cc3B3c4ccc(C([2H])([2H])[2H])cc4N(c4ccc(C([2H])([2H])[2H])cc4)c4cc(C)cc2c43)cc1 ; [2H]C([2H])([2H])c1ccc(N2c3ccc(C([2H])([2H])[2H])cc3B3c4sc5ccc(C([2H])([2H])[2H])cc5c4N(c4ccc(C([2H])([2H])[2H])cc4)c4cc(C)cc2c43)cc1 ; [2H]C([2H])([2H])c1ccc(N2c3cc(C([2H])([2H])[2H])ccc3B3c4cc(C([2H])([2H])[2H])cc5c4N(c4ccc(C([2H])([2H])[2H])cc4O5)c4cc([Si](c5ccccc5)(c5ccccc5)c5ccccc5)cc2c43)cc1]

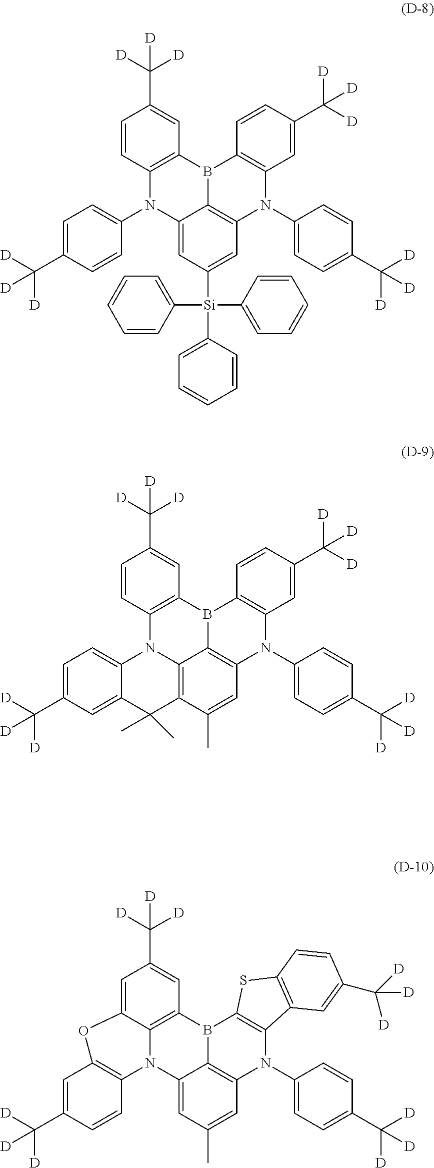 [SMILES: [2H]C([2H])([2H])c1ccc(N2c3ccc(C([2H])([2H])[2H])cc3B3c4ccc(C([2H])([2H])[2H])cc4N(c4ccc(C([2H])([2H])[2H])cc4)c4cc([Si](c5ccccc5)(c5ccccc5)c5ccccc5)cc2c43)cc1 ; [2H]C([2H])([2H])c1ccc(N2c3cc(C([2H])([2H])[2H])ccc3B3c4cc(C([2H])([2H])[2H])ccc4N4c5ccc(C([2H])([2H])[2H])cc5C(C)(C)c5c(C)cc2c3c54)cc1 ; [2H]C([2H])([2H])c1ccc(N2c3cc(C)cc4c3B(c3cc(C([2H])([2H])[2H])cc5c3N4c3ccc(C([2H])([2H])[2H])cc3O5)c3sc4ccc(C([2H])([2H])[2H])cc4c32)cc1]

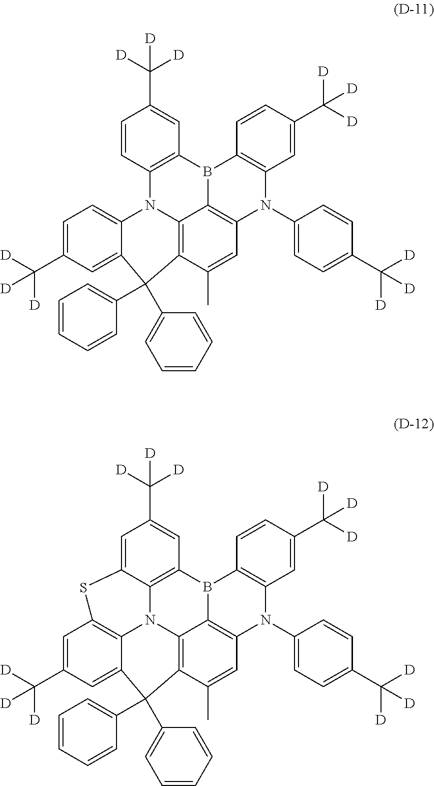 [SMILES: [2H]C([2H])([2H])c1ccc(N2c3cc(C([2H])([2H])[2H])ccc3B3c4cc(C([2H])([2H])[2H])ccc4N4c5ccc(C([2H])([2H])[2H])cc5C(c5ccccc5)(c5ccccc5)c5c(C)cc2c3c54)cc1 ; [2H]C([2H])([2H])c1ccc(N2c3cc(C([2H])([2H])[2H])ccc3B3c4cc(C([2H])([2H])[2H])cc5c4N4c6c(cc(C([2H])([2H])[2H])cc6C(c6ccccc6)(c6ccccc6)c6c(C)cc2c3c64)S5)cc1]

In some examples, in the case where X₁ is N(Rₐ), Rₐ contains deuterium, and X₂ is C(R_{b}R_{c}), the structural formula of the guest material D may be as shown below.

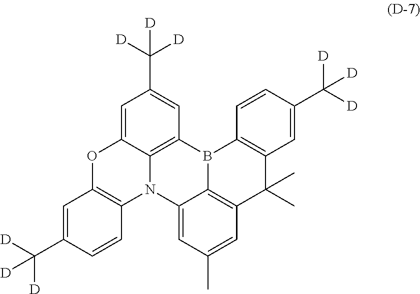 [SMILES: [2H]C([2H])([2H])c1ccc2c(c1)Oc1cc(C([2H])([2H])[2H])cc3c1N2c1cc(C)cc2c1B3c1ccc(C([2H])([2H])[2H])cc1C2(C)C]

It will be noted that the structural formulas listed above are examples of the structure of the guest material D, but not limitations on the structure of the guest material D. Moreover, “(D-x)” in the above structural formulas is a name of a respective structural formula but is not part of the structure represented by the structural formula, where x is a positive integer.

In some embodiments, a substituent of at least one of A, E, and F includes tert-butyl.

In the related art, tert-butyl is the remaining group after removing the hydrogen atom from methine of the 2-methylpropane molecule, and has a structure similar to a tetrahedron. Therefore, in a case where tert-butyl is used as a substituent, the structure has good stereo effect and spatial effect.

It will be understood that in the case where a substituent of at least one of A, E and F includes tert-butyl, the structure represented by the general formula (II) has a certain stereoactivity, which improves the stereoactivity of the structure of the guest material D and reduces the planarity of the structure of the guest material D. Since the low planarity of the material structure may increase the distance between molecules, which may reduce the intermolecular forces, and reduce the orderly stacking of molecules, so that the quenching of excitons may be relatively less. Therefore, due to the configuration of a substituent of at least one of A, E and F to including tert-butyl, the quenching of excitons on the guest material D may be relatively less, and the exciton concentration on the guest material may be relatively high, so that the efficiency of the light-emitting device 100 (e.g., the first light-emitting device 101) may be improved.

It will be noted that, in the case where at least one of A, E and F contains deuterium and a substituents of at least one of A, E and F includes tert-butyl, in A, E and F, the ring in which a substituent contains deuterium and the ring in which a substituent contains tert-butyl may be the same or different, which is not limited here. Furthermore, in a case where the substituent includes tert-butyl, part of the hydrogen atoms in tert-butyl may be substituted with deuterium, that is, tert-butyl may be deuterium-substituted tert-butyl, which is not limited here.

Exemplary structures of the guest material D in a case where a substituent of at least one of A, E and F in the structure represented by the general formula (II) includes tert-butyl will be described below.

In some examples, in the case where the substituent of E and the substituent of F both include tert-butyl, the structural formula of the guest material D may be as shown in (D-1), (D-2), and (D-3) above.

It will be noted that the structural formulas listed above are examples of the structure of the guest material D, but not limitations on the structure of the guest material D.

In some embodiments, in the case where the guest material D is a deuterated material, a mass fraction of deuterium in the guest material D is greater than or equal to 0.1% and less than or equal to 8.5%.

The mass fraction of deuterium in the guest material refers to, in the structure of the guest material, a ratio of the relative molecular mass of deuterium atoms to the relative molecular mass of the guest material molecules.

It will be understood that in the case where the mass fraction of deuterium in the guest material is greater than or equal to 0.1% and less than or equal to 8.5%, the mass fraction of deuterium in the guest material is relatively high, that is, the guest material contains relatively more deuterium atoms. As mentioned above, in a case where the number of deuterium atoms in the guest material is relatively large, the bond dissociation energy and stability of the guest material may be improved, so that the service life of the light-emitting device 100 (e.g., the first light-emitting device 101) is improved. Moreover, the molecular vibration of the guest material may be reduced, and the quantum efficiency loss caused by the molecular vibration of the guest material may be reduced, so that the efficiency of the light-emitting device 100 (e.g., the first light-emitting device 101) is improved. Furthermore, in a case where the number of deuterium atoms in the guest material is relatively large, molecular vibration may be suppressed, and the emission spectrum of the guest material may be narrowed, so that the color purity of the light-emitting device 100 (e.g., the first light-emitting device 101) is relatively high. In addition, in the case where the guest material contains relatively more deuterium atoms, the energy required for the guest material to undergo side reactions is relatively high, so that the probability of the guest material undergoing side reactions may be relatively low to improve the stability of the guest material.

For example, the guest material D is selected from the structures represented by general formula (II), and the mass fraction of deuterium in the guest material is greater than or equal to 0.1% and less than or equal to 8.5%.

For example, the mass fraction of deuterium in the guest material may be 0.1%, 1.0%, 3.0%, 5.0%, 7.0% or 8.5%, etc.

In some embodiments, the first functional material is selected from the structures represented by the following general formula (III).

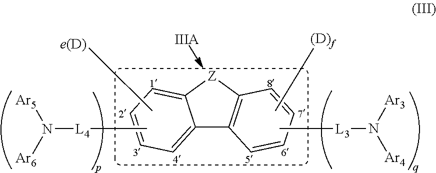

In the general formula, Z is selected from O, S, N(R_{d}) and C(RₑR_{f}). Here, O is oxygen, S is sulfur, N(Rₐ) is a group in which a hydrogen atom on the nitrogen is substituted by R_{d}, and C(RₑR_{f}) is a group in which hydrogen atoms on the carbon are respectively substituted by Rₑ and R_{f}.
R_{d}, Rₑ, and R_{f} are the same or different, and are independently selected from substituted or unsubstituted alkyl, substituted or unsubstituted aryl, and substituted or unsubstituted heteroaryl.
L₃ and L₄ are the same or different, and are independently selected from single bond, substituted or unsubstituted arylidene, and substituted or unsubstituted heteroarylene.
e and f are the same or different, and are independently selected from 1, 2, 3 and 4.
Ar₃, Ar₄, Ar₅ and Ar₆ are the same or different, and are independently selected from substituted or unsubstituted C6-C60 aryl and substituted or unsubstituted C2-C60 heteroaryl; C2-C60 heteroaryl includes at least one heteroatom, and the heteroatom includes N, O and S, where O is oxygen, S is sulfur, and N is nitrogen.
p and q are the same or different and are independently selected from 0, 1 and 2; and a sum of p and q is greater than or equal to 1 and less than or equal to 2.

As for the structure represented by the general formula (III), the following points need to be explained.

For the description that L₃ or L₄ is a single bond, reference may be made to the above description that L₁ or L₂ is a single bond; for the description of aryl and heteroaryl, reference may be made to the above description of aryl and heteroaryl; for the description of arylene and heteroarylene, reference may be made to the above description of arylene and heteroarylene, which will not be repeated here.

The term of “Cx aryl” refers to aryl containing x carbon (C) atoms in total, where x is a positive integer, and the same applies below. For understandings of other terms such as “Cx heteroaryl”, reference may be made to the above contents, and details are not repeated here.

The connection position between L₃ and the IIIA part shown in the general formula (III) means that L3 may be connected to any carbon having a substitution position among carbons at positions 1′, 2′, 3′, and 4′ of the IIIA part. For understanding of the connection position between deuterium (D) and the IIIA part, the connection position between L4 and the IIIA part, etc., reference will be made to the above content and will not be repeated here. The connection positions between the IIIA part and any two deuteriums (D) of the e deuteriums (D) and the f deuteriums (D) are all different. Moreover, in a case where e is 4, p is 0; in a case where f is 4, q is 0.

In the case where a sum of p and q is 1, the structure represented by the general formula (III) contains one triarylamine structure; in a case where the sum of p and q is 2, the structure represented by the general formula (III) contains two triarylamine structures.

In a case where R_{d}, Rₑ or R_{f} is selected from substituted alkyl, substituted aryl and substituted heteroaryl, and/or L₃ or L₄ is selected from substituted arylene and substituted heteroarylene, and/or Ar₃, Ar₄, Ar₅ or Ar₆ is selected from substituted C6-C60 aryl and substituted C2-C60 heteroaryl, the type and number of substituents are not limited here.

It can be understood that in a case where Z is oxygen, the IIIA part is a dibenzofuran structure; in a case where Z is sulfur, the IIIA part is a dibenzothiophene structure; in a case where Z is nitrogen, the IIIA part is a carbazole structure. In the case where the IIIA part is a dibenzofuran structure, a dibenzothiophene structure or a carbazole structure, the positions where carbons at positions 1′ to 8′ are located and the position where Z is located have high reactivity. When chemical reactions occur at these positions, degradation will occur on the first functional material. In the structure shown in the general formula (III), e deuteriums (D) and f deuteriums (D) are connected to (e+f) carbons of the carbons at positions 1′ to 8′; that is, hydrogens at high reaction active sites are replaced by multiple deuteriums. Thus, it is possible to shorten the bond length to increase the bond dissociation energy, thereby improving the molecular stability of the first functional material; moreover, the probability of side reactions occurring on the first functional material may be reduced. As a result, the electrical stability of the first functional material may be improved, the electronic resistance of the first functional material may be improved, which may slow down the degradation of the first functional material caused by electrons and excitons, so that the stability of the first functional material is improved, and the service life of the light-emitting device 100 (e.g., the first light-emitting device 101) is improved.

Furthermore, in the case where the IIIA part is a dibenzofuran structure, a dibenzothiophene structure or a carbazole structure, the triplet energy level of the first functional material is relatively high, so that the difference between the triplet energy level of the first functional material and the triplet energy level of the host material is relatively large. In this way, after the holes and electrons recombine in the host material to form triplet excitons, the triplet excitons transferred from the host material to the first functional material are relatively few, so that the triplet excitons may be confined in the light-emitting layer 131 (for example, confined in the host material). As a result, the triplet exciton concentration in the light-emitting layer 131 may be increased, the TTA effect may be enhanced, which may fully utilize the TTA effect to improve the efficiency of the light-emitting device 100 (e.g., the first light-emitting device 101).

In a case where Z is carbon, the IIIA part is a structure of fluorene or spirofluorene. In the structure of fluorene or spirofluorene, the sp3 carbon (i.e., Z) is an unstable part of the molecule, and defective may occur due to chemical reactions. In the structure shown in the above general formula (III), e deuteriums (D) and f deuteriums (D) are connected to (e+f) carbons of the carbons at positions 1′ to 8′ to form a multi-deuterium-substituted fluorene or spirofluorene structure. Thus, it is possible to improve the molecular stability and electrical stability of the first functional material, and improve the electronic resistance of the first functional material, so that the service life of the light-emitting device 100 (e.g., the first light-emitting device 101) may be increased. Furthermore, it is possible to reduce the zero point energy, i.e., the energy of the ground state, and reduce the molecular hard-core volume caused by a case that the bonding length of deuterium-carbon is shorter than that of hydrogen-carbon, so that the electrical polarizability may be reduced, which may play a role of reducing crystallinity of thin film, i.e., the amorphous state. The grain boundary is reduced through isotropic and homogeneous properties of the amorphous state, allowing charges to flow quickly, thereby improving the hole mobility of the first functional material.

Exemplary structures of the first functional material G1 with the structure represented by the general formula (III) are introduced below.

In some examples, in the case where Z is oxygen, the structural formula of the first functional material G1 may be as shown in the following formulas.

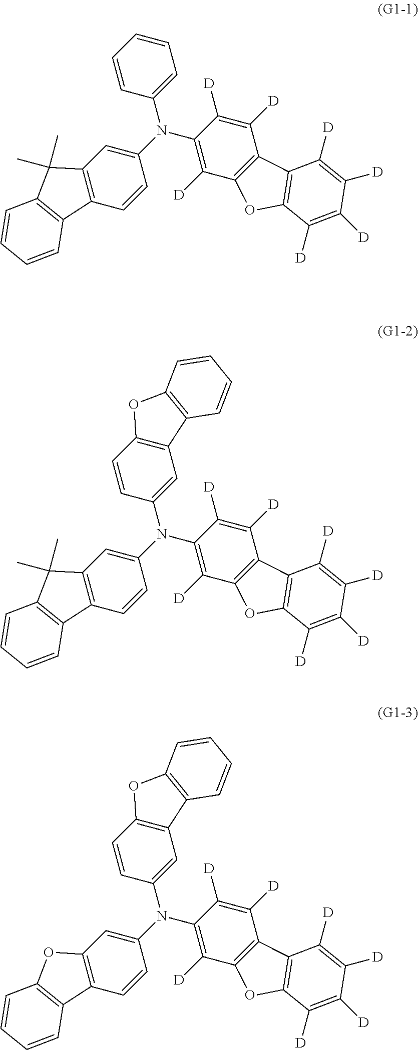 [SMILES: [2H]c1c([2H])c([2H])c2c(oc3c([2H])c(N(c4ccccc4)c4ccc5c(c4)C(C)(C)c4ccccc4-5)c([2H])c([2H])c32)c1[2H] ; [2H]c1c([2H])c([2H])c2c(oc3c([2H])c(N(c4ccc5c(c4)C(C)(C)c4ccccc4-5)c4ccc5oc6ccccc6c5c4)c([2H])c([2H])c32)c1[2H] ; [2H]c1c([2H])c([2H])c2c(oc3c([2H])c(N(c4ccc5c(c4)oc4ccccc45)c4ccc5oc6ccccc6c5c4)c([2H])c([2H])c32)c1[2H]]

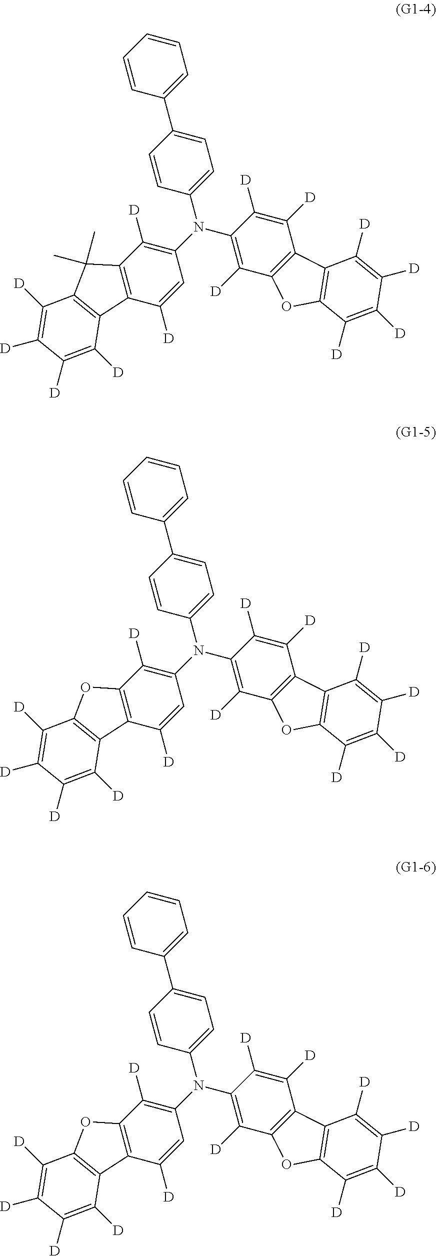 [SMILES: [2H]c1cc(N(c2ccc(-c3ccccc3)cc2)c2c([2H])c([2H])c3c(oc4c([2H])c([2H])c([2H])c([2H])c43)c2[2H])c([2H])c2c1-c1c([2H])c([2H])c([2H])c([2H])c1C2(C)C ; [2H]c1c([2H])c([2H])c2c(oc3c([2H])c(N(c4ccc(-c5ccccc5)cc4)c4c([2H])c([2H])c5c(oc6c([2H])c([2H])c([2H])c([2H])c65)c4[2H])cc([2H])c32)c1[2H] ; [2H]c1c([2H])c([2H])c2c(oc3c([2H])c(N(c4ccc(-c5ccccc5)cc4)c4c([2H])c([2H])c5c(oc6c([2H])c([2H])c([2H])c([2H])c65)c4[2H])cc([2H])c32)c1[2H]]

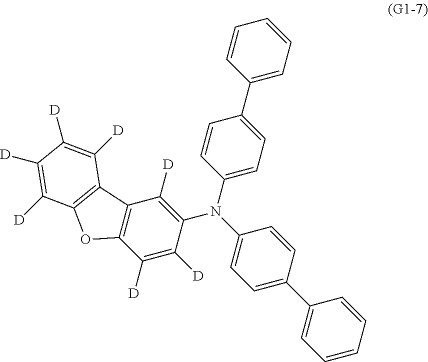 [SMILES: [2H]c1c([2H])c([2H])c2c(oc3c([2H])c([2H])c(N(c4ccc(-c5ccccc5)cc4)c4ccc(-c5ccccc5)cc4)c([2H])c32)c1[2H]]

In some examples, in the case where Z is sulfur, the structural formula of the first functional material G1 may be as shown in the following formulas.

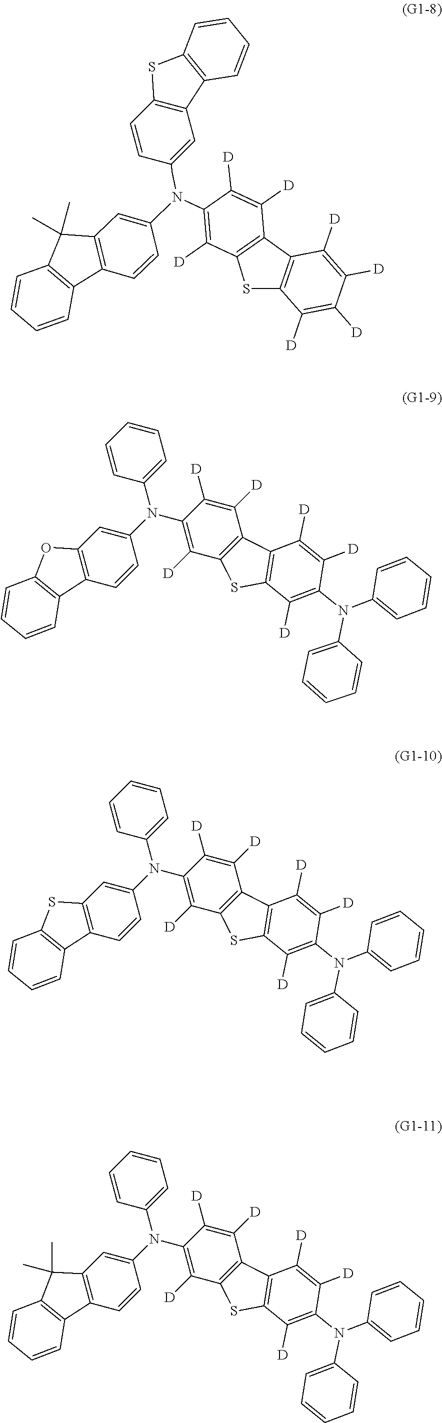 [SMILES: [2H]c1c([2H])c([2H])c2c(sc3c([2H])c(N(Cc4ccc5sc6ccccc6c5c4)c4ccc5c(c4)C(C)(C)c4ccccc4-5)c([2H])c([2H])c32)c1[2H] ; [2H]c1c(N(c2ccccc2)c2ccccc2)c([2H])c2sc3c([2H])c(N(c4ccccc4)c4ccc5c(c4)oc4ccccc45)c([2H])c([2H])c3c2c1[2H] ; [2H]c1c(N(c2ccccc2)c2ccccc2)c([2H])c2sc3c([2H])c(N(c4ccccc4)c4ccc5c(c4)sc4ccccc45)c([2H])c([2H])c3c2c1[2H] ; [2H]c1c(N(c2ccccc2)c2ccccc2)c([2H])c2sc3c([2H])c(N(c4ccccc4)c4ccc5c(c4)C(C)(C)c4ccccc4-5)c([2H])c([2H])c3c2c1[2H]]

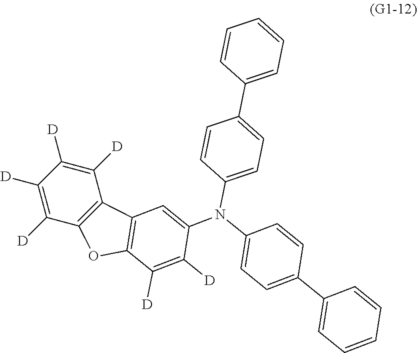 [SMILES: [2H]c1c(N(c2ccc(-c3ccccc3)cc2)c2ccc(-c3ccccc3)cc2)cc2c(oc3c([2H])c([2H])c([2H])c([2H])c32)c1[2H]]

In some examples, in the case where Z is phenyl-substituted nitrogen, the structural formula of the first functional material G1 may be as shown in the following formula.

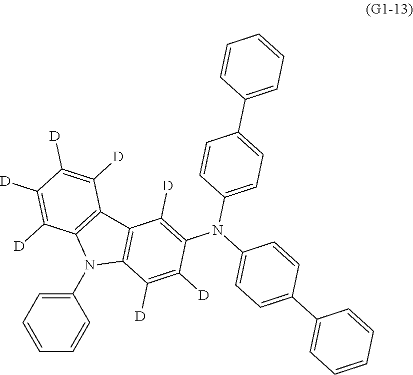 [SMILES: [2H]c1c([2H])c([2H])c2c(c1[2H])c1c([2H])c(N(c3ccc(-c4ccccc4)cc3)c3ccc(-c4ccccc4)cc3)c([2H])c([2H])c1n2-c1ccccc1]

In some examples, in a case where Z is methyl-substituted carbon, the structural formula of the first functional material G1 may be as shown in the following formulas.

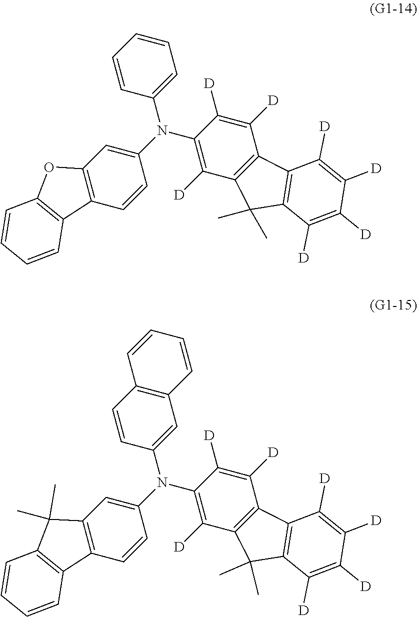 [SMILES: [2H]c1c([2H])c([2H])c2c(c1[2H])-c1c([2H])c([2H])c(N(c3ccccc3)c3ccc4c(c3)oc3ccccc34)c([2H])c1C2(C)C ; [2H]c1c([2H])c([2H])c2c(c1[2H])-c1c([2H])c([2H])c(N(c3ccc4c(c3)C(C)(C)c3ccccc3-4)c3ccc4ccccc4c3)c([2H])c1C2(C)C]

It will be noted that the structural formulas listed above are examples of the structure of the first functional material G1, but not limitations on the structure of the first functional material G1. Similarly, “(G1-x)” in the above structural formulas is a name of a respective structural formula but is not part of the structure in the structural formula, where x is a positive integer.

In some embodiments, the first functional material is selected from the structures represented by the following general formula (III-A).

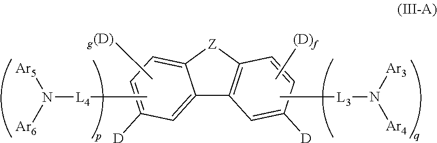

In the general formula, g and h are the same or different, and are independently selected from 0, 1, 2 and 3.

In the structure represented by the general formula (III-A), in a case where carbons at positions 3′ and 6′ are connected to deuterium, the structure represented by the general formula (III) may be transformed into the structure represented by the general formula (III-A).

It will be understood that in the IIIA part of the structure shown in the general formula (III), the reaction activity of carbons at positions 3′ and 6′ is relatively higher than that of carbons at positions 1′, 2′, 4′, 5′, 7′ and 8′. In a case where a chemical reaction occurs on carbons at positions 3′ and 6′, it may cause degradation of the first functional material. In the structure shown in the above general formula (III-A), hydrogens connected to carbons at positions 3′ and 6′ are replaced by deuterium, which may shorten the bond length and increase the bond dissociation energy, so that the probability of side reactions occurring on the first functional material is reduced to improve the molecular stability of the first functional material. In this way, it is possible to improve the electrical stability of the first functional material, and improve the electronic resistance of the first functional material, which may slow down the degradation of the first functional material caused by electrons and excitons, so that the stability of the first functional material may be improved, and the service life of the light-emitting device 100 (e.g., the first light-emitting device 101) can be improved.

Exemplary structures of the first functional material G1 with the structure represented by the general formula (III-A) are introduced below.

In some examples, in the case where Z is oxygen, the structural formula of the first functional material G1 may be as shown in (G1-1) to (G1-6) above.

In some examples, in the case where Z is sulfur, the structural formula of the first functional material G1 may be as shown in (G1-8) to (G1-11) above.

In some examples, in the case where Z is methyl-substituted carbon, the structural formula of the first functional material G1 may be as shown in (G1-14) and (G1-15) above.

It will be noted that the structural formulas listed above are examples of the structure of the first functional material G1, but not limitations on the structure of the first functional material G1.

In some embodiments, the first functional material is selected from the structures represented by the following general formula (IV).

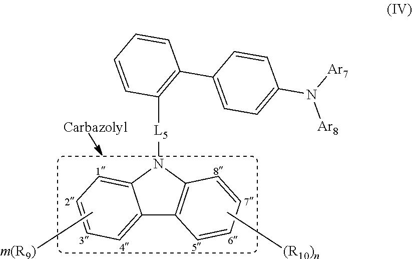

In the general formula, L₅ is selected from single bond, and substituted or unsubstituted C6-C60 arylene.
Ar₇ and Ar₈ are the same or different, and are independently selected from substituted or unsubstituted C6-C60 aryl, and substituted or unsubstituted C2-C60 heteroaryl; C2-C60 heteroaryl includes at least one heteroatom, and the heteroatom includes N, O and S, where N is nitrogen, O is oxygen, and S is sulfur.
R₉ and R₁₀ are the same or different and are independently selected from hydrogen, deuterium, halogen, cyano, nitro, amino, substituted or unsubstituted C1-C60 alkyl, substituted or unsubstituted C3-C60 cycloalkyl, substituted or unsubstituted C2-C60 alkenyl, substituted or unsubstituted C6-C60 aryl, and substituted or unsubstituted C2-C60 heteroaryl. Alternatively, R₉ and R₁₀ may each be connected to an adjacent substituent to form a substituted or unsubstituted ring. C2-C60 heteroaryl includes at least one heteroatom, and the heteroatom includes N, O and S, where N is nitrogen, O is oxygen, and S is sulfur.
m and n are the same or different, and are independently selected from 1, 2, 3 and 4.
At least one R₉ is deuterium.
At least one R₁₀ is deuterium.

The description of L₅ being a single bond here may refer to the above description of L₁ being a single bond; the description of the Cx aryl and the Cx alkyl here may refer to the above description of the Cx aryl, the Cx alkyl; the description of aryl and heteroaryl here may refer to the above description of aryl and heteroaryl; the description of arylene and heteroarylene here may refer to the above description of arylene and heteroarylene, which will not be repeated here.

In a case where L₅ is selected from substituted C6-C60 arylene, and/or Ar₇ or Ar₈ is selected from substituted C6-C60 aryl and substituted C2-C60 heteroaryl, and/or R₉ or R₁₀ is selected from substituted C1-C60 alkyl, substituted C3-C60 cycloalkyl, substituted C2-C60 alkenyl, substituted C6-C60 aryl and substituted C2-C60 heteroaryl, the type and number of the substituents are not limited here.

It is understandable that the structure shown in the general formula (IV) contains carbazolyl, and carbons at positions 1″ to 8″ in carbazole have high reactivity. When chemical reactions occur at these positions, degradation will occur on the first functional material. In the structure shown in the general formula (IV), m R₉ and n R₁₀ are connected to (m+n) carbons of the carbons at positions 1″ to 8″, and at least one R₉ is deuterium and at least one R₁₀ is deuterium. That is, hydrogens at high reaction active sites are replaced by multiple deuteriums. Thus, it may be possible to shorten the bond length, increase the bond dissociation energy, so as to improve the molecular stability of the first functional material. Moreover, it may be possible to reduce the probability of side reactions occurring on the first functional material. As a result, the electrical stability of the first functional material may be improved, the electronic resistance of the first functional material may be improved, which may slow down the degradation of the first functional material caused by electrons and excitons, so that the stability of the first functional material is improved, and the service life of the light-emitting device 100 (e.g., the first light-emitting device 101) is improved.

Furthermore, since the structure shown in the general formula (IV) contains carbazolyl, the triplet energy level of the first functional material is relatively high, and the difference between the triplet energy level of the first functional material and the triplet energy level of the host material is relatively great. In this way, after the holes and electrons recombine in the host material to form triplet excitons, the triplet excitons transferred from the host material to the first functional material are relatively few, so that the triplet excitons may be confined in the light-emitting layer 131 (for example, confined in the host material). As a result, the triplet exciton concentration in the light-emitting layer 131 may be increased, the TTA effect may be enhanced, which may fully utilize the TTA effect to improve the efficiency of the light-emitting device 100 (e.g., the first light-emitting device 101).

Exemplary structures of the first functional material G1 with the structure represented by the general formula (IV) are introduced below.

In some examples, in the case where Ar₇ and Ar₈ both include biphenyl, the structural formula of the first functional material G1 may be as shown in the following formulas.

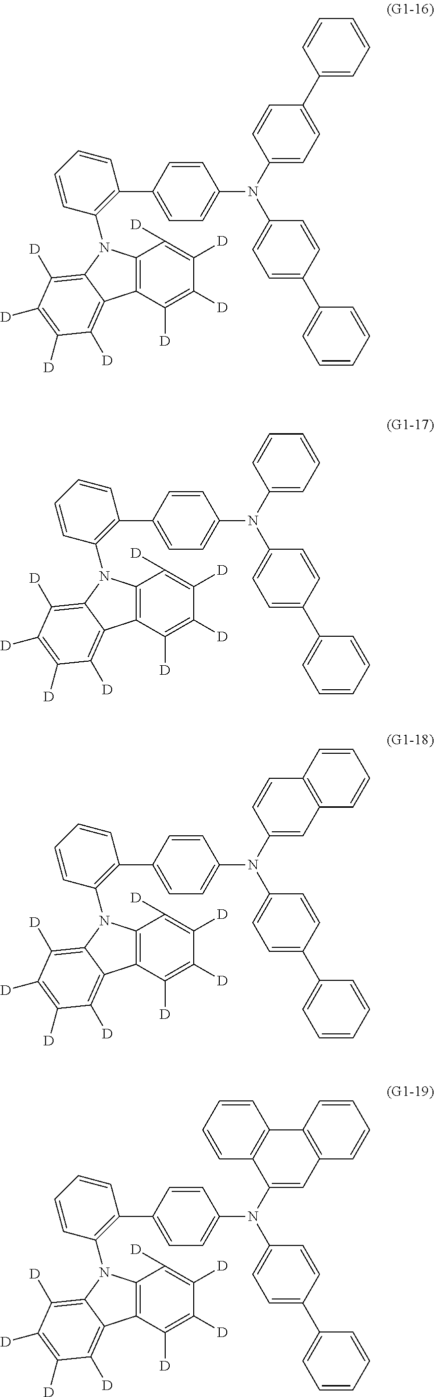 [SMILES: [2H]c1c([2H])c([2H])c2c(c1[2H])c1c([2H])c([2H])c([2H])c([2H])c1n2-c1ccccc1-c1ccc(N(c2ccc(-c3ccccc3)cc2)c2ccc(-c3ccccc3)cc2)cc1 ; [2H]c1c([2H])c([2H])c2c(c1[2H])c1c([2H])c([2H])c([2H])c([2H])c1n2-c1ccccc1-c1ccc(N(c2ccccc2)c2ccc(-c3ccccc3)cc2)cc1 ; [2H]c1c([2H])c([2H])c2c(c1[2H])c1c([2H])c([2H])c([2H])c([2H])c1n2-c1ccccc1-c1ccc(N(c2ccc(-c3ccccc3)cc2)c2ccc3ccccc3c2)cc1 ; [2H]c1c([2H])c([2H])c2c(c1[2H])c1c([2H])c([2H])c([2H])c([2H])c1n2-c1ccccc1-c1ccc(N(c2ccc(-c3ccccc3)cc2)c2cc3ccccc3c3ccccc23)cc1]

In some examples, in the case where Ar₇ and Ar₈ both include naphthyl, the structural formula of the first functional material G1 may be as shown in the following structural formulas.

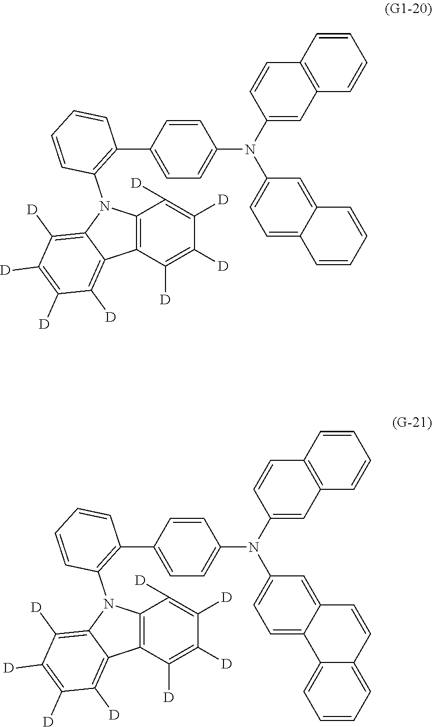 [SMILES: [2H]c1c([2H])c([2H])c2c(c1[2H])c1c([2H])c([2H])c([2H])c([2H])c1n2-c1ccccc1-c1ccc(N(c2ccc3ccccc3c2)c2ccc3ccccc3c2)cc1 ; [2H]c1c([2H])c([2H])c2c(c1[2H])c1c([2H])c([2H])c([2H])c([2H])c1n2-c1ccccc1-c1ccc(N(c2ccc3ccccc3c2)c2ccc3c(ccc4ccccc43)c2)cc1]

From the above structural formulas (G1-16) to (G1-21) of the first functional material, it can be found that in the structure shown in the general formula (VI), the deuterium substitution may occur at the carbons at positions 3″ and 6″. Compared with carbons at positions 1″, 2″, 4″, 5″, 7″, and 8″, carbons at positions 3″ and 6″ have relatively higher reactivity. By setting deuterium substitution occurring at the carbons at positions 3″ and 6″, the molecular stability of the carbons at positions 3″ and 6″ may be improved, so that the stability of the first functional material is relatively high, and the service life of the light-emitting device 100 (e.g., the first light-emitting device 101) is improved.

It will be noted that the structural formulas listed above are examples of the structure of the first functional material G1, but not limitations on the structure of the first functional material G1. Moreover, “(G1-x)” in the above structural formulas is a name of a respective structural formula but is not part of the structure in the structural formula, where x is a positive integer.

In some embodiments, in the case where the first functional material is a deuterated material, a mass fraction of deuterium in the first functional material is greater than or equal to 0.15% and less than or equal to 5.50%.

The mass fraction of deuterium in the first functional material refers to, in the structure of the first functional material, a ratio of the relative molecular mass of deuterium atoms to the relative molecular mass of the first functional material molecules.

It can be understood that in the case where the mass fraction of deuterium in the first functional material is greater than or equal to 0.15% and less than or equal to 5.50%, the mass fraction of deuterium in the first functional material is relatively high, that is, the first functional material contains relatively more deuterium atoms. As mentioned above, in a case where the number of deuterium atoms in the first functional material is relatively great, the bond dissociation energy and stability of the first functional material may be improved, which may improve the electrical stability of the first functional material, and improve the electronic resistance of the first functional material to slow down the degradation of the first functional material caused by electrons and excitons, so that the stability of the first functional material may be improved, and the service life of the light-emitting device 100 (e.g., the first light-emitting device 101) may be improved. Moreover, in a case where the first functional material contains relatively more deuterium atoms, the energy required for the side reactions occurring on the first functional material is also relatively high. In this way, the probability of the side reactions occurring on the first functional material may be relatively low, thereby improving the stability of the first functional material.

In some examples, the first functional material is selected from the structures shown in formula (III), and the mass fraction of deuterium in the first functional material is greater than or equal to 0.15% and less than or equal to 5.50%.

In some other examples, the first functional material is selected from the structures shown in general formula (III-A), and the mass fraction of deuterium in the first functional material is greater than or equal to 0.15% and less than or equal to 5.50%.

In yet some other examples, the first functional material is selected from the structures shown in general formula (IV), and the mass fraction of deuterium in the first functional material is greater than or equal to 0.15% and less than or equal to 5.50%.

For example, the mass fraction of deuterium in the first functional material may be 0.15%, 1.00%, 2.00%, 3.00%, 4.00% or 5.50%, etc.

In order to objectively evaluate technical effects of the embodiments of the present disclosure, detailed exemplary description of embodiments of the present application is given through the following Embodiments and Comparative example. According to different types of device structure, the following Embodiments and Comparative examples are divided into a first group of experimental examples, and a second group of experimental examples.

### The First Group of Experimental Examples

In the following Embodiments and Comparative examples, the light-emitting layer 131 and the electron blocking layer 1323 of the first light-emitting device 101 are each made of a different material, and the voltage, current efficiency, device life of the first light-emitting device 101 are compared.

In the following Comparative examples and Embodiments, the structure of the first light-emitting device 101 and the test conditions of the first light-emitting device 101 are each the same.

The first light-emitting device 101 is a single-layer light-emitting device, and its structure is shown in FIG. 6. The method for manufacturing a display panel including the above-mentioned first light-emitting device 101 includes: using a substrate 210 (glass substrate) provided with a pixel definition layer 221 and an anode 11 thereon as a backplane, and placing the backplane in a vacuum chamber of a vacuum evaporation device, and evacuating the vacuum chamber to a range of 1×10⁻⁵ Pa to 1×10⁻⁶ Pa, and then, sequentially forming a hole injection layer 1321, a hole transport layer 1322, an electron blocking layer 1323, a light-emitting layer 131, a hole blocking layer 1333, an electron transport layer 1332, an electron injection layer 1331, a cathode 12, and a covering layer 15 on the backplane by respectively using the material of the hole injection layer 1321, the material of the hole transport layer 1322, the material of the electron blocking layer 1323, the material of the light-emitting layer 131, the material of the hole blocking layer 1333, the material of the electron transport layer 1332, the material of the electron injection layer 1331, the material of the cathode 12, and the material of the covering layer 15. Before use, the backplane is first ultrasonically treated in a detergent, then rinsed with deionized water, and then ultrasonically treated in an acetone-ethanol mixed solvent to remove oil, and then dried in a clean environment until the water and solvent are removed.

It will be noted that, in the Embodiments and Comparative examples, the hole transport layer 1322, the electron blocking layer 1323, the light-emitting layer 131, the hole blocking layer 1333, the electron transport layer 1332, the electron injection layer 1331, the cathode 12, and the covering layer 15 each have a same thickness, and are each 10 nm, 100 nm, 10 nm, 20 nm, 5 nm, 30 nm, 1 nm, 13 nm, and 60 nm.

In the Embodiments and Comparative examples, the anode 11, the hole injection layer 1321, the hole transport layer 1322, the hole blocking layer 1333, the electron transport layer 1332, the electron injection layer 1331, and the cathode 12 are each made of a same material. The material of the anode 11 is ITO. The material of the hole injection layer 1321 is a mixed material obtained by mixing a hole transport material (the structure is shown in the structural formula (HTL) described above) and a hole injection material (the structure is shown in the following structural formula (HIL)) in a mass ratio of 98:2. The structure of the material of the hole transport layer 1322 is shown in the structural formula (HTL) described above. The material of the hole blocking layer 1333 is shown in the following structural formula (HIL). The material of the hole blocking layer 1333 is shown in the following structural formula (HBL). The structure of the material of the electron transport layer 1332 is a mixed material obtained by mixing a first electron transport material (the structure is shown in the structural formula (ETL)) and a second electron transport material (the structure is shown in the structural formula (LiQ)) in a mass ratio of 1:1. The material of the electron injection layer 1331 is ytterbium. The material of the cathode 12 is magnesium silver alloy (Mg:Ag=1:9).

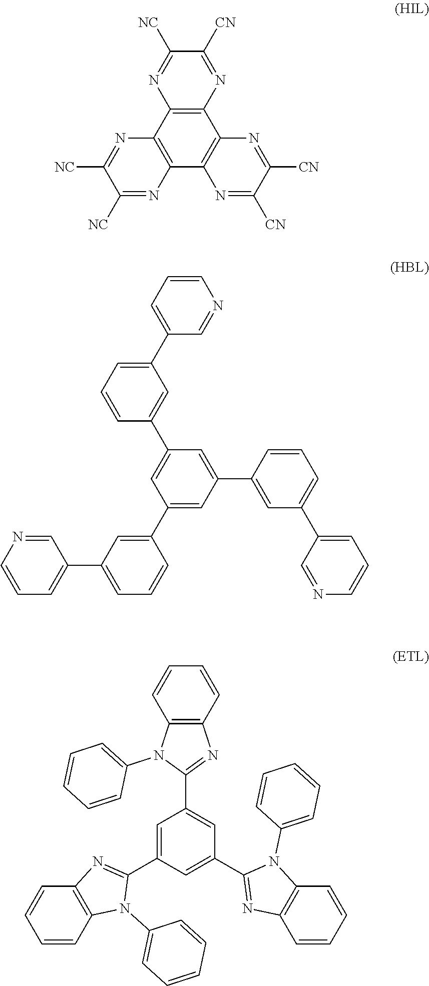 [SMILES: N#Cc1nc2c3nc(C#N)c(C#N)nc3c3nc(C#N)c(C#N)nc3c2nc1C#N ; c1cncc(-c2cccc(-c3cc(-c4cccc(-c5cccnc5)c4)cc(-c4cccc(-c5cccnc5)c4)c3)c2)c1 ; c1ccc(-n2c(-c3cc(-c4nc5ccccc5n4-c4ccccc4)cc(-c4nc5ccccc5n4-c4ccccc4)c3)nc3ccccc32)cc1]

In Embodiments and Comparative examples, the electron blocking layer 1323 and the light-emitting layer 131 are each made of a different material. The material of the electron blocking layer 1323 in Comparative examples and some Embodiments includes a comparative first functional material, and the structure is shown in the following structural formula (R-G1); the material of the light-emitting layer 131 in Comparative examples and some Embodiments includes a contrast host material and a contrast guest material, the structure of the contrast host material is shown in the following structural formula (R-H), and the structure of the contrast guest material is shown in the following structural formula (R-D).

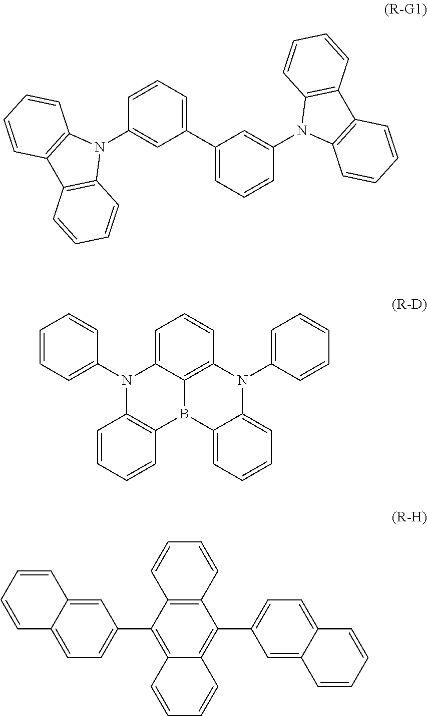

It will be noted that, “(HIL)”, “(HBL)”, “(ETL)”, “(LiQ)”, “(R-H)”, “(R-D)”, and “(R-G1)” in the above structural formulas are each a name of the respective structural formula and not part of the structure of the respective structural formula.

The materials of the light-emitting layer 131 and the electron blocking layer 1323 of the first light-emitting device 101 in Embodiments and Comparative examples will be described respectively below.

In Embodiment 1, the light-emitting layer 131 includes a host material H and a guest material D. The structural formula of the host material H is shown in (H-4); the structural formula of the guest material D is shown in (D-4). Furthermore, the mass ratio of the host material H to the guest material D is 97:3. The structural formula of the material of the electron blocking layer 1323 is shown in (G1-13).

In Embodiment 2, the light-emitting layer 131 includes a host material H and a guest material D. The structural formula of the host material H is shown in (H-5); the structural formula of the guest material D is shown in (D-6). Furthermore, the mass ratio of the host material H to the guest material D is 97:3. The structural formula of the material of the electron blocking layer 1323 is shown in (G1-7).

In Embodiment 3, the light-emitting layer 131 includes a host material H and a guest material D. The structural formula of the host material H is shown in (H-4); the structural formula of the guest material D is shown in (D-4). Furthermore, the mass ratio of the host material H to the guest material D is 97:3. The structural formula of the material of the electron blocking layer 1323 is shown in (G1-18).

In Embodiment 4, the light-emitting layer 131 includes a host material H and a guest material D. The structural formula of the host material H is shown in (H-5); the structural formula of the guest material D is shown in (D-6). Furthermore, the mass ratio of the host material H to the guest material D is 97:3. The structural formula of the material of the electron blocking layer 1323 is shown in (G1-20).

In Embodiment 5, the light-emitting layer 131 includes a host material H and a guest material D. The structural formula of the host material H is shown in (H-5); the structural formula of the guest material D is shown in (D-4). Furthermore, the mass ratio of the host material H to the guest material D is 97:3. The structural formula of the material of the electron blocking layer 1323 is shown in (R-G1).

In Embodiment 6, the light-emitting layer 131 includes a contrast host material and a contrast guest material, and the structural formula of the contrast host material is shown as (R-H); the structural formula of the contrast guest material is shown as (R-D). Moreover, the mass ratio of the contrast host material to the contrast guest material is 97:3. The structural formula of the material of the electron blocking layer 1323 is shown in (G1-13).

In Embodiment 7, the light-emitting layer 131 includes a host material H and a contrast guest material, and the structural formula of the host material H is shown in (H-4); the structural formula of the contrast guest material is shown in (R-D). Furthermore, the mass ratio of the host material H to the contrast guest material is 97:3. The structural formula of the material of the electron blocking layer 1323 is shown in (R-G1).

In Embodiment 8, the light-emitting layer 131 includes a contrast host material and a guest material D, the structural formula of the contrast host material is shown as (R-H); the structural formula of the guest material D is shown as (D-4). Moreover, the mass ratio of the comparative host material to the guest material D is 97:3. The structural formula of the material of the electron blocking layer 1323 is shown in (R-G1).

In Embodiment 9, the light-emitting layer 131 includes a contrast host material and a guest material D, the structural formula of the contrast host material is shown as (R-H); the structural formula of the guest material D is shown as (D-4). Moreover, the mass ratio of the contrast host material to the guest material D is 97:3. The structural formula of the material of the electron blocking layer 1323 is shown in (G1-18).

In Comparative Example 1, the light-emitting layer 131 includes a contrast host material and a contrast guest material, and the structural formula of the contrast host material is shown as (R-H); the structural formula of the contrast guest material is shown as (R-D). Moreover, the mass ratio of the contrast host material to the contrast guest material is 97:3. The structural formula of the material of the electron blocking layer 1323 is shown in (R-G1).

In order to more clearly describe the difference in the structural formulas of the host material, the guest material and the material of the electron blocking layer used in the Embodiments and Comparative example, Table 1 below is used to clearly show the structural formulas of the host material, the guest material and the material of the electron blocking layer used in the Embodiments and Comparative example.

TABLE 1

| | Host | Guest | Material of an electron |
|---|---|---|---|
| | material | material | blocking layer |
| Embodiment 1 | H-4 | D-4 | G1-13 |
| Embodiment 2 | H-5 | D-6 | G1-7 |
| Embodiment 3 | H-4 | D-4 | G1-18 |
| Embodiment 4 | H-5 | D-6 | G1-20 |
| Embodiment 5 | H-5 | D-4 | R-G1 |
| Embodiment 6 | R-H | R-D | G1-13 |
| Embodiment 7 | H-4 | R-D | R-G1 |
| Embodiment 8 | R-H | D-4 | R-G1 |
| Embodiment 9 | R-H | D-4 | G1-18 |
| Comparative | R-H | R-D | R-G1 |
| example 1 | | | |

It will be noted that, “A-x” in Table 1 means that the corresponding structural formula is A-x. For example, the content of the sub-grid corresponding to the host material H in Embodiment 1 is H-4, which means that in the light-emitting layer 131 in Embodiment 1, the structural formula of the host material H is shown as (H-4). The structural formulas represented by “H-x”, “D-x”, “G1-x” (x is a positive integer), R-H, R-D, and R-G1 are as mentioned above and will not be repeated here.

In this group of experimental examples, Gaussian 09 software is used to calculate the overlap ratio of density of states for HOMO of the material of the electron blocking layer 1323 to density of states for HOMO of the material (the structure is shown in the above structural formula (HTL)) of the hole transport layer 1322, and the overlap ratio of density of states for HOMO of the material of the electron blocking layer 1323 to density of states for HOMO of the host material through simulation calculation, and the results are shown in Table 2. The simulation calculation method includes: performing deposition simulation on hundreds to thousands of molecules (e.g., 500 molecules), and then obtaining the HOMO energy of each material through quantum mechanical calculation, and obtaining the density of states for HOMO of each material based on this; then, comparing the distribution difference between the density of states for HOMO of the material of the electron blocking layer 1323 and the material (the structure is shown in the aforementioned structural formula (HTL)) of the hole transport layer 1322, and comparing the distribution difference between the density of states for HOMO of the material of the electron blocking layer 1323 and the density of states for HOMO of the host material, and converting the overlap ratio into percentage to obtain the overlap rate of the density of states for HOMO.

TABLE 2

| | Overlap ratio of density of states for HOMO |
|---|---|
| (G1-13) and (H-4) | 12 |
| (G1-7) and (H-4) | 16 |
| (G1-13) and (H-5) | 23 |
| (G1-7) and (H-5) | 32 |
| (G1-18) and (H-4) | 25 |
| (G1-20) and (H-4) | 29 |
| (G1-18) and (H-5) | 19 |
| (G1-20) and (H-5) | 22 |
| (G1-13) and (HTL) | 55 |
| (G1-7) and (HTL) | 68 |
| (G1-18) and (HTL) | 60 |
| (G1-20) and (HTL) | 74 |

It can be seen from Table 2 that, the overlap rate of density of states for HOMO of the first functional materials with the structure shown in formulas (G1-13), (G1-7), (G1-18), and (G1-20) to density of states for HOMO of the host material with the structure shown in formulas (H-4) and (H-5) is in a range of 12% to 32%, which is a relatively high; the overlap rate of density of states for HOMO of the first functional material with the structure as shown in formulas (G1-13), (G1-7), (G1-18), and (G1-20) to density of states for HOMO of the second functional material (i.e., the material of the hole transport layer 1322) with the structure as shown in the general formula (HTL) is in a range of 55% to 74%, which is relatively high.

In this group of experimental examples, simulation software is used to calculate the hole reorganization energy and electron reorganization energy of the above-mentioned host material, and the absolute value of the difference between the electron reorganization energy and the hole reorganization energy is calculated. The results are shown in Table 3.

TABLE 3

| | Absolute value of adifference between electron reorganization |
|---|---|
| | energy and hole reorganization energy (eV) |
| H-4 | 0.02 |
| H-5 | 0.05 |

It can be seen from Table 3 that the differences between the electron reorganization energy and the hole reorganization energy of the host material with the structures shown in (H-4) and (H-5) are 0.02 eV and 0.05 eV, respectively, both of which are less than 0.1 eV.

In this group of experimental examples, thermogravimetric analyzer (TGA) is used to test the thermal decomposition temperature Td (i.e., the temperature corresponding to 5% weight loss) of the above-mentioned host material, guest material, and first functional material. The test is carried out in nitrogen atmosphere, with a test temperature in a range of room temperature to 600° C. and a heating rate of 10° C./min. Furthermore, in this group of experimental examples, the dipole moments (Debye) of the host material, guest material, and first functional material are calculated using Gaussian 09 software. The results of the thermal decomposition temperature Td and the dipole moment are shown in Table 4.

TABLE 4

| | Thermal decomposition temperature | Dipole moment |
|---|---|---|
| | Td (° C.) | (D) |
| H-4 | 425 | 0.14 |
| H-5 | 439 | 0.13 |
| D-4 | 371 | 0.08 |
| D-6 | 386 | 0.08 |
| G1-13 | 416 | 0.15 |
| G1-7 | 402 | 0.21 |
| G1-18 | 415 | 0.20 |
| G1-20 | 409 | 0.22 |

It can be seen from Table 4 that the thermal decomposition temperatures of the host materials with structures shown in structural formula (H-4) and formula (H-5), the guest materials with structures shown in structural formula (D-4) and formula (D-6), and the first functional materials with structures shown in structural formula (G1-13), (G1-7), (G1-18) and (G1-20) are in a range of 371° C. to 439° C., which are all relatively high, indicating that the above materials have good thermal stability.

It can be seen from Table 4 that the dipole moments of the host materials with structures shown in structural formula (H-4) and (H-5), the guest materials with structures shown in structural formula (D-4) and (D-6), and the first functional materials with structures shown in structural formula (G1-13), (G1-7), (G1-18) and (G1-20) are in a range of 0.08 D to 0.22 D, all of which are greater than 0 D, indicating that the molecules of the above materials are asymmetric.

Based on the above materials, the voltage (V), current efficiency (cd/A) and device life (h) of the light-emitting device 101 in Embodiments 1 to 9 and Comparative example 1 are tested. The data results of the voltage (V), luminous efficiency (cd/A), and device life in Embodiments are based on the data result in Comparative example 1, and the test results are shown in Table 5 below. The device life is characterized by the parameter LT95.

TABLE 5

| | Voltage | Efficiency | Device life |
|---|---|---|---|
| Embodiment 1 | 92% | 119% | 152% |
| Embodiment 2 | 94% | 117% | 133% |
| Embodiment 3 | 97% | 108% | 128% |
| Embodiment 4 | 96% | 106% | 111% |
| Embodiment 5 | 96% | 105% | 109% |
| Embodiment 6 | 97% | 102% | 103% |
| Embodiment 7 | 97% | 102% | 105% |
| Embodiment 8 | 98% | 99% | 99% |
| Embodiment 9 | 97% | 101% | 102% |
| Comparative example 1 | 100% | 100% | 100% |

It can be seen from Table 5 that, compared with Comparative Example 1, the device life of Embodiments 1 to 4 is in a range of 111% to 152%, which are relatively high. This is because in the first light-emitting device 101 of Embodiments 1 to 4, the host material H, the guest material D, and the material of the electron blocking layer 1323 (i.e., the first functional material) are all deuterated materials, while in Comparative Example 1, the contrast host material R-H, the contrast guest material R-D, and the contrast first functional material R-G1 are all materials that do not contain deuterium atoms. Since deuterated materials have relatively great bond dissociation energy, the stability of the material may be improved. In the case where the host material H, the guest material D, and the material (i.e., the first functional material) of the electron blocking layer 1323 are all deuterated materials, the material of the first light-emitting device 101 contains relatively more deuterium atoms, and the stability of the three materials is improved. Moreover, due to the synergistic effect of the three deuterated materials, the first light-emitting device 101 may exhibit relatively excellent device life.

Compared with Comparative Example 1, referring to Table 5, the device efficiency of Embodiments 1 to 4 is in a range of 106% to 119%, which are relatively high. This is because in the first light-emitting device 101 of Embodiments 1 to 4, the host material H, the guest material D, and the material (i.e., the first functional material) of the electron blocking layer 1323 are all deuterated materials, while in Comparative Example 1, the contrast host material R-H, the contrast guest material R-D, and the contrast first functional material R-G1 are all materials that do not contain deuterium atoms. In the case where the host material H and the guest material D are deuterated materials, the molecular vibration is relatively small, so that the quantum efficiency loss caused by the molecular vibration of the host material H and the guest material D is relatively small, and the efficiency of the first light-emitting device 101 is relatively high.

Compared with Comparative Example 1, referring to Table 5, the device life of Embodiments 5, 7 and 8 are relatively long, which is because in the first light-emitting device 101 in Embodiments 5, 7 and 8, the host material H and/or the guest material D are all deuterated materials, while the contrast host material R-H and the contrast guest material R-D in Comparative Example 1 are both materials that do not contain deuterium atoms. The host material or the contrast host material is a material where high-energy excitons are generated by recombination, and the guest material or the contrast guest material is a material that receives the energy transferred by the host material or the contrast host material to radiate light. Since deuterated materials have relatively high bond dissociation energy, the electrical stability of the material may be improved. In the case where the host material H and/or the guest material D are both deuterated materials, the host material H and/or the guest material D have relatively high electrical stability, which may improve the tolerance to high-energy excitons and high-energy intermediates of the TTA effect, so that the first light-emitting device 101 exhibits relatively excellent device life.

Compared with Comparative Example 1, referring to Table 5, the device life of Embodiments 6 and 9 are relatively long, which is because in the first light-emitting device 101 in Embodiments 6 and 9, the material (i.e., the first functional material) of the electron blocking layer 1323 is a deuterated material, while the material (i.e., the contrast first functional material) of the electron blocking layer 1323 in Comparative Example 1 is a material that does not contain deuterium atoms. Since deuterated materials have relatively high bond dissociation energy, the electrical stability of the material may be improved. In the case where the material of the electron blocking layer 1323 is a deuterated material, the material of the electron blocking layer 1323 has relatively high electrical stability, which may improve the tolerance to carriers (electrons or holes) and excitons, so that the first light-emitting device 101 exhibits relatively excellent device life.

Compared with Comparative Example 1, referring to Table 5, the device efficiency of Embodiments 6 and 9 are relatively high, which is because the structure of the material (i.e., the first functional material) of the electron blocking layer 1323 in the first light-emitting device 101 in Embodiments 6 and 9 is selected from the structure shown in general formula (III) or general formula (IV), while the material (i.e., the contrast first functional material) of the electron blocking layer 1323 in Comparative Example 1 does not conform to the structure shown in general formula (III) or general formula (IV). Since the structure represented by general formula (III) or general formula (IV) contains carbazolyl, dibenzofuran, dibenzothiophene, fluorene or spirofluorene, the triplet energy level of the first functional material may be relatively high, and the difference between the triplet energy level of the first functional material and the triplet energy level of the host material may be relatively large. In this way, after holes and electrons recombine to form triplet excitons in the host material, the number of triplet excitons transferred from the host material to the first functional material is relatively small, so that the triplet excitons may be confined in the light-emitting layer 131 (for example, confined to the host material). As a result, the concentration of triplet excitons in the light-emitting layer 131 may be increased, which may enhance the TTA effect to fully utilize the TTA effect, so that the efficiency of the first light-emitting device 101 may be improved.

It can be seen from the above Embodiments and Comparative example that, in the present disclosure, by setting the overlap rate of the density of states for HOMO of the first functional material and the density of states for HOMO of the second functional material to be greater than 0% and less than or equal to 90%, the efficiency of the single-layer light-emitting device 100 (e.g., the first light-emitting device 101) may be improved, and the device life of the single-layer light-emitting device 100 (e.g., the first light-emitting device 101) may be improved. Moreover, by configuring the host material H to be any one of the structures represented by the general formula (I), the guest material D to be any one of the structures represented by the general formula (II), and the first functional material G1 to be any one of the structures represented by the general formula (III) or the general formula (IV), the efficiency of the single-layer light-emitting device 100 (e.g., the first light-emitting device 101) may be further improved, and the device life of the single-layer light-emitting device 100 (e.g., the first light-emitting device 101) may be increased.

### The Second Group of Experimental Examples

In the following Embodiments and Comparative examples, the light-emitting layer 131 and the electron blocking layer 1323 of the first light-emitting device 101 are each made of a different material, and the voltage, current efficiency, device life of the first light-emitting device 101 are compared.

In the following Comparative examples and Embodiments, the structure of the first light-emitting device 101 and the test conditions of the first light-emitting device 101 are each the same.

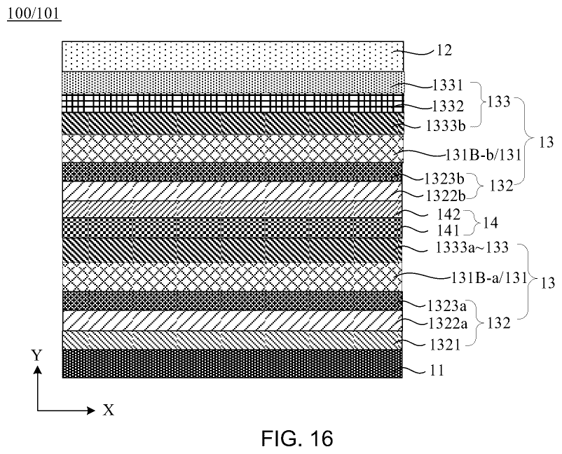

The first light-emitting device 101 is a tandem light-emitting device, and its structure is shown in FIG. 16. Specifically, the first light-emitting device 101 includes an anode 11, a hole injection layer 1321, a hole transport layer 1322a, an electron blocking layer 1323a, a light-emitting layer 131B-a, a hole blocking layer 1333a, an electron generation layer 141, a hole generation layer 142, a hole transport layer 1322b, an electron blocking layer 1323b, a light-emitting layer 131B-b, a hole blocking layer 1333b, an electron transport layer 1332 and a cathode 12 that are stacked. Among them, the hole injection layer 1321, the hole transport layer 1322a, the electron blocking layer 1323a, the light-emitting layer 131B-a, and the hole blocking layer 1333a that are located close to the anode 11 constitute a first light-emitting unit 13, and the hole transport layer 1322b, the electron blocking layer 1323b, the light-emitting layer 131B-b, the hole blocking layer 1333b, the electron transport layer 1332, and the electron injection layer 1331 that are located close to the cathode 12 constitute a second light-emitting unit 13.

The manufacturing method for the display panel including the above-mentioned first light-emitting device 101 includes: using a substrate 210 (glass substrate) provided with a pixel definition layer 221 and an anode 11 thereon as a backplane, and placing the backplane in a vacuum chamber of a vacuum evaporation device, and evacuating the vacuum chamber to a range of 1×10⁻⁵ Pa to 1×10⁻⁶ Pa, and then, sequentially forming the hole injection layer 1321, the hole transport layer 1322a, the electron blocking layer 1323a, the light-emitting layer 131B-a, the hole blocking layer 1333a, the electron generation layer 141, the hole generation layer 142, the hole transport layer 1322b, the electron blocking layer 1323b, the light-emitting layer 131B-b, the hole blocking layer 1333b, the electron transport layer 1332 and the cathode 12 on the backplane by respectively using the material of the hole injection layer 1321, the material of the hole transport layer 1322a, the material of the electron blocking layer 1323a, the material of the light-emitting layer 131B-a, the material of the hole blocking layer 1333a, the material of the electron generation layer 141, the material of the hole generation layer 142, the material of the hole transport layer 1322b, the material of the electron blocking layer 1323b, the material of the light-emitting layer 131B-b, the material of the hole blocking layer 1333b, the material of the electron transport layer 1332, and the material of the cathode 12. Before use, the backplane is first ultrasonically treated in a detergent, then rinsed with deionized water, and then ultrasonically treated in an acetone-ethanol mixed solvent to remove oil, and then dried in a clean environment until the water and solvent are removed.

It will be noted that the thicknesses of the hole injection layer 1321, hole transport layer 1322a, electron blocking layer 1323a, light-emitting layer 131B-a, hole blocking layer 1333a, electron generation layer 141, hole generation layer 142, hole transport layer 1322b, electron blocking layer 1323b, light-emitting layer 131B-b, hole blocking layer 1333b, electron transport layer 1332, electron injection layer 1331, and cathode 12 in the Embodiments and Comparative example are all the same, which are 10 nm, 19 nm, 5 nm, 15 nm, 5 nm, 18 nm, 9 nm, 19 nm, 5 nm, 15 nm, 5 nm, 35 nm, 1 nm, and 15 nm, respectively.

The materials of the hole injection layer 1321, hole transport layer 1322a, hole blocking layer 1333a, electron generation layer 141, hole generation layer 142, hole transport layer 1322b, hole blocking layer 1333b, electron transport layer 1332, electron injection layer 1331 and cathode 12 in the Embodiments and Comparative example are the same. The material of the anode 11 is indium tin oxide (ITO). The material of the hole injection layer 1321 is a mixed material obtained by mixing a hole transport material (the structure of which is shown in the aforementioned structural formula (HTL)) and a hole injection material (the structure of which is shown in the aforementioned structural formula (HIL)) in a mass ratio of 95:5. The materials of the hole transport layer 1322a and the hole transport layer 1322b are the same, the structures of which are both shown in the aforementioned structural formula (HTL). The materials of the hole blocking layer 1333a and the hole blocking layer 1333b are the same, the structures of which are both shown in the aforementioned structural formula (HBL). The material of the electron transport layer 1332 is a mixed material obtained by mixing a first electron transport material (the structure of which is shown in the aforementioned structural formula (ETL) and a second electron transport material (the structure of which is shown in the aforementioned structural formula (LiQ) in a mass ratio of 1:1. The material of the electron injection layer 1331 is ytterbium. The material of the electron generation layer 141 is a mixed material obtained by mixing an electron generation material (the structure of which is shown in the following structural formula (N-CGL)) and ytterbium in a mass ratio of 99:1. The material of the hole generation layer 142 is a mixed material obtained by mixing a hole generation material (the structure of which is shown in the above structural formula (HTL)) and a hole injection material (the structure of which is shown in the above structural formula (HIL)) in a mass ratio of 95:5. The material of the cathode 12 is a magnesium-silver alloy (Mg:Ag=1:9).

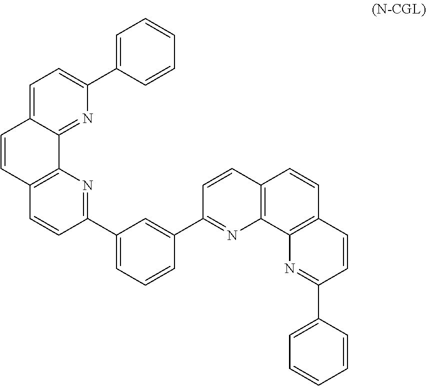 [SMILES: c1ccc(-c2ccc3ccc4ccc(-c5cccc(-c6ccc7ccc8ccc(-c9ccccc9)nc8c7n6)c5)nc4c3n2)cc1]

It will be noted that, “(N-CGL)” in the above structural formulas is the name of the structural formula and is not part of the structure of the structural formula.

The materials of the electron blocking layer 1323a, the light-emitting layer 131B-a, the electron blocking layer 1323b, the light-emitting layer 131B-b in the Embodiments and Comparative example will be described respectively.

In Embodiment 10, the light-emitting layer 131B-a and the light-emitting layer 131B-b each include a host material H and a guest material D. The structural formula of the host material H is shown in (H-4), and the structural formula of the guest material D is shown in (D-4). Furthermore, the mass ratio of the host material H to the guest material D is 97:3. The structural formula of the material of the electron blocking layer 1323a and the electron blocking layer 1323b is shown in (G1-13).

In Embodiment 11, the light-emitting layer 131B-a and the light-emitting layer 131B-b each include a host material H and a guest material D. The structural formula of the host material H is shown in (H-5), and the structural formula of the guest material D is shown in (D-6). Furthermore, the mass ratio of the host material H to the guest material D is 97:3. The structural formula of the material of the electron blocking layer 1323a and the electron blocking layer 1323b is shown in (G1-7).

In Embodiment 12, the light-emitting layer 131B-a and the light-emitting layer 131B-b each include a host material H and a guest material D. The structural formula of the host material H is shown in (H-4), and the structural formula of the guest material D is shown in (D-4). Furthermore, the mass ratio of the host material H to the guest material D is 97:3. The structural formula of the material of the electron blocking layer 1323a and the electron blocking layer 1323b is shown in (G1-18).

In Embodiment 13, the light-emitting layer 131B-a and the light-emitting layer 131B-b each include a host material H and a guest material D. The structural formula of the host material H is shown in (H-5), and the structural formula of the guest material D is shown in (D-6). Furthermore, the mass ratio of the host material H to the guest material D is 97:3. The structural formula of the materials of the electron blocking layer 1323a and the electron blocking layer 1323b is shown in (G1-20).

In Embodiment 14, the light-emitting layer 131B-a and the light-emitting layer 131B-b each include a host material H and a guest material D. The structural formula of the host material H is shown in (H-5), and the structural formula of the guest material D is shown in (D-4). Furthermore, the mass ratio between the host material H and the guest material D was 97:3. The structural formula of the materials of the electron blocking layer 1323a and the electron blocking layer 1323b is shown in (R-G1).

In Embodiment 15, the light-emitting layer 131B-a and the light-emitting layer 131B-b each include a contrast host material and a contrast guest material; the structural formula of the contrast host material is shown as (R-H), and the structural formula of the contrast guest material is shown as (R-D). Moreover, the mass ratio of the contrast host material and the contrast guest material is 97:3. The structural formula of the materials of the electron blocking layer 1323a and the electron blocking layer 1323b is shown in (G1-13).

In Embodiment 16, the light-emitting layer 131B-a and the light-emitting layer 131B-b each include a host material H and a contrast guest material. The structural formula of the host material H is shown in (H-4); the structural formula of the contrast guest material is shown in (R-D). Furthermore, the mass ratio of the host material H and the contrast guest material is 97:3. The structural formula of the materials of the electron blocking layer 1323a and the electron blocking layer 1323b is shown in (R-G1).

In Embodiment 17, the light-emitting layer 131B-a and the light-emitting layer 131B-b each include a contrast host material and a guest material D; the structural formula of the contrast host material is shown as (R-H), and the structural formula of the guest material D is shown as (D-4). Moreover, the mass ratio of the contrast host material and the guest material D is 97:3. The structural formula of the materials of the electron blocking layer 1323a and the electron blocking layer 1323b is shown in (R-G1).

In Embodiment 18, the light-emitting layer 131B-a and the light-emitting layer 131B-b each include a contrast host material and a guest material D; the structural formula of the contrast host material is shown as (R-H), and the structural formula of the guest material D is shown as (D-4). Moreover, the mass ratio of the contrast host material to the guest material D is 97:3. The structural formula of the materials of the electron blocking layer 1323a and the electron blocking layer 1323b is shown in (G1-18).

In Comparative Example 2, the light-emitting layer 131B-a and the light-emitting layer 131B-b each include a contrast host material and a contrast guest material; the structural formula of the contrast host material is shown as (R-H), and the structural formula of the contrast guest material is shown as (R-D). Moreover, the mass ratio of the contrast host material to the contrast guest material is 97:3. The structural formula of the materials of the electron blocking layer 1323a and the electron blocking layer 1323b is shown in (R-G1).

In order to more clearly describe the difference in the structural formula of the host material, the guest material, and the material of the electron blocking layer 1323 used in the Embodiments and Comparative example, Table 6 below is used to clearly show the structural formulas of the host material, the guest material, and the material of the electron blocking layer 1323 used in the Embodiments and Comparative example.

TABLE 6

| | Host material | Guest material of | Material of |
|---|---|---|---|
| | of light-emitting | light-emitting | electron blocking |
| | layer 131B-a and | layer 131B-a and | layer 1323a and |
| | light-emitting | light-emitting | electron blocking |
| | layer 131B-b | layer 131B-b | layer 1323b |
| Embodiment | H-4 | D-4 | G1-13 |
| 10 | | | |
| Embodiment | H-5 | D-6 | G1-7 |
| 11 | | | |
| Embodiment | H-4 | D-4 | G1-18 |
| 12 | | | |
| Embodiment | H-5 | D-6 | G1-20 |
| 13 | | | |
| Embodiment | H-5 | D-4 | R-G1 |
| 14 | | | |
| Embodiment | R-H | R-D | G1-13 |
| 15 | | | |
| Embodiment | H-4 | R-D | R-G1 |
| 16 | | | |
| Embodiment | R-H | D-4 | R-G1 |
| 17 | | | |
| Embodiment | R-H | D-4 | G1-18 |
| 18 | | | |
| Comparative | R-H | R-D | R-G1 |
| example 2 | | | |

It will be noted that, “A-x” in Table 1 means that the corresponding structural formula is A-x. For example, the content of the sub-grid corresponding to the host material H in Embodiment 10 is “H-4”, which means that in the light-emitting layer 131B-a and the light-emitting layer 131B-n in Embodiment 10, the structural formula of the host material H is shown as H-4. The structural formulas represented by “H-x”, “D-x”, “G1-x” (x is a positive integer), R-H, R-D, and R-G1 are as mentioned above and will not be repeated here.

For the values of the overlap rate of the density of states for HOMO, the absolute value of the difference between the electron reorganization energy and the hole reorganization energy, the thermal decomposition temperature Td, and the dipole moment of the above-mentioned host material H, guest material D, and first functional material G1, reference will be made to the first group of experimental examples, which will not be repeated here.

Based on the above materials, the voltage (V), current efficiency (cd/A) and device life (h) of the light-emitting device 101 in Embodiments 10 to 18 and Comparative example 2 are tested. The data results of the voltage (V), luminous efficiency (cd/A), and device life in Embodiments are based on the data result in Comparative example 2, and the test results are shown in Table 7 below. The device life is characterized by the parameter LT95.

TABLE 7

| | Voltage | Efficiency | Device life |
|---|---|---|---|
| Embodiment 10 | 96.1% | 105.3% | 132.6% |
| Embodiment 11 | 97.3% | 104.2% | 141.9% |
| Embodiment 12 | 96.3% | 103.6% | 129.8% |
| Embodiment 13 | 97.2% | 106.2% | 137.3% |
| Embodiment 14 | 100.3% | 105.0% | 103.3% |
| Embodiment 15 | 98.7% | 102.0% | 102.6% |
| Embodiment 16 | 98.5% | 102.0% | 101.5% |
| Embodiment 17 | 99.6% | 99.0% | 101.9% |
| Embodiment 18 | 99.4% | 101.0% | 102.4% |
| Comparative example 2 | 100% | 100% | 100% |

It can be seen from Table 7 that, compared with Comparative Example 2, the device life of Embodiments 10 to 13 is in a range of 129.8% to 141.9%, which are all relatively high. This is because in the first light-emitting device 101 in Embodiments 10 to 13, the host material H and guest material D of the light-emitting layer 131B-a and the light-emitting layer 131B-b, and the material (i.e., the first functional material) of the electron blocking layer 1323a and the electron blocking layer 1323b are all deuterated materials, while in Comparative Example 2, the contrast host material R-H and contrast guest material R-D of the light-emitting layer 131B-a and the light-emitting layer 131B-b, and the contrast first functional material R-G1 of the electron blocking layer 1323a and the electron blocking layer 1323b are all materials that do not contain deuterium atoms. Since deuterated materials have relatively high bond dissociation energy, the stability of the material may be improved. Therefore, in the case where the host material H and guest material D of the light-emitting layer 131B-a and the light-emitting layer 131B-b, and the material (i.e., the first functional material) of the electron blocking layer 1323a and the electron blocking layer 1323b are all deuterated materials, the materials of the first light-emitting device 101 contains relatively more deuterium atoms, so that the stability of the three materials is improved; moreover, due to the synergistic effect of the three deuterated materials, the first light-emitting device 101 may exhibit the relatively excellent device life.

Compared with Comparative Example 2, referring to Table 7, the device efficiency in Embodiments 10 to 13 is in a range of 103.6% to 106.2%, which are relatively high. This is because in the first light-emitting device 101 in Embodiments 10 to 13, the host material H and guest material D of the light-emitting layer 131B-a and the light-emitting layer 131B-b, and the material (i.e., the first functional material) of the electron blocking layer 1323a and the electron blocking layer 1323b are all deuterated materials, while the contrast host material R-H and contrast guest material R-D of the light-emitting layer 131B-a and the light-emitting layer 131B-b, and the contrast first functional material R-G1 of the electron blocking layer 1323a and the electron blocking layer 1323b in Comparative Example 2 are all materials that do not contain deuterium atoms. Therefore, in the case where the host material H and guest material D are deuterated materials, the molecular vibration is relatively small, so that the quantum efficiency loss caused by the molecular vibration of the host material H and the guest material D is relatively small, and the efficiency of the first light-emitting device 101 is relatively high.

Compared with Comparative Example 2, referring to Table 7, the device life of Embodiments 14, 16 and 17 are relatively long, which is because the host material H and/or guest material D of the light-emitting layer 131B-a and the light-emitting layer 131B-b in the first light-emitting device 101 of Embodiments 14, 16 and 17 are all deuterated materials, while the contrast host material R-H and contrast guest material R-D of the light-emitting layer 131B-a and the light-emitting layer 131B-b in Comparative Example 2 are materials that do not contain deuterium atoms. The host material or the contrast host material is the materials where high-energy excitons are generated by recombination, and the guest material or the contrast guest material is a material that receives the energy transferred by the host material or the contrast host material to radiate light. Since deuterated materials have relatively high bond dissociation energy, the electrical stability of the material may be improved. In the case where the host material H and/or guest material D of the light-emitting layer 131B-a and the light-emitting layer 131B-b are both deuterated materials, the host material H and/or guest material D have relatively high electrical stability, which may improve the tolerance to high-energy excitons and high-energy intermediates of the TTA effect, so that the first light-emitting device 101 exhibits relatively excellent device life.

Compared with Comparative Example 2, referring to Table 7, the device life of Embodiments 15 and 18 is relatively high, which is because the material (i.e., the first functional material) of the electron blocking layer 1323a and the electron blocking layer 1323b of the first light-emitting device 101 in Embodiments 15 and 18 is a deuterated material, while the material (i.e., the contrast first functional material) of the electron blocking layer 1323a and the electron blocking layer 1323b in Comparative Example 2 is a material that does not contain deuterium atoms. Since deuterated materials have relatively high bond dissociation energy, the electrical stability of the material may be improved. Therefore, in the case where the material of the electron blocking layer 1323a and the electron blocking layer 1323b is a deuterated material, the material of the two electron blocking layers have relatively high electrical stability, which may improve the tolerance to carriers (electrons or holes) and excitons, so that the first light-emitting device 101 exhibits relatively excellent device life.

Compared with Comparative Example 2, referring to Table 7, the device efficiency of Embodiments 15 and 18 are relatively high, which is because the structure of the material (i.e., the first functional material) of the electron blocking layer 1323a and the electron blocking layer 1323b in the first light-emitting device 101 in Embodiments 15 and 18 is selected from the structure shown in general formula (III) or general formula (IV), while the material (i.e., the contrast first functional material) of the electron blocking layer 1323a and the electron blocking layer 1323b in Comparative example 2 does not conform to the structure shown in general formula (III) or general formula (IV). Since the structure represented by general formula (III) or general formula (IV) contains carbazolyl, dibenzofuran, dibenzothiophene, fluorene or spirofluorene, the triplet energy level of the first functional material may be relatively high, and the difference between the triplet energy level of the first functional material and the triplet energy level of the host material may be relatively large. In this way, after holes and electrons recombine to form triplet excitons in the host material, the number of triplet excitons transferred from the host material to the first functional material is relatively small, so that the triplet excitons may be confined in the light-emitting layer 131 (for example, confined to the host material). As a result, the concentration of triplet excitons in the light-emitting layer 131 may be increased, which may enhance the TTA effect to fully utilize the TTA effect, so that the efficiency of the first light-emitting device 101 may be improved.

It can be seen from the above Embodiments and Comparative example that, in the present disclosure, by setting the overlap rate of the density of states for HOMO of the first functional material and the density of states for HOMO of the second functional material to be greater than 0% and less than or equal to 90%, the efficiency of the tandem light-emitting device 100 (e.g., the first light-emitting device 101) may be improved, and the device life of the tandem light-emitting device 100 (e.g., the first light-emitting device 101) may be improved. Moreover, by configuring the host material H to be any one of the structures represented by the general formula (I), the guest material D to be any one of the structures represented by the general formula (II), and the first functional material G1 to be any one of the structures represented by the general formula (III) or the general formula (IV), the efficiency of the tandem light-emitting device 100 (e.g., the first light-emitting device 101) may be further improved, and the device life of the tandem light-emitting device 100 (e.g., the first light-emitting device 101) may be increased.

The above are only specific embodiments of the present disclosure, but the protection scope of the present disclosure is not limited thereto, and variations or substitutions that any person skilled in the art may conceive of within the technical scope disclosed by the present disclosure, should fall within the protection scope of the present disclosure. Therefore, the protection scope of the present disclosure should be determined by the protection scope of the claims.

1. A light-emitting device, comprising: a cathode and an anode that are arranged opposite to each other, and at least one light-emitting unit located between the cathode and the anode; wherein
a light-emitting unit of the at least one light-emitting unit includes a light-emitting layer and a first type of functional layer arranged on a side of the light-emitting layer proximate to the anode; the first type of functional layer includes a first functional sub-layer and a second functional sub-layer, a material of the first functional sub-layer includes a first functional material, and a material of the second functional sub-layer includes a second functional material;
wherein an overlap rate of density of states for HOMO of the first functional material and density of states for HOMO of the second functional material is greater than 0% and less than or equal to 90%.

2. The light-emitting device according to claim 1, wherein the first functional sub-layer is in contact with the light-emitting layer, and a material of the light-emitting layer includes a host material;
wherein an overlap rate of the density of states for HOMO of the first functional material and density of states for HOMO of the host material is greater than 0% and less than or equal to 90%.

3. The light-emitting device according to claim 2, wherein the material of the light-emitting layer further includes a guest material; at least one of the host material, the guest material and the first functional material is a deuterated material.

4. The light-emitting device according to claim 2, wherein an absolute value of a difference between an electron reorganization energy of the host material and a hole reorganization energy of the host material is less than or equal to 0.1 eV; and/or
a hole mobility of the host material is greater than an electron mobility of the host material.

5. The light-emitting device according to claim 1, wherein a dipole moment of the first functional material is greater than 0 D and/or
a lowest bond dissociation energy of bond dissociation energies of the first functional material in a ground state is greater than or equal to 2.40 eV; and/or
a lowest bond dissociation energy of bond dissociation energies of the first functional material in a anionic state is greater than or equal to 1.0 eV.

6. (canceled)

7. The light-emitting device according to claim 3, wherein a lowest bond dissociation energy of bond dissociation energies of the host material in a ground state is greater than or equal to 1.50 eV; and/or
a lowest bond dissociation energy of bond dissociation energies of the guest material in a ground state is greater than or equal to 1.50 eV;
a triplet energy level of the host material is less than a triplet energy level of the guest material; and/or
a singlet energy level of the host material is greater than a singlet energy level of the guest material.

8. (canceled)

9. The light-emitting device according to claim 2, wherein the light-emitting unit further includes: a second type of functional layer disposed on a side of the light-emitting layer proximate to the cathode; the second type of functional layer includes a third functional sub-layer, and the third functional sub-layer is in contact with the light-emitting layer; a material of the third functional sub-layer includes a third functional material;
wherein a triplet energy level of the host material is greater than a triplet energy level of the third functional material; and/or
the triplet energy level of the host material is less than a triplet energy level of the first functional material.

10. The light-emitting device according to claim 2, wherein the host material is selected from structures represented by a following general formula (I); 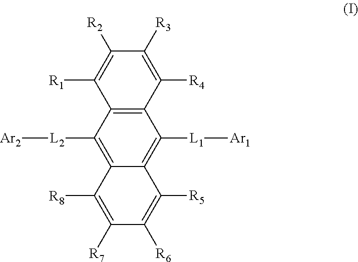
wherein R₁, R₂, R₃, R₄, R₅, R₆, R₇ and R₈ are same or different, and are independently selected from hydrogen, deuterium, substituted or unsubstituted alkyl, substituted or unsubstituted alkoxy, substituted or unsubstituted aryl, substituted or unsubstituted aryloxy, substituted or unsubstituted diarylamino, substituted or unsubstituted siloxane and substituted or unsubstituted silyl;
L₁ and L₂ are same or different, and are independently selected from a single bond, substituted or unsubstituted arylene and substituted or unsubstituted heteroarylene;
Ar₁ and Ar₂ are same or different, and are independently selected from substituted or unsubstituted aryl; and
at least one of R₁, R₂, R₃, R₄, R₅, R₆, R₇, R₈, L₁, L₂, Ar₁ and Ar₂ contains deuterium.

11. (canceled)

12. The light-emitting device according to claim 3, wherein the guest material is selected from structures represented by a following general formula (II); 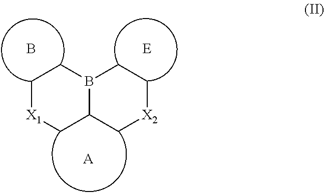
wherein A, E and F are same or different, and are independently selected from a substituted or unsubstituted aromatic ring, a substituted or unsubstituted heteroaromatic ring, and substituted or unsubstituted cycloalkane; in a case where A, E and F are each selected from a substituted aromatic ring, a substituted heteroaromatic ring and substituted cycloalkane, a substituent is connected to an adjacent substituent to form a substituted or unsubstituted ring;
X₁ and X₂ are same or different, and are independently selected from O, N(Rₐ) and C(R_{b}R_{c});
Rₐ, R_{b} and R_{c} are same or different, and are independently selected from hydrogen, deuterium, halogen, cyano, substituted or unsubstituted alkyl, substituted or unsubstituted silyl, substituted or unsubstituted alkoxy, substituted or unsubstituted aryl and substituted or unsubstituted heterocyclic; and
at least one of A, E and F contains deuterium.

13-14. (canceled)

15. The light-emitting device according to claim 1, wherein the first functional material is selected from structures represented by a following general formula (III); 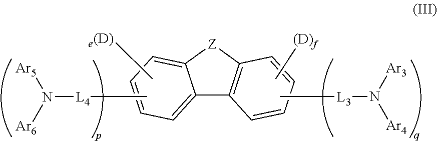
wherein Z is selected from O, S, N(R_{d}) and C(RₑR_{f});
R_{d}, Rₑ, and R_{f} are same or different, and are independently selected from substituted or unsubstituted alkyl, substituted or unsubstituted aryl, and substituted or unsubstituted heteroaryl;
L₃ and L₄ are same or different, and are independently selected from a single bond, substituted or unsubstituted arylidene, and substituted or unsubstituted heteroarylene;
e and f are same or different, and are independently selected from 1, 2, 3 and 4;
Ar₃, Ar₄, Ar₅ and Ar₆ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S;
p and q are same or different, and are independently selected from 0, 1 and 2, and a sum of p and q is greater than or equal to 1 and less than or equal to 2.

16. The light-emitting device according to claim 15, wherein the first functional material is selected from structures represented by a following general formula (III-A); 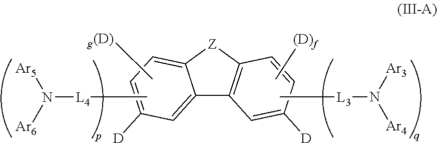
wherein g and h are same or different, and are independently selected from 0, 1, 2 and 3.

17. The light-emitting device according to claim 1, wherein the first functional material is selected from structures represented by a following general formula (IV); 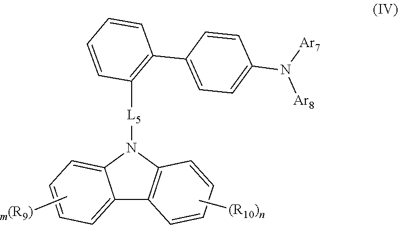
wherein L₅ is selected from a single bond, and substituted or unsubstituted C6-C60 arylene;
Ar₇ and Ar₈ are same or different, and are independently selected from substituted or unsubstituted C6-C60 aryl, and substituted or unsubstituted C2-C60 heteroaryl; the C2-C60 heteroaryl includes at least one heteroatom, and the heteroatom includes N, O and S;
R₉ and R₁₀ are same or different, and are independently selected from hydrogen, deuterium, halogen, cyano, nitro, amino, substituted or unsubstituted C1-C60 alkyl, substituted or unsubstituted C3-C60 cycloalkyl, substituted or unsubstituted C2-C60 alkenyl, substituted or unsubstituted C6-C60 aryl, and substituted or unsubstituted C2-C60 heteroaryl; or R₉ and R₁₀ are each connected to an adjacent substituent to form a substituted or unsubstituted ring; the C2-C60 heteroaryl includes at least one heteroatom, and the heteroatom includes N, O and S;
m and n are same or different, and are independently selected from 1, 2, 3 and 4;
at least one R₉ is deuterium; and
at least one R₁₀ is deuterium.

18. The light-emitting device according to claim 3, wherein in a case where the host material is a deuterated material, a mass fraction of deuterium in the host material is greater than or equal to 1.0% and less than or equal to 4.9%; and/or
in a case where the guest material is a deuterated material, a mass fraction of deuterium in the guest material is greater than or equal to 0.1% and less than or equal to 8.5%; and/or
in a case where the first functional material is a deuterated material, a mass fraction of deuterium in the first functional material is greater than or equal to 0.15% and less than or equal to 5.50%.

19. The light-emitting device according to claim 1, wherein the light-emitting device comprises at least two light-emitting units, and the at least two light-emitting units are arranged in sequence; and
the light-emitting device further comprises a charge generation layer located between two adjacent light-emitting units; wherein the charge generation layer includes a hole generation layer and an electron generation layer that are stacked, and the electron generation layer is closer to the anode than the hole generation layer.

20-21. (canceled)

22. A display panel, comprising a plurality of light-emitting devices each according to claim 1; and
a plurality of pixel driving circuits, wherein a pixel driving circuits is electrically connected to a light-emitting device, and is used to drive the light-emitting device to emit light.

23. A display panel, comprising:
a substrate; and
a plurality of light-emitting devices disposed on the substrate and arranged in a first direction, the first direction being parallel to a plane where the substrate is located; the plurality of light-emitting devices including at least one first light-emitting device, at least one second light-emitting device and at least one third light-emitting device, the first light-emitting device being configured to emit blue light, the second light-emitting device being configured to emit green light, and the third light-emitting device being configured to emit red light;
wherein each light-emitting device of the plurality of light-emitting devices includes: a cathode and an anode that are arranged opposite to each other, and at least one light-emitting unit arranged between the cathode and the anode; a light-emitting unit of the at least one light-emitting unit includes a light-emitting layer; a number of light-emitting units included in each light-emitting device of the plurality of light-emitting devices is n, wherein n is a positive integer greater than or equal to 1; and
a thickness of a light-emitting layer of an N-th light-emitting unit of the third light-emitting device is greater than a thickness of a light-emitting layer of an N-th light-emitting unit of the second light-emitting device, and the thickness of the light-emitting layer of the N-th light-emitting unit of the second light-emitting device is greater than a thickness of a light-emitting layer of an N-th light-emitting unit of the first light-emitting device, wherein N is a positive integer less than or equal to n.

24. The display panel according to claim 23, wherein a difference between the thickness of the light-emitting layer of the N-th light-emitting unit of the third light-emitting device and the thickness of the light-emitting layer of the N-th light-emitting unit of the first light-emitting device is a first thickness difference, a difference between the thickness of the light-emitting layer of the N-th light-emitting unit of the second light-emitting device and the thickness of the light-emitting layer of the N-th light-emitting unit of the first light-emitting device is a second thickness difference, and a difference between the thickness of the light-emitting layer of the N-th light-emitting unit of the third light-emitting device and the thickness of the light-emitting layer of the N-th light-emitting unit of the second light-emitting device is a third thickness difference;
wherein a ratio of the first thickness difference to the second thickness difference is greater than or equal to 1.5 and less than or equal to 2, and a ratio of the third thickness difference to the second thickness difference is greater than or equal to 1 and less than or equal to 1.5.

25. The display panel according to claim 23, wherein the light-emitting unit further includes a first type of functional layer disposed on a side of the light-emitting layer proximate to the anode; the first type of functional layer includes a first functional sub-layer in contact with the light-emitting layer; wherein
a difference between a thickness of a first functional sub-layer of the N-th light-emitting unit of the third light-emitting device and a thickness of a first functional sub-layer of the N-th light-emitting unit of the first light-emitting device is a fourth thickness difference, and a difference between a thickness of a first functional sub-layer of the N-th light-emitting unit of the second light-emitting device and a thickness of a first functional sub-layer of the N-th light-emitting unit of the first light-emitting device is a fifth thickness difference; a ratio of the fourth thickness difference to the fifth thickness difference is greater than or equal to 1.1 and less than or equal to 1.5.

26. (canceled)

27. The display panel according to claim 23, wherein a material of the light-emitting layer includes a guest material, and the guest material is configured to emit light of a set wavelength; wherein
a relative molecular weight of the guest material of the light-emitting layer of the first light-emitting device is greater than or equal to 650 and less than or equal to 1300; and/or
a relative molecular weight of the guest material of the light-emitting layer of the second light-emitting device is greater than or equal to 700 and less than or equal to 1400; and/or
a relative molecular weight of the guest material of the light-emitting layer of the third light-emitting device is greater than or equal to 700 and less than or equal to 1500.

28-30. (canceled)

31. The display panel according to claim 23, wherein the light-emitting device includes a first light-emitting unit and a second light-emitting unit; the first light-emitting unit is closer to the anode than the second light-emitting unit;
wherein a ratio of a thickness of a light-emitting layer of the first light-emitting unit to a thickness of a light-emitting layer of the second light-emitting unit is greater than or equal to 0.8 and less than or equal to 1.5.

32-54. (canceled)
